(19) United States
(12) Patent Application Publication
(10) Pub. No.: US 2015/0034927 A1
(43) Pub. Date: Feb. 5, 2015

(54) MATERIAL FOR ORGANIC ELECTROLUMINESCENT ELEMENT, AND ORGANIC ELECTROLUMINESCENT ELEMENT USING SAME

(71) Applicants: Yuki Nakano, Sodegaura-shi (JP); Hiroshi Yamamoto, Sodegaura-shi (JP); Ryohei Hashimoto, Sodegaura-shi (JP); Hideaki Nagashima, Sodegaura-shi (JP)

(72) Inventors: Yuki Nakano, Sodegaura-shi (JP); Hiroshi Yamamoto, Sodegaura-shi (JP); Ryohei Hashimoto, Sodegaura-shi (JP); Hideaki Nagashima, Sodegaura-shi (JP)

(73) Assignee: Idemitsu Kosan Co., Ltd., Chiyoda-ku Tokyo (JP)

(21) Appl. No.: 14/377,834

(22) PCT Filed: Feb. 7, 2013
(86) PCT No.: PCT/JP13/00674

§ 371 Date: Aug. 8, 2014

(30) Foreign Application Priority Data
Feb. 10, 2012 (JP) 2012-027742
May 7, 2012 (JP) 2012-106167
Sep. 21, 2012 (JP) 2012-208846

(51) Int. Cl. H01L 51/00; H01L 51/50

(52) U.S. Cl. CPC H01L 51/0073; H01L 51/0052; H01L 51/0054; H01L 51/0067; H01L 51/0072; H01L 51/5012
USPC 257/40; 549/220; 546/22; 546/23; 548/305.1

(57) ABSTRACT

A compound represented by the following formula (1-1):

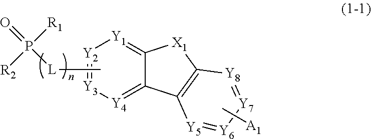

### TECHNICAL FIELD

The invention relates to a material for an organic electroluminescence device and an organic electroluminescence device using the same.

### BACKGROUND ART

An organic electroluminescence (EL) device includes a fluorescent organic EL device and a phosphorescent organic EL device, and a device design optimum for the emission mechanism of each type of organic EL device has been studied. It is known that a highly efficient phosphorescent organic EL device cannot be obtained by merely applying fluorescent device technology due to the emission characteristics. The reasons therefor are generally considered to be as follows.

Specifically, since phosphorescence emission utilizes triplet excitons, a compound used for forming an emitting layer must have a large energy gap. This is because the energy gap (hereinafter often referred to as “singlet energy”) of a compound is normally larger than the triplet energy thereof (in the invention, the difference in energy between the lowest excited triplet state and the ground state) of the compound.

In order to confine the triplet energy of a phosphorescent dopant material efficiently in an emitting layer, it is required to use, in an emitting layer, a host material having a triplet energy larger than that of the phosphorescent dopant material. Further, an electron-transporting layer and a hole-transporting layer are required to be provided adjacent to an emitting layer, and a compound having a triplet energy larger than that of a phosphorescent dopant material is required to be used in the electron-transporting layer and the hole-transporting layer.

As mentioned above, if based on the conventional design concept of an organic EL device, it leads to the use of a compound having a larger energy gap as compared with a compound used in a fluorescent organic EL device in a phosphorescent organic EL device. As a result, the driving voltage of the entire organic EL device is increased.

Further, a hydrocarbon-based compound having a high resistance to oxidation or reduction, which has been useful in a fluorescent device, the π electron cloud spreads largely, and hence it has a small energy gap. Therefore, in a phosphorescent organic EL device, such a hydrocarbon-based compound is hardly selected. As a result, an organic compound including a hetero atom such as oxygen and nitrogen is selected, and hence a phosphorescent organic EL device has a problem that it has a short lifetime as compared with a fluorescent organic EL device.

In addition, a significantly long exciton relaxation time of a triplet exciton of a phosphorescent dopant material as compared with that of a singlet exciton greatly affects the device performance. That is, emission from the singlet exciton has a high relaxation speed that leads to emission, and hence, diffusion of excitons to peripheral layers of emitting layers (a hole-transporting layer or an electron-transporting layer, for example) hardly occurs, whereby efficient emission is expected. On the other hand, in the case of emission from the triplet exciton, since it is spin-forbidden and has a slow relaxation speed, diffusion of excitons to the peripheral layers tends to occur easily, and as a result, thermal energy deactivation occurs from other compounds than a specific phosphorescent emitting compound. That is, in a phosphorescent organic EL device, control of a recombination region of electrons and holes is more important than that of a fluorescent organic EL device.

For the reasons mentioned above, in order to improve the performance of a phosphorescent organic EL device, material selection and device design that are different from a fluorescent organic EL device have come to be required.

In order to lower the driving voltage of an organic EL device, it is required to use a material having excellent carrier-injecting properties or carrier-transporting properties. However, when a material having excellent carrier-injecting properties or carrier-transporting properties is used, while the driving voltage is lowered, the carrier balance within the emitting layer may be deteriorated, resulting in a shortened device life. That is, a carrier-transporting material that reduces the driving voltage while keeping the life of a device long is required.

Non-Patent Document 1 discloses a compound in which the 2-position of dibenzofuran is substituted by carbazole and the 8-position of dibenzofuran is substituted by diphenylphosphine oxide. This document states that, since this compound is used in a blue phosphorescent EL device, dibenzofuran having a high triplet energy is used as a core unit, and as a skeleton for improving electron-injection properties and electron-transporting properties, phosphine oxide is used, and in combination, carbazole is used in order to impart a device with hole-transporting properties. These compounds show bipolarity, since a device using this compound as a host material exhibits a high luminous efficiency and current-voltage characteristics that are equivalent to those of a mixed host device using corresponding hole-transporting host and electron-transporting host.

Non-Patent Document 2 discloses a compound in which the 4-position of dibenzofuran is substituted by diphenylphosphine oxide. This compound can retain a high triplet energy of dibenzofuran and can suppress aggregation of molecules. By using this compound as a host material of a blue phosphorescent device, a high luminous efficiency can be exhibited and lowering in luminous efficiency can be suppressed even if the luminance is high.

Patent Document 1 discloses a compound obtained by combining phosphine oxide and carbazole. Due to this combination, this compound is known to have excellent heat stability and hole-transporting properties. This compound is used in an emitting layer or a hole-transporting layer.

Patent Document 2 discloses that a compound having a phosphine oxide to which a diarylamine site having hole-transporting properties and a nitrogen-containing heterocyclic linking group are directly bonded exhibits excellent hole/electron injecting and transporting properties and has well-balanced holes and electrons in the device. This compound is used as a material for an emitting layer or an electron-transporting layer.

### RELATED ART DOCUMENTS

### Patent Documents

Patent Document 1: WO2010/137779

Patent Document 2: WO2010/098386

### Non-Patent Documents

Non-Patent Document 1: CHEMISTRY-AN ASIAN JOURNAL 2011, 6(11), 2895.

Non-Patent Document 2: CHEMISTRY-A EUROPEAN JOURNAL 2011, 17(2), 445.

### SUMMARY OF THE INVENTION

An object of the invention is to provide a compound capable of lowering the driving voltage while keeping the life of an organic EL device long.

According to the invention, the following compounds or the like are provided.

1. A compound represented by the following formula (1-1):

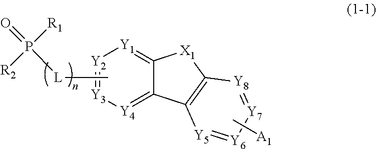

wherein in the formula (1-1),

X₁ is O or S;

Y₁ to Y₄ are independently C(Rₐ), N, or a carbon atom that is bonded to L or P;

Y₅ to Y₈ are independently C(Rₐ), N, or a carbon atom that is bonded to A₁;

L is O, S, a substituted or unsubstituted arylene group including 6 to 30 carbon atoms that form a ring (hereinafter referred to as “ring carbon atoms”), or a substituted or unsubstituted heteroarylene group including 5 to 30 atoms that form a ring (hereinafter referred to as “ring atoms”);

n is an integer of 0 to 3, and when n is 2 or more, plural Ls may be the same or different from each other;

R₁ and R₂ are independently a substituted or unsubstituted aryl group including 6 to 30 ring carbon atoms, or a substituted or unsubstituted heteroaryl group including 5 to 30 ring atoms;

Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;

when two or more Rₐs are present in the formula (1-1), plural Rₐs may be the same or different from each other;

A₁ is a hydrogen atom, a substituted or unsubstituted aryl group including 6 to 30 ring carbon atoms, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl group, a substituted or unsubstituted azacarbazolyl group, a substituted or unsubstituted benzimidazolyl group, or a substituent represented by the following formula (2); and

provided that when A₁ is a hydrogen atom, n is an integer of 1 to 3:

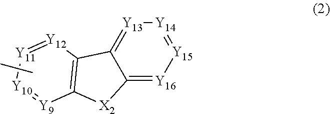

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ), or N; and

Rₐ is the same as in the formula (1-1).

2. The compound according to 1, wherein the substituted or unsubstituted aryl group including 6 to 30 ring carbon atoms for A is a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.
3. The compound according to 1 or 2, wherein the group represented by the formula (2) is a group represented by the following formula (2-1):

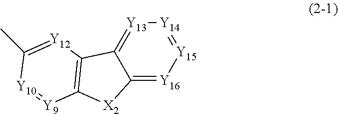

wherein in the formula (2-1),

X₂, Y₉, Y₁₀, Y₁₂ and Y₁₃ to Y₁₆ are the same as those in the formula (2).

4. The compound according to any of 1 to 3, wherein L is an arylene group or a heteroarylene group represented by any of the following formulas (4) to (8):

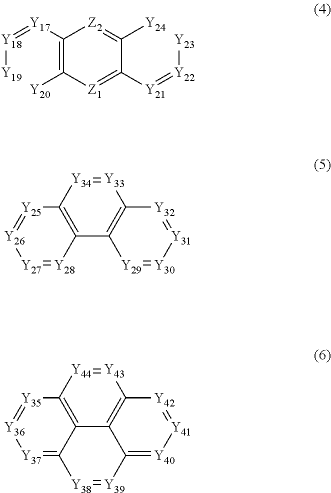

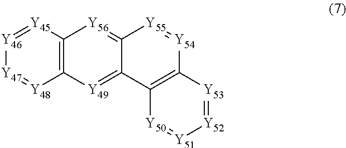

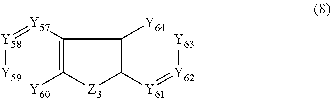

wherein in the formulas (4) to (8), Y₁₇ to Y₆₄, Z₁ and Z₂ are independently C(Rₐ), N or a carbon atom that is bonded to P, another L or any of Y₁ to Y₄;

in the formula (8), Z₃ is C(Rₐ)₂, N(Rₐ) or a nitrogen atom that is bonded to P, another L or any of Y₁ to Y₄; and

Rₐ is the same as in the formula (1-1).

5. A material for an organic electroluminescence device comprising the compound according to any of 1 to 4.
6. An electron-transporting material for an organic electroluminescence device represented by the following formula (1-2):

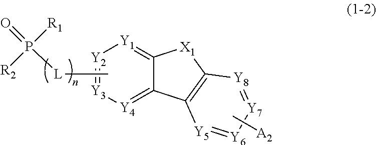

wherein in the formula (1-2),

X₁ is O or S;

Y₁ to Y₄ are independently C(Rₐ), N, or a carbon atom that is bonded to L or P;

Y₅ to Y₈ are independently C(Rₐ), N, or a carbon atom that is bonded to A₂;

L is O, S, a substituted or unsubstituted arylene group including 6 to 30 ring carbon atoms, or a substituted or unsubstituted heteroarylene group including 5 to 30 ring atoms;

n is an integer of 0 to 3, and when n is 2 or more, plural Ls may be the same or different from each other;

R₁ and R₂ are independently a substituted or unsubstituted aryl group including 6 to 30 ring carbon atoms, or a substituted or unsubstituted heteroaryl group including 5 to 30 ring atoms;

Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;

when two or more Rₐs are present in the formula (1-2), plural Rₐs may be the same or different from each other; and

A₂ is a hydrogen atom, a substituted or unsubstituted aryl group including 6 to 30 ring carbon atoms, or a substituted or unsubstituted heteroaryl group including 5 to 30 ring atoms.

7. The electron-transporting material for an organic electroluminescence device according to 6, wherein the substituted or unsubstituted aryl group including 6 to 30 ring carbon atoms for A₂ is a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.
8. The electron-transporting material for an organic electroluminescence device according to claim 6, wherein the substituted or unsubstituted heteroaryl group including 5 to 30 ring atoms for A₂ is a group represented by the following formula (2):

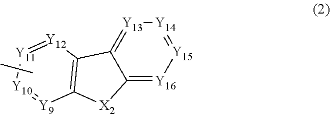

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ), or N; and

Rₐ is the same as in the formula (1-2).

9. The electron-transporting material for an organic electroluminescence device according to 8, wherein the group represented by the formula (2) is a group represented by the following formula (2-1):

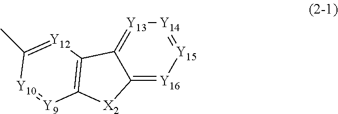

wherein in the formula (2-1),

X₂, Y₉, Y₁₀, Y₁₂ and Y₁₃ to Y₁₆ are the same as those in the formula (2).

10. The electron-transporting material for an organic electroluminescence device according to 6, wherein the substituted or unsubstituted heteroaryl group including 5 to 30 ring atoms for A₂ is a substituted or unsubstituted nitrogen-containing heteroaryl group including 5 to 30 ring atoms.
11. The electron-transporting material for an organic electroluminescence device according to 10, wherein the substituted or unsubstituted nitrogen-containing heteroaryl group including 5 to 30 ring atoms for A₂ is a substituted or unsubstituted pyridinyl group, a substituted or unsubstituted pyrimidinyl group, a substituted or unsubstituted triazinyl group, a substituted or unsubstituted imidazoyl group, a substituted or unsubstituted carbazolyl group, a substituted or unsubstituted phenanthrolinyl group, a substituted or unsubstituted carbazolyl group, or a substituted or unsubstituted azacarbazolyl group.
12. The electron-transporting material for an organic electroluminescence device according to any of 6 to 11, wherein L is an arylene group or a heteroarylene group represented by any of the following formulas (4) to (8):

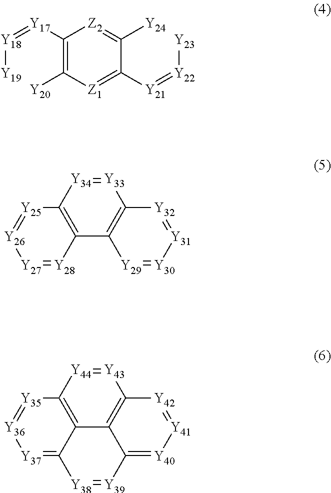

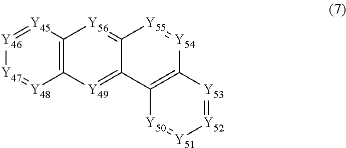

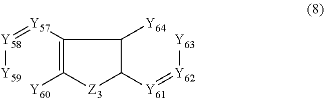

wherein in the formulas (4) to (8), Y₁₇ to Y₆₄, Z₁ and Z₂ are independently C(Rₐ), N, or a carbon atom that is bonded to P, another L or any of Y₁ to Y₄;

in the formula (8), Z₃ is C(Rₐ)₂, N(Rₐ), or a nitrogen atom that is bonded to P, another L or any of Y₁ to Y₄; and

Rₐ is the same as in the formula (1-2).

13. A hole-blocking material for an organic electroluminescence device represented by the following formula (1-3):

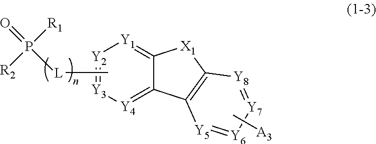

wherein in the formula (1-3),

X₁ is O or S;

Y₁ to Y₄ are independently C(Rₐ), N, or a carbon atom that is bonded to L or P;

Y₅ to Y₈ are independently C(Rₐ), N, or a carbon atom that is bonded to A₃;

L is O, S, a substituted or unsubstituted arylene group including 6 to 30 ring carbon atoms, or a substituted or unsubstituted heteroarylene group including 5 to 30 ring atoms;

n is an integer of 0 to 3, and when n is 2 or more, plural Ls may be the same or different from each other;

R₁ and R₂ are independently a substituted or unsubstituted aryl group including 6 to 30 ring carbon atoms, or a substituted or unsubstituted heteroaryl group including 5 to 30 ring atoms;

Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;

when two or more Rₐs are present in the formula (1-3), plural Rₐs may be the same or different from each other;

A₃ is a hydrogen atom, a substituted or unsubstituted phenyl group, a substituted or unsubstituted meta-biphenylyl group, a substituted or unsubstituted meta-terphenyl group, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl group, a substituted or unsubstituted azacarbazolyl group, a substituted or unsubstituted benzimidazolyl group, or a substituent represented by the following formula (2); and

provided that when A₃ is a hydrogen atom, n is an integer of 1 to 3,

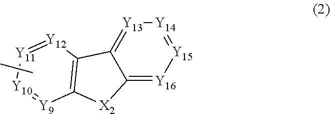

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ), or N; and

Rₐ is the same as in the formula (1-3).

14. The hole-blocking material for an organic electroluminescence device according to 13, wherein the group represented by the formula (2) is a group represented by the following formula (2-1):

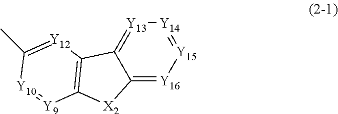

wherein in the formula (2-1),

X₂, Y₉, Y₁₀, Y₁₂ and Y₁₃ to Y₁₆ are the same as those in the formula (2).

15. The hole-blocking material for an organic electroluminescence device according to 13 or 14, wherein L is an arylene group or a heteroarylene group represented by any of the following formulas (4) to (8):

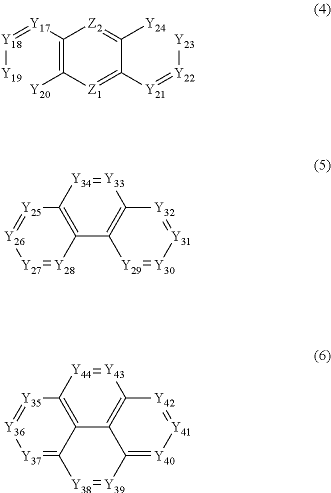

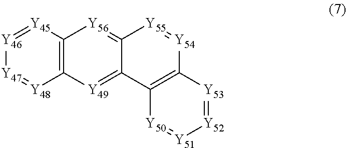

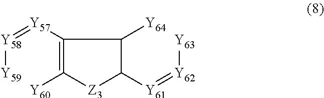

wherein in the formulas (4) to (8), Y₁₇ to Y₆₄, Z₁ and Z₂ are independently C(Rₐ), N or a carbon atom that is bonded to P, another L or any of Y₁ to Y₄;

in the formula (8), Z₃ is C(Rₐ)₂, N(Rₐ) or a nitrogen atom that is bonded to P, another L or any of Y₁ to Y₄; and

Rₐ is the same as in the formula (1-3).

16. An organic electroluminescence device comprising one or more organic thin film layers including an emitting layer between an anode and a cathode, wherein at least one layer of the organic thin film layers comprises the material for an organic electroluminescence device according to 5.
17. The organic electroluminescence device according to 16, wherein the emitting layer comprises the material for an organic electroluminescence device.
18. An organic electroluminescence device comprising one or more organic thin film layers including an emitting layer between an anode and a cathode, and comprising an electron-transporting region between the cathode and the emitting layer, wherein the electron-transporting region comprises the electron-transporting material for an organic electroluminescence device according to any of 6 to 12.
19. An organic electroluminescence device comprising one or more organic thin film layers including an emitting layer between an anode and a cathode, and comprising an hole-blocking layer between the cathode and the emitting layer, wherein the hole-barrier layer comprises the hole-blocking material for an organic electroluminescence device according to any of 13 to 15.
20. The organic electroluminescence device according to 19, further comprising an electron-transporting region between the cathode and the emitting layer.
21. The organic electroluminescence device according to 18 or 20, wherein the electron-transporting region comprises an electron-donating dopant.
22. The organic electroluminescence device according to any of 16 to 21, wherein the emitting layer comprises a phosphorescent material, the phosphorescent material being an ortho-metalated complex of a metal atom selected from iridium (Ir), osmium (Os) and platinum (Pt).
23. The organic electroluminescence device according to 22, wherein the phosphorescent material is represented by the following formula (I):

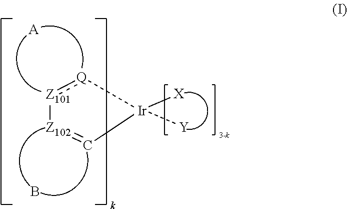

wherein in the formula, Z₁₀₁ and Z₁₀₂ are independently a carbon atom or a nitrogen atom;

A is a group of atoms that forms a five-membered hetero ring or a six-membered hetero ring together with Z₁₀₁ and a nitrogen atom;

B is a group of atoms that forms a five-membered ring or a six-membered ring together with Z₁₀₂ and a carbon atom;

Q is a carbon atom, a nitrogen atom, or a boron atom;

X—Y is a monoanionic bidentate ligand; and

k is an integer of 1 to 3.

24. The organic electroluminescence device according to any of 16 to 23, wherein the emitting layer comprises a compound comprising a carbazole ring and a dibenzofuran ring.

According to the invention, it is possible to provide a compound capable of lowering the driving voltage while keeping the life of an organic EL device long.

### BRIEF DESCRIPTION OF THE DRAWINGS

FIG. 1 is a view showing one embodiment of the organic EL device of the invention; and

FIG. 2 is a view showing another embodiment of the organic EL device of the invention.

### MODE FOR CARRYING OUT THE INVENTION

The compound of the invention is represented by the following formula (1-1):

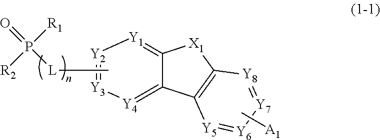

wherein in the formula (1-1),

X₁ is O or S;

Y₁ to Y₄ are independently C(Rₐ), N, or a carbon atom that is bonded to L or P;

Y₅ to Y₈ are independently C(Rₐ), N, or a carbon atom that is bonded to A₁;

L is O, S, a substituted or unsubstituted arylene group including 6 to 30 ring carbon atoms, or a substituted or unsubstituted heteroarylene group including 5 to 30 ring atoms;

n is an integer of 0 to 3, and when n is 2 or more, plural Ls may be the same or different from each other;

R₁ and R₂ are independently a substituted or unsubstituted aryl group including 6 to 30 ring carbon atoms, or a substituted or unsubstituted heteroaryl group including 5 to 30 ring atoms;

Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;

when two or more Rₐs are present in the formula (1-1), plural Rₐs may be the same or different from each other;

A₁ is a hydrogen atom, a substituted or unsubstituted aryl group including 6 to 30 ring carbon atoms, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl group, a substituted or unsubstituted azacarbazolyl group, a substituted or unsubstituted benzimidazolyl group, or a substituent represented by the following formula (2); and

provided that when A₁ is a hydrogen atom, n is an integer of 1 to 3:

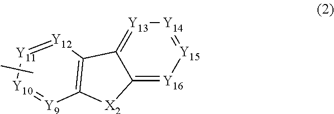

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ), or N; and

Rₐ is the same as in the formula (1-1).

It is preferred that any of Y₁ to Y₈ be C(Rₐ) or a carbon atom that is bonded to an adjacent group or an adjacent atom. That is, it is preferred that each of Y₁ to Y₄ be C(Rₐ) or a carbon atom that is bonded to L or P, and that each of Y₅ to Y₈ be C(Rₐ) or a carbon atom that is bonded to any of Y₉ to Y₁₂.

When A₁ is a substituent represented by the formula (2), it is preferred that each of Y₉ to Y₁₆ be C(Rₐ) or a carbon atom that is bonded to an adjacent group or an adjacent atom. That is, it is preferred that Y₉ to Y₁₂ be independently C(Rₐ) or a carbon atom that is bonded to any of Y₅ to Y₈ and that each of Y₁₃ to Y₁₆ be C(Rₐ).

Further, when A is a substituent represented by the formula (2), it is also preferred that at least one of Y₁ to Y₁₆ be N, and when A is a substituent other than a substituent represented by the formula (2), it is also preferred that at least one of Y₁ to Y₈ be N.

A₁ is preferably a substituted or unsubstituted aryl group including 6 to 30 ring carbon atoms or a substituent represented by the formula (2).

The substituted or unsubstituted aryl group including 6 to 30 ring carbon atoms for A is preferably a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.

The substituent represented by the formula (2) for A₁ is preferably a group represented by the following formula (2-1):

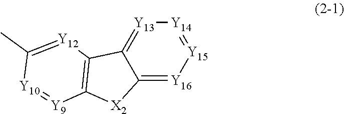

wherein in the formula (2-1), X₂, Y₉, Y₁₀, Y₁₂ and Y₁₃ to Y₁₆ are the same as those in the formula (2).

n is preferably 0.

L is preferably a substituted or unsubstituted arylene group including 10 to 30 ring carbon atoms or a substituted or unsubstituted heteroarylene group including 8 to 30 ring atoms. L is more preferably an arylene group or a heteroarylene group represented by any of the following formulas (4) to (8):

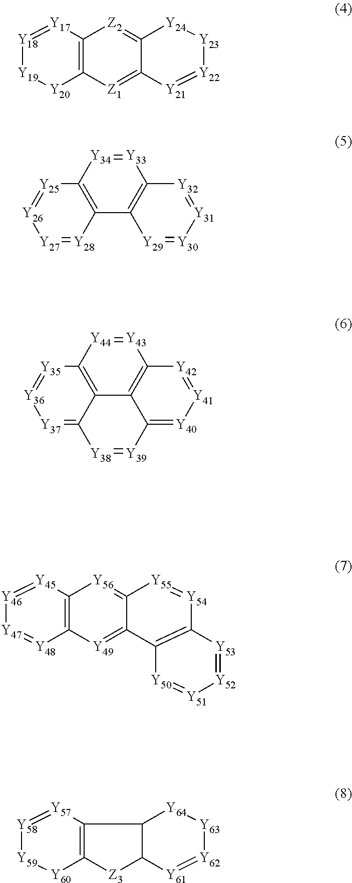

wherein in the formulas (4) to (8), Y₁₇ to Y₆₄ and Z₁ and Z₂ are independently C(Rₐ), N or P, another L or a carbon atom that is bonded to any of Y₁ to Y₄.

In the formula (8), Z₃ is independently C(Rₐ)₂, N(Rₐ) or P, another L or a nitrogen atom that is bonded to any of Y₁ to Y₄;

Rₐ is the same as that of the formula (1-1).

The compound represented by the formula (1-1) and by the formulas (1-2) and (1-3) mentioned later exhibits high electron-transporting properties since it has electron-transporting dibenzofuran (dibenzothiophene). Further, due to the presence of a phosphine oxide site that enhances electron-injecting properties, the compound has excellent electron-injecting properties and electron-transporting properties. Therefore, when the compound represented by the formula (1-1) is used as a material for an organic EL device, the device has excellent carrier balance, and as a result, an organic EL device has a prolonged life.

Therefore, the compound represented by the formula (1-1) of the invention can preferably be used as a material for an organic EL device. It is preferable to use it as a host material. The compound represented by the formula (1-2) is preferably used as an electron-transporting material. The compound represented by the formula (1-3) is preferably used as a hole-blocking material.

The compound represented by the following formula (1-2) is preferable as an electron-transporting material for an organic EL device.

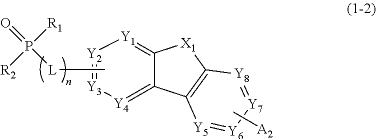

wherein in the formula (1-2),

X₁ is O or S;

Y₁ to Y₄ are independently C(Rₐ), N or a carbon atom that is bonded to L or P;

Y₅ to Y₈ are independently C(Rₐ), N or a carbon atom that is bonded to A₂;

L is O, S, a substituted or unsubstituted arylene group including 6 to 30 ring carbon atoms or a heteroarylene group including 5 to 30 ring atoms;

n is an integer of 0 to 3, and when n is 2 or more, plural Ls may be the same or different from each other;

R₁ and R₂ are independently a substituted or unsubstituted aryl group including 6 to 30 ring carbon atoms or a substituted or unsubstituted heteroaryl group including 5 to 30 ring atoms;

Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring atoms, a substituted or unsubstituted aralkyl group including 7 to 30 carbon atoms, a cyano group, a nitro group or a carboxy group,

when two or more Rₐs are present in the formula (1-2), plural of Rₐs may be the same or different from each other; and

A₂ is a hydrogen atom, a substituted or unsubstituted aryl group including 6 to 30 ring carbon atoms or a substituted or unsubstituted heteroaryl group including 5 to 30 ring atoms.

The compound represented by the formula (1-2) is a compound having a structure similar to that represented by the formula (1-1), except that A₂ is bonded to the dibenzofuran skeleton or the dibenzothiophene skeleton instead of A₁.

The structure or the like other than A₂ in the formula (1-2) are the same as those in the formula (1-1) mentioned above.

The substituted or unsubstituted aryl group including 6 to 30 ring carbon atoms for A₂ is preferably a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.

The substituted or unsubstituted heteroaryl group including 5 to 30 ring atoms for A₂ is preferably a substituted or unsubstituted nitrogen-containing heteroaryl group including 5 to 30 ring atoms.

The substituted or unsubstituted nitrogen-containing heteroaryl group including 5 to 30 ring atoms is preferably a substituted or unsubstituted pyridinyl group, a substituted or unsubstituted pyrimidinyl group, a substituted or unsubstituted triazinyl group, a substituted or unsubstituted imidazolyl group, a substituted or unsubstituted benzimidazolyl group, a substituted or unsubstituted carbazolyl group, a substituted or unsubstituted phenanthrolinyl group, a substituted or unsubstituted carbazolyl group or a substituted or unsubstituted azacarbazolyl group.

The substituted or unsubstituted heteroaryl group including 5 to 30 ring atoms for A₂ is preferably a group represented by the following formula (2), and is more preferably a group represented by the following formula (2-1):

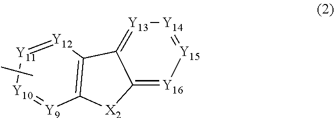

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ) or N; and

Rₐ is the same as Rₐ in the formula (1-2).

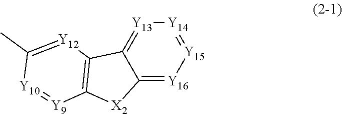

wherein in the formula (2-1),

X₂, Y₉, Y₁₀, Y₁₂ and Y₁₃ to Y₁₆ are the same as those in the formula (2).

The compound represented by the formula (1-3) of the invention is preferable as a hole-blocking material for an organic EL device.

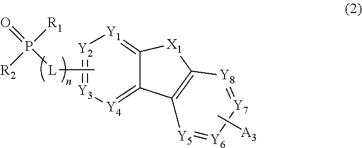

wherein in the formula (1-3),

X₁ is O or S;

Y₁ to Y₄ are independently C(Rₐ), N, or a carbon atom that is bonded to L or P;

Y₅ to Y₈ are independently C(Rₐ), N or a carbon atom that is bonded to A₃;

L is O, S, a substituted or unsubstituted arylene group including 6 to 30 ring carbon atoms or a substituted or unsubstituted heteroarylene group including 5 to 30 ring atoms;

n is an integer of 0 to 3, and when n is 2 or more, plural Ls may be the same or different from each other;

R₁ and R₂ are independently a substituted or unsubstituted aryl group including 6 to 30 ring carbon atoms or a substituted or unsubstituted heteroaryl group including 5 to 30 ring atoms;

Rₐs are independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group or a carboxyl group;

when two or more Rₐs are present in the formula (1-3), plural Rₐs may be the same or different from each other;

A₃ is a hydrogen atom, a substituted or unsubstituted phenyl group, a substituted or unsubstituted meta-biphenylyl group, a substituted or unsubstituted meta-terphenyl group, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl, a substituted or unsubstituted azacarbazolyl group, a substituted or unsubstituted benzimidazolyl group or a substituent represented by the following formula (2), provided that when A₃ is a hydrogen atom, n is an integer of 1 to 3;

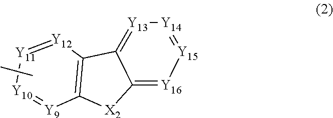

wherein in the formula (2),

X₂ is O or S;

Y₉ to Y₁₂ are independently C(Rₐ), N, or a carbon atom that is bonded to any of Y₅ to Y₈;

Y₁₃ to Y₁₆ are independently C(Rₐ) or N; and

Rₐ is the same as Rₐ in the formula (1-3).

The compound represented by the formula (1-3) is a compound having a structure similar to that represented by the formula (1-1), except that A₃ is bonded to the dibenzofuran skeleton or the dibenzothiophene skeleton instead of A₁.

The structure or the like other than A₃ in the formula (1-3) are the same as those in the formula (1-1) mentioned above.

A₃ is preferably a substituted or unsubstituted phenyl group, a substituted or unsubstituted meta-biphenylyl group, a substituted or unsubstituted meta-terphenyl group or a substituent represented by the formula (2).

Among these, each of the phenyl group, the meta-biphenyl group and the meta-terphenyl group is a skeleton having a large triplet energy. Due to the presence of such a skeleton, energy transfer from the emitting layer to the hole-blocking layer is prevented, whereby lowering in luminous efficiency can be prevented effectively.

The substituent represented by the formula (2) for A₃ is preferably a substituent represented by the following formula (2-1):

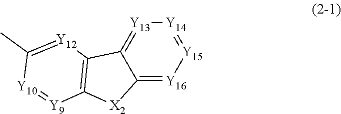

wherein in the formula (2-1),

X₂, Y₉, Y₁₀, Y₁₂ and Y₁₃ to Y₁₆ are the same as those in the formula (2).

Hereinbelow, an explanation will be made on examples of each group of the compound represented by the above-mentioned formulas (1-1), (1-2) and (1-3).

As the alkyl group including 1 to 30 carbon atoms, a linear or branched alkyl group can be given. Specific examples thereof include a methyl group, an ethyl group, a propyl group, an isopropyl group, an n-butyl group, an isobutyl group, a sec-butyl group, a tert-butyl group, an n-pentyl group, an n-hexyl group, an n-heptyl group, an n-octyl group or the like. Preferable examples include a methyl group, an ethyl group, a propyl group, an isopropyl group, an n-butyl group, an isobutyl group, a sec-butyl group and a tert-butyl group. A methyl group, an ethyl group, a propyl group, an isopropyl group, an n-butyl group, a sec-butyl group and a tert-butyl group are more preferable.

As the fluoroalkyl group including 1 to 30 carbon atoms, a group obtained by substituting the alkyl group mentioned above with one or more fluorine atoms can be given. Specific examples thereof include a fluoromethyl group, a difluoromethyl group, a trifluoromethyl group, a fluoroethyl group, a trifluoromethylethyl group and a pentafluoroethyl group. Among these, a trifluoromethyl group and a pentafluoroethyl group are preferable.

As the cycloalkyl group including 3 to 30 ring carbon atoms, a cyclopropyl group, a cyclobutyl group, a cyclopentyl group, a cyclohexyl group, a 1-adamantyl group, a 2-adamentyl group, a 1-norbornyl group, a 2-norbornyl group or the like can be mentioned. Among these, a cyclopentyl group and a cyclohexyl group are preferable.

The “carbon atoms that form a ring” means carbon atoms that form a saturated ring, an unsaturated ring or an aromatic ring.

The aryl group including 6 to 30 ring carbon atoms is preferably an aryl group including 6 to 20 ring carbon atoms.

Specific examples of the aryl group include a phenyl group, a naphthyl group, an anthryl group, a phenanthryl group, a naphthacenyl group, a pyrenyl group, a chrysenyl group, a benz[c]phenanthryl group, a benzo[g]phenanthryl group, a triphenylenyl group, a fluorenyl group, a benzofluorenyl group, a dibenzofluorenyl group, a biphenylyl group, a terphenyl group, a quarterphenyl group and a fluoranthenyl group. Among these, a naphthyl group, an anthryl group, a phenanthryl group, a naphthacenyl group, a pyrenyl group and a chrysenyl group are preferable.

As the arylene group including 6 to 30 ring carbon atoms, the divalent group mentioned above can be given.

The heteroaryl group including 5 to 30 ring atoms is preferably a heteroaryl group including 5 to 20 ring atoms.

As specific examples of the heteroaryl group, a pyrrolyl group, a pyrazinyl group, a pyridinyl group, a pyrimidinyl group, a triazinyl group, an indolyl group, an isoindolyl group, an imidazolyl group, a furyl group, a benzofuranyl group, an isobenzofuranyl group, a dibenzofuranyl group, a dibenzothiophenyl group, an azadibenzofuranyl group, an azadibenzothiophenyl group, a diazadibenzofuranyl group, a diazadibenzothiophenyl group, a quinolyl group, an isoquinolyl group, a quinoxanyl group, a carbazolyl group, a phenanthrydinyl group, an acridinyl group, a phenanthrolinyl group, a phenadinyl group, a phenothiadinyl group, a phenoxadinyl group, an oxazolyl group, an oxadiazolyl group, a furazanyl group, a thienyl group, a benzothiophenyl group, a dihydroacridinyl group, an azacarbazolyl group, a diazacarbazolyl group, a quinazolinyl group or the like can be given. Among these, a pyridinyl group, a primidinyl group, a triazinyl group, a dibenzofuranyl group, a dibenzothiophenyl group, an azadibenzofuranyl group, an azadibenzothiophenyl group, a diazadibenzofuranyl group, a diazadibenzothiophenyl group, a carbazolyl group, an azacarbazolyl group and a diazacarbazolyl group are preferable.

As the heteroarylene group including 5 to 30 ring atoms, the divalent group mentioned above can be given.

The aralkyl group including 7 to 30 carbon atoms is represented by —Y—Z. As examples of Y, examples of the alkylene group corresponding to examples of the alkyl group mentioned above can be given. As examples of Z, examples of the aryl group mentioned above can be given.

The aryl part of the aralkyl group preferably includes 6 to 20 ring carbon atoms. The alkyl part of the aralkyl group preferably includes 1 to 8 carbon atoms. As the aralkyl group, a benzyl group, a phenylethyl group and a 2-phenylpropane-2-yl group can be given, for example.

As the substituent of the “substituted or unsubstituted . . . ” of each group mentioned above, in addition to the alkyl group, the cycloalkyl group, the fluoroalkyl group, the aryl group and the heteroaryl group mentioned above, a halogen atom (fluorine, chlorine, bromine, iodine or the like can be given, with fluorine being preferable), a hydroxyl group, a nitro group, a cyano group, a carboxy group, an aryloxy group or the like can be mentioned.

The method for producing the compounds represented by the formulas (1-1), (1-2) and (1-3), which are the compounds of the invention, is not particularly restricted, and the compounds of the invention can be produced by a known method.

Specific examples of the compounds represented by the formulas (1-1), (1-2) and (1-3) (hereinafter often referred to as the compounds of the invention) are shown below:

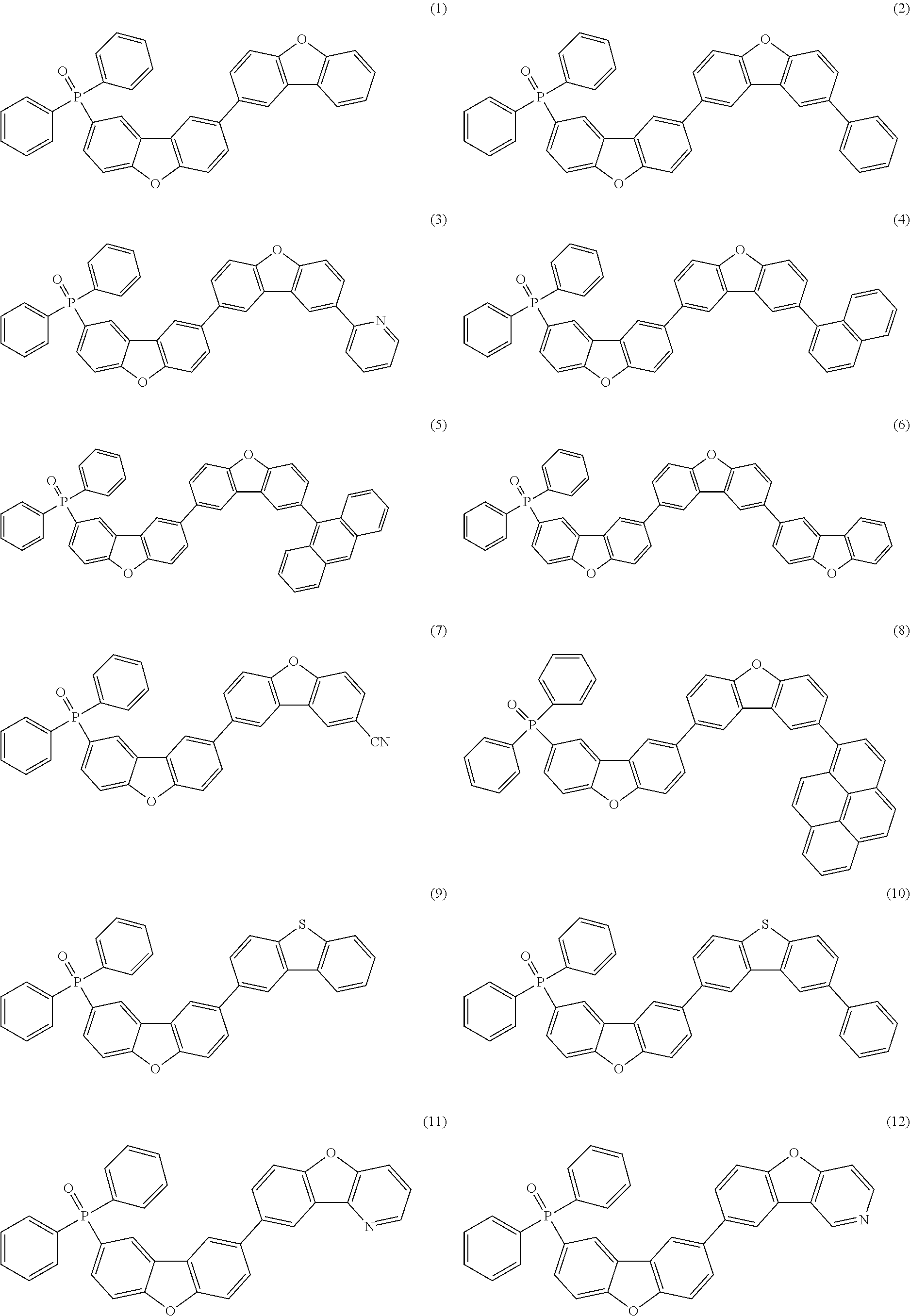

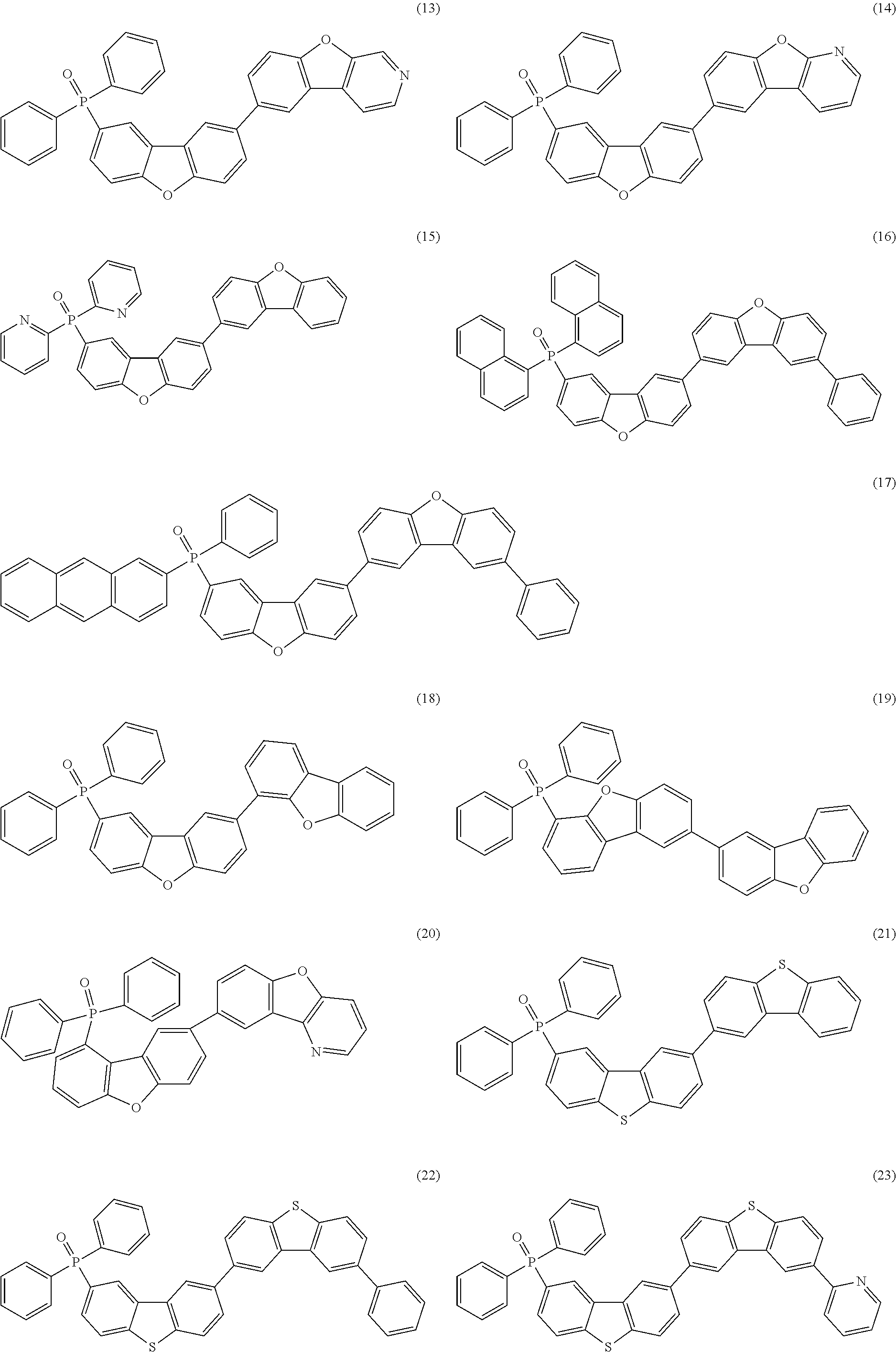

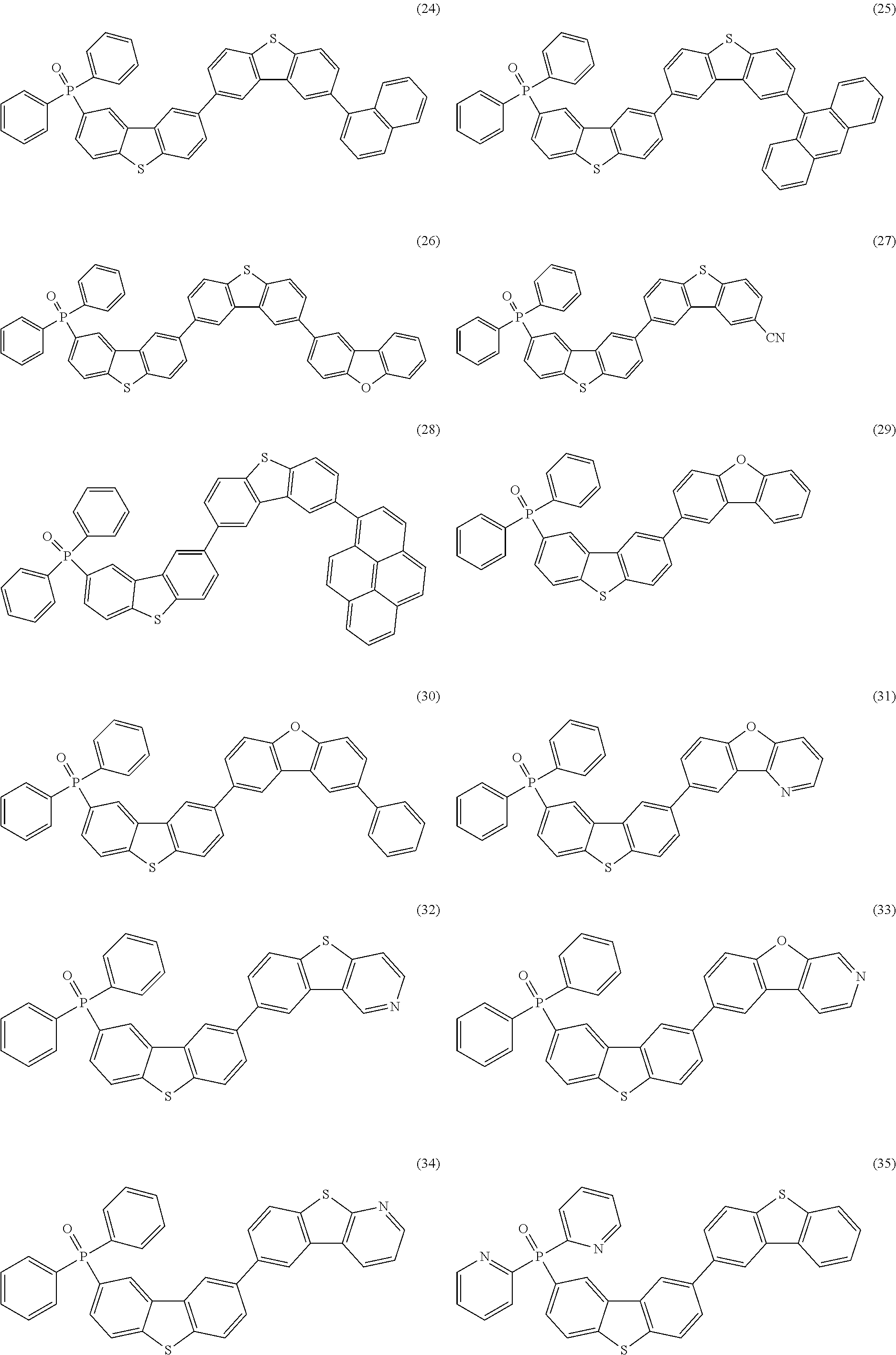

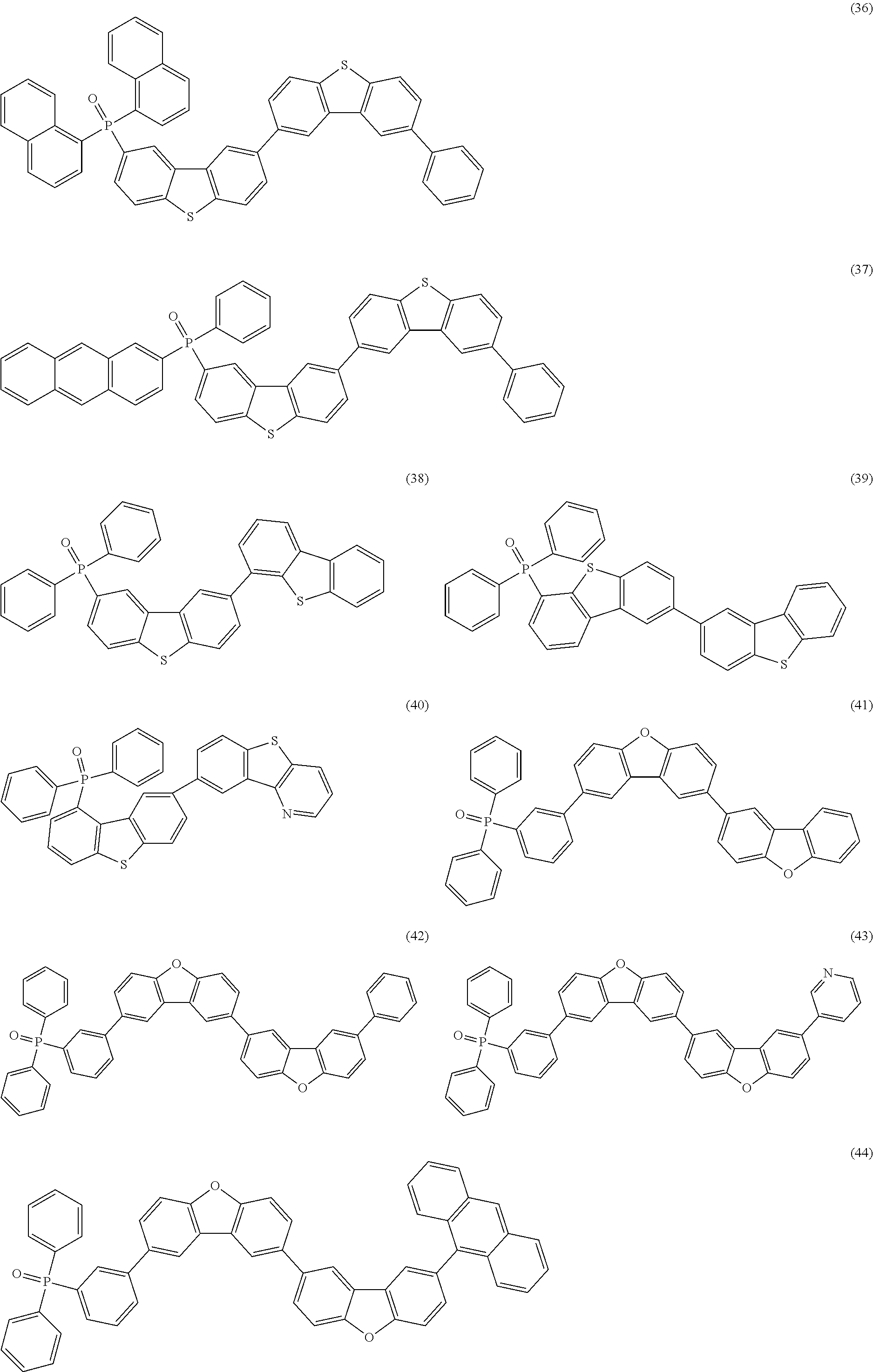

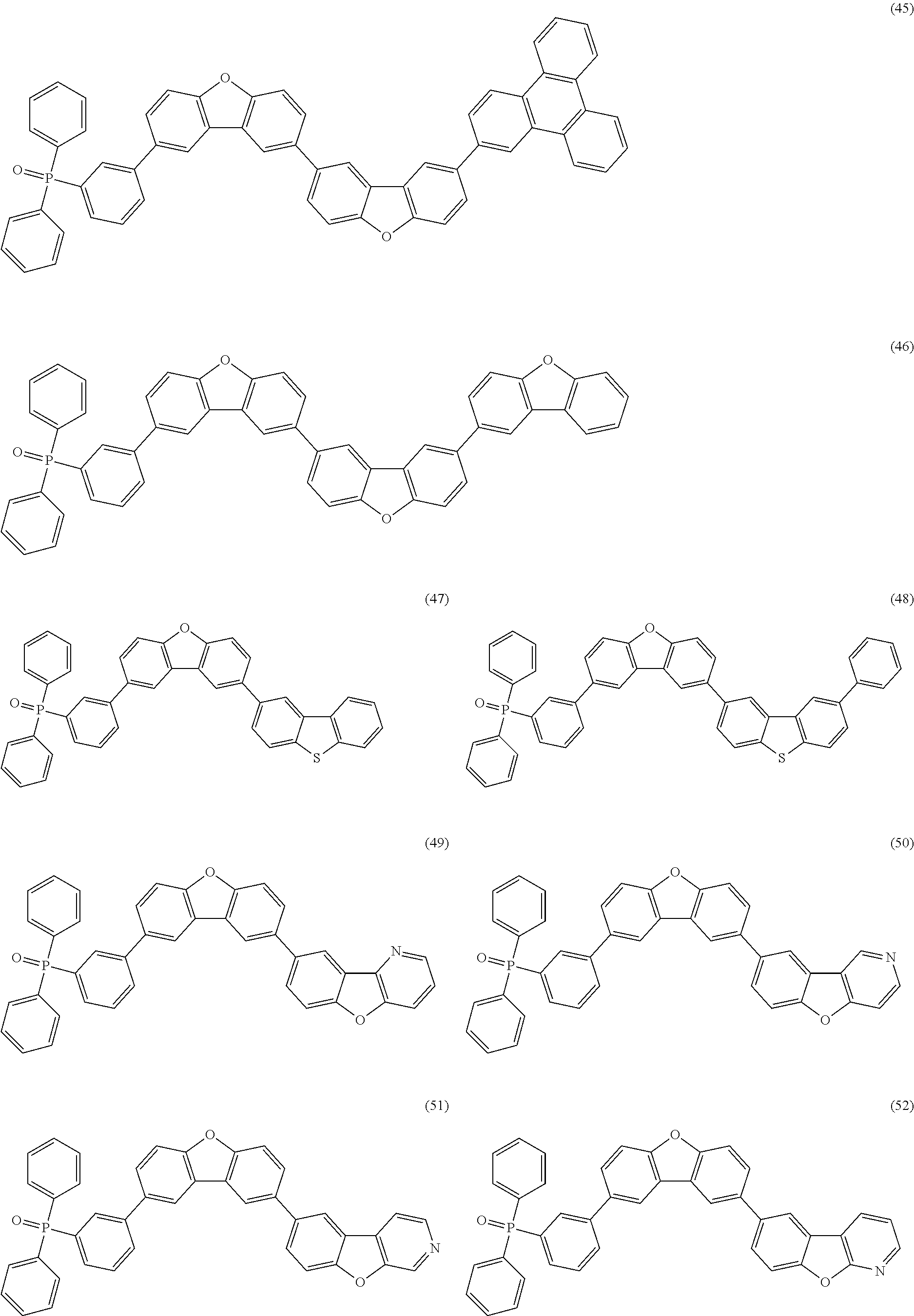

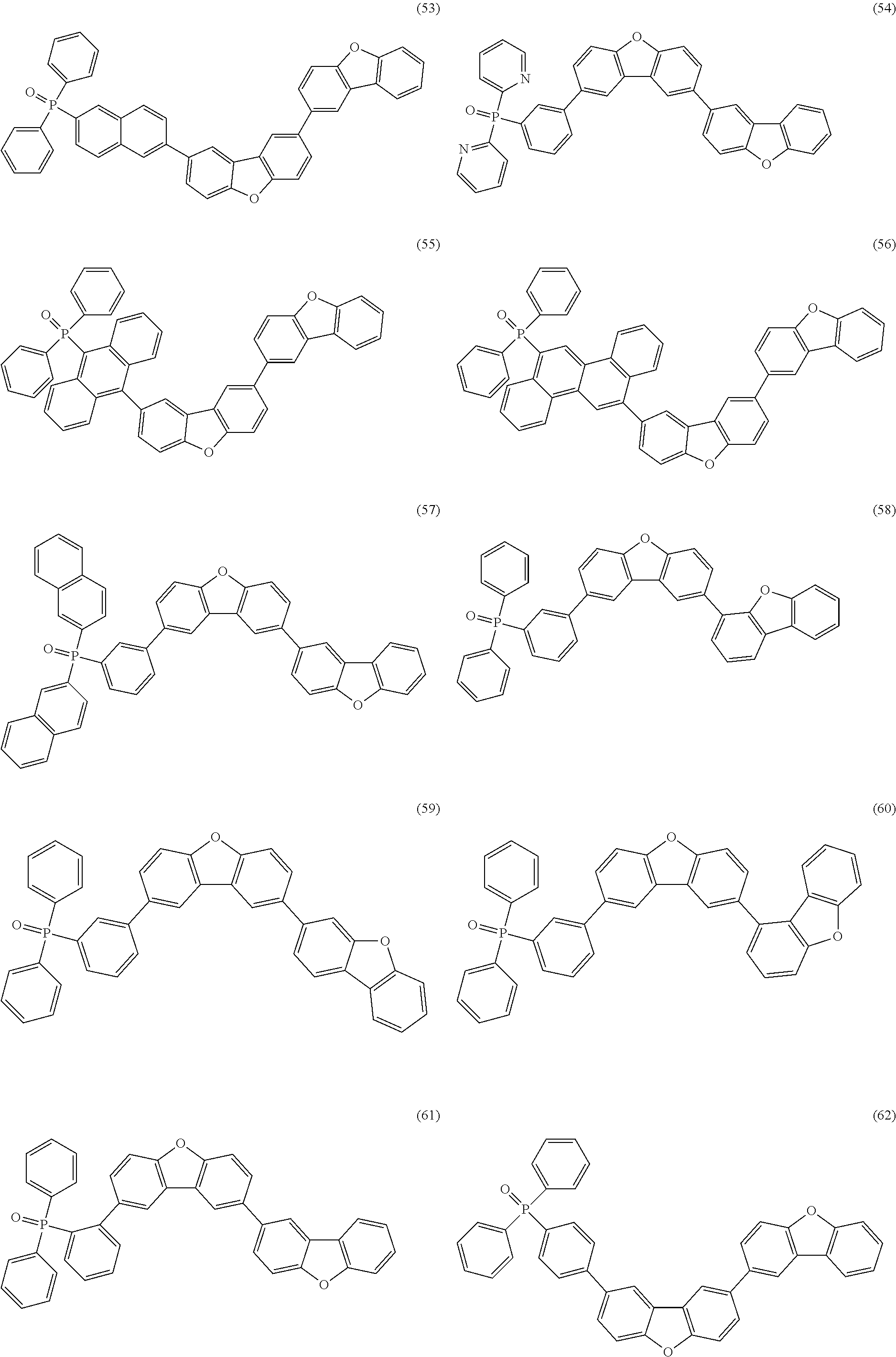

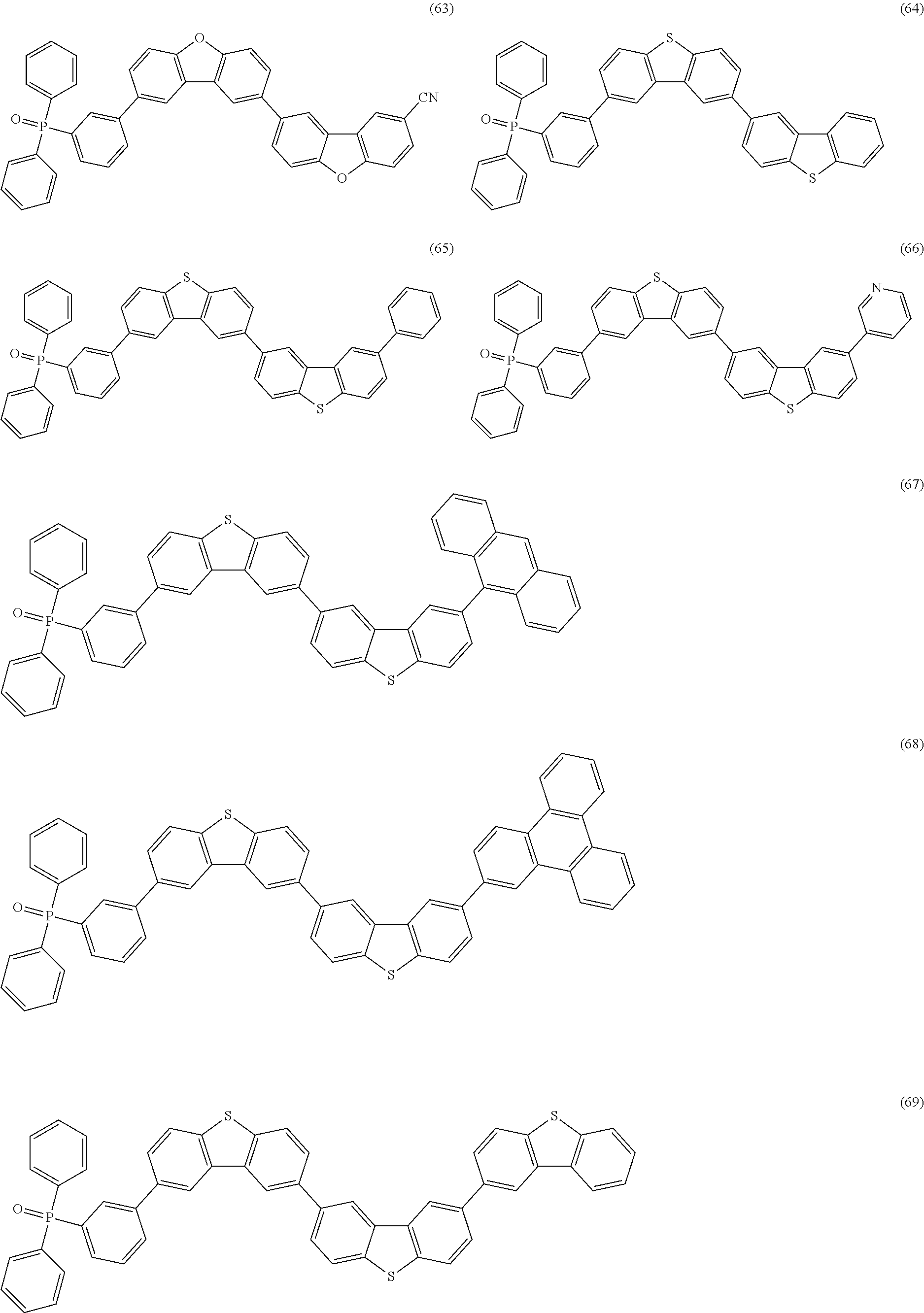

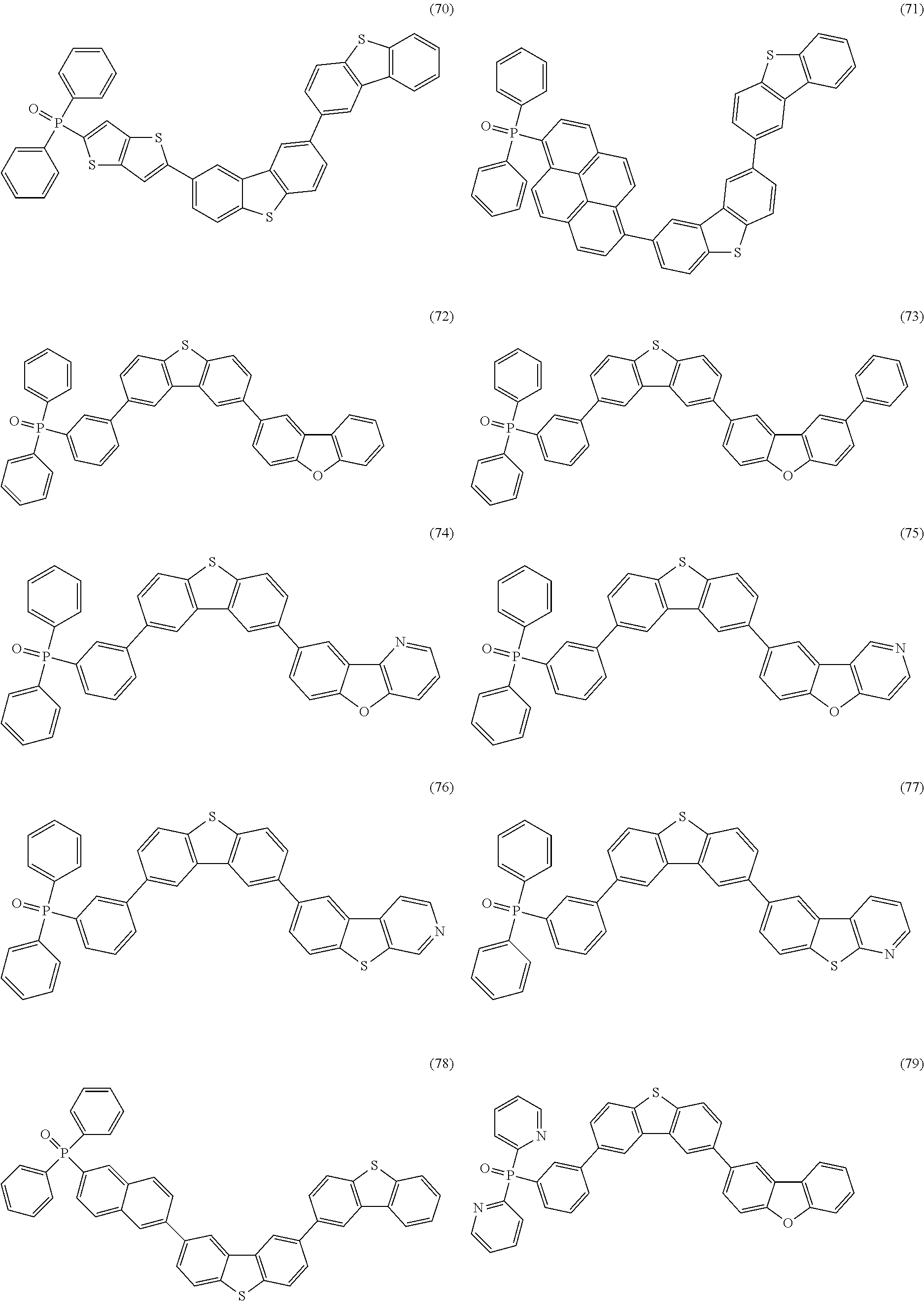

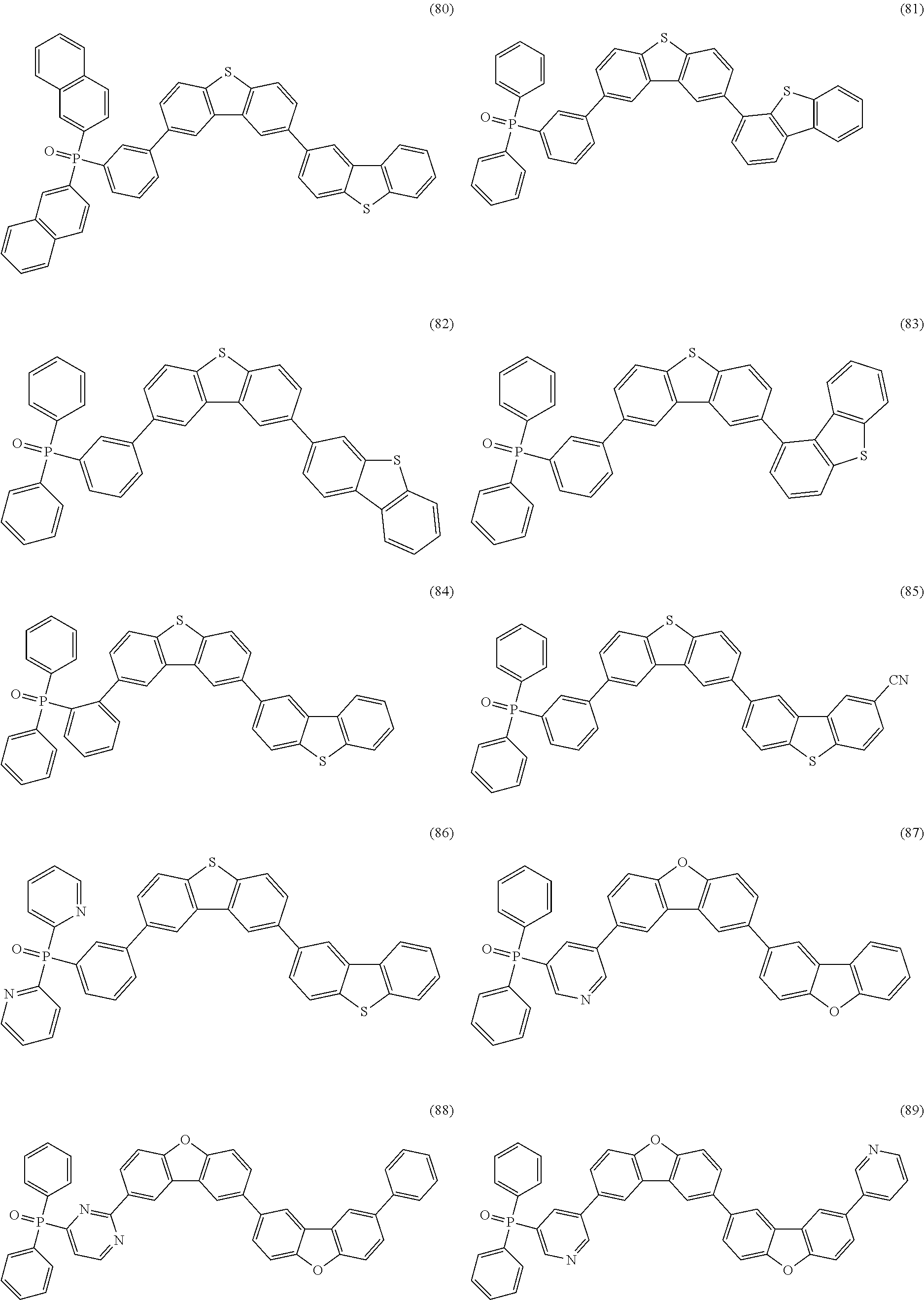

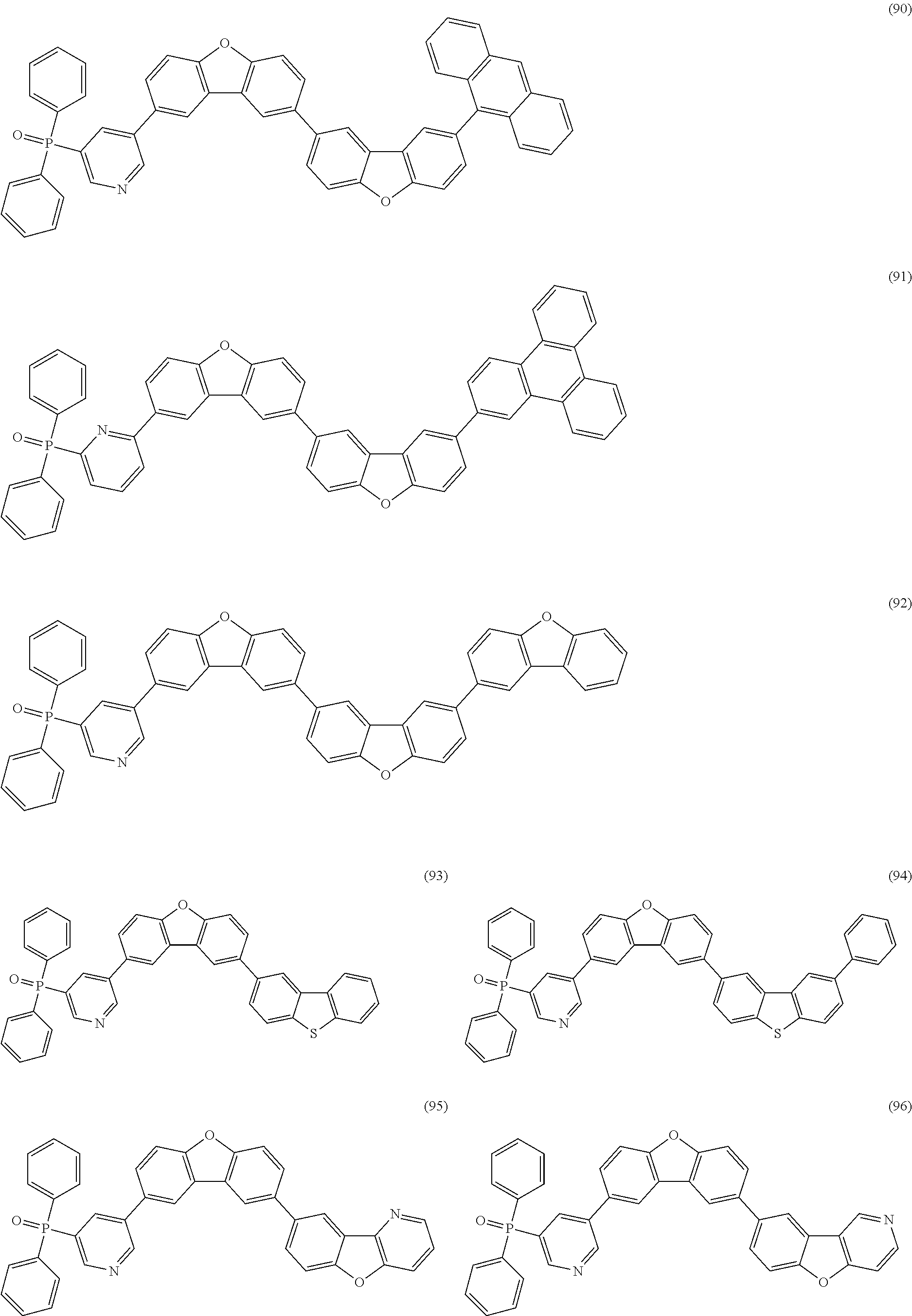

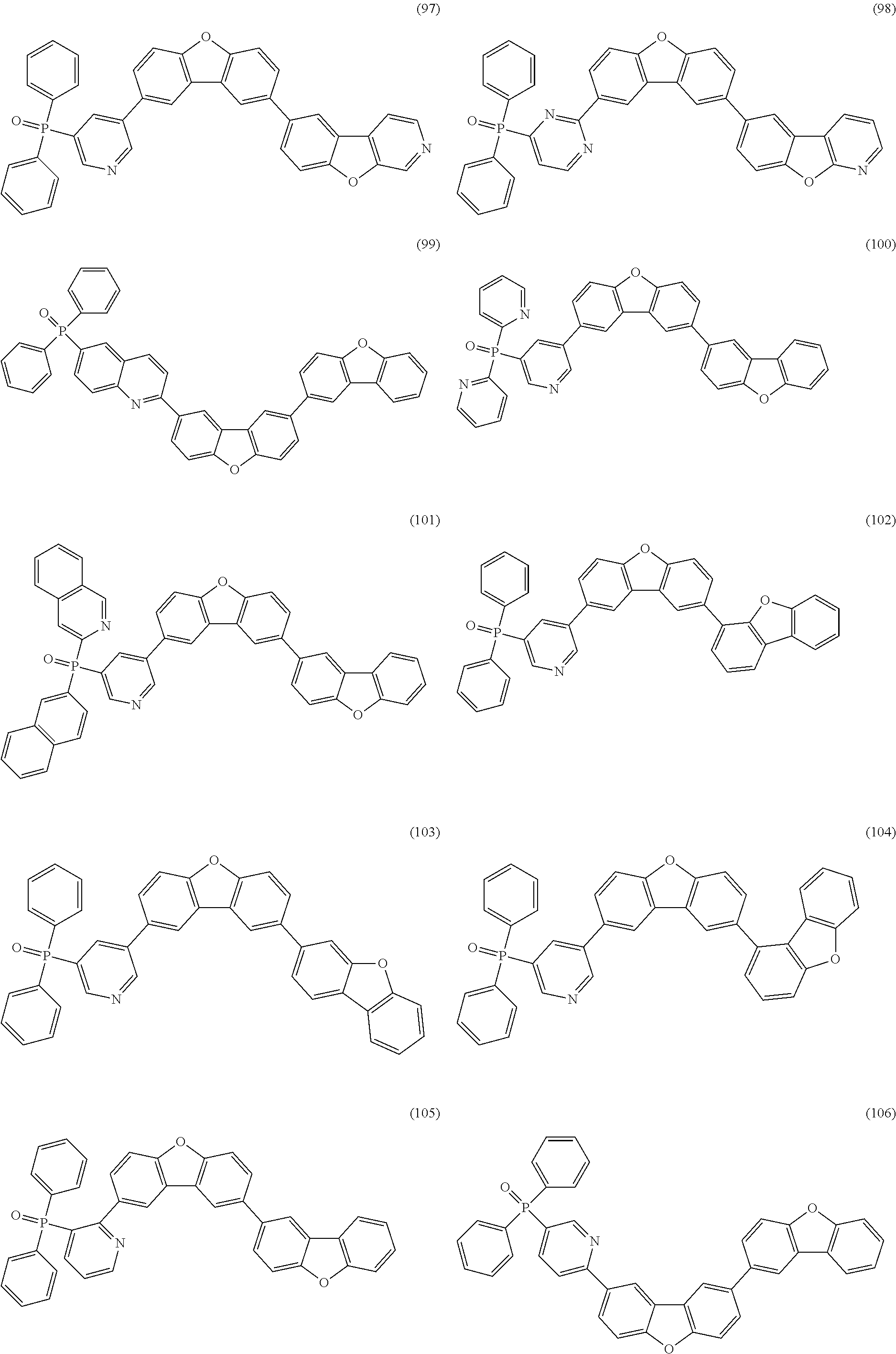

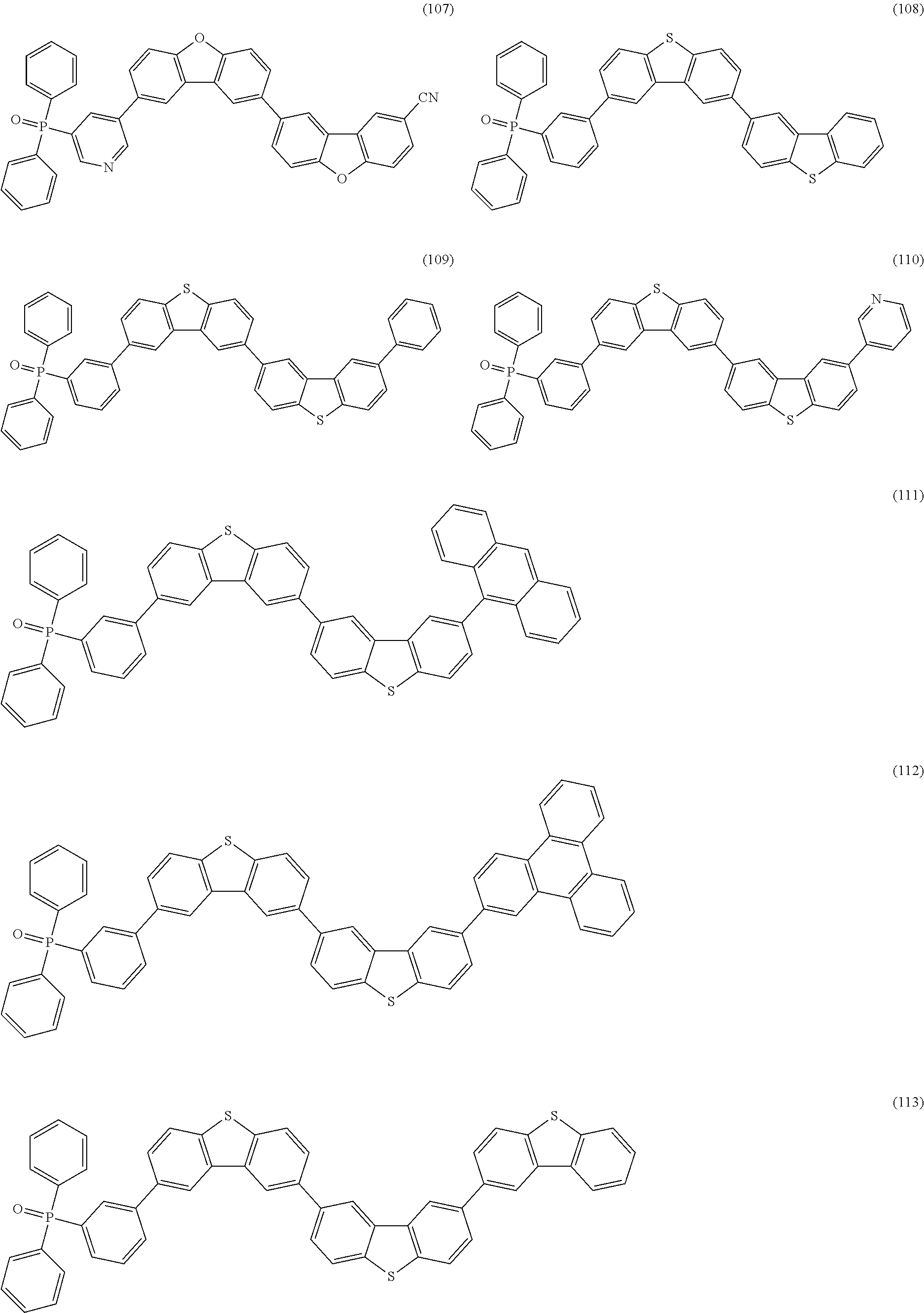

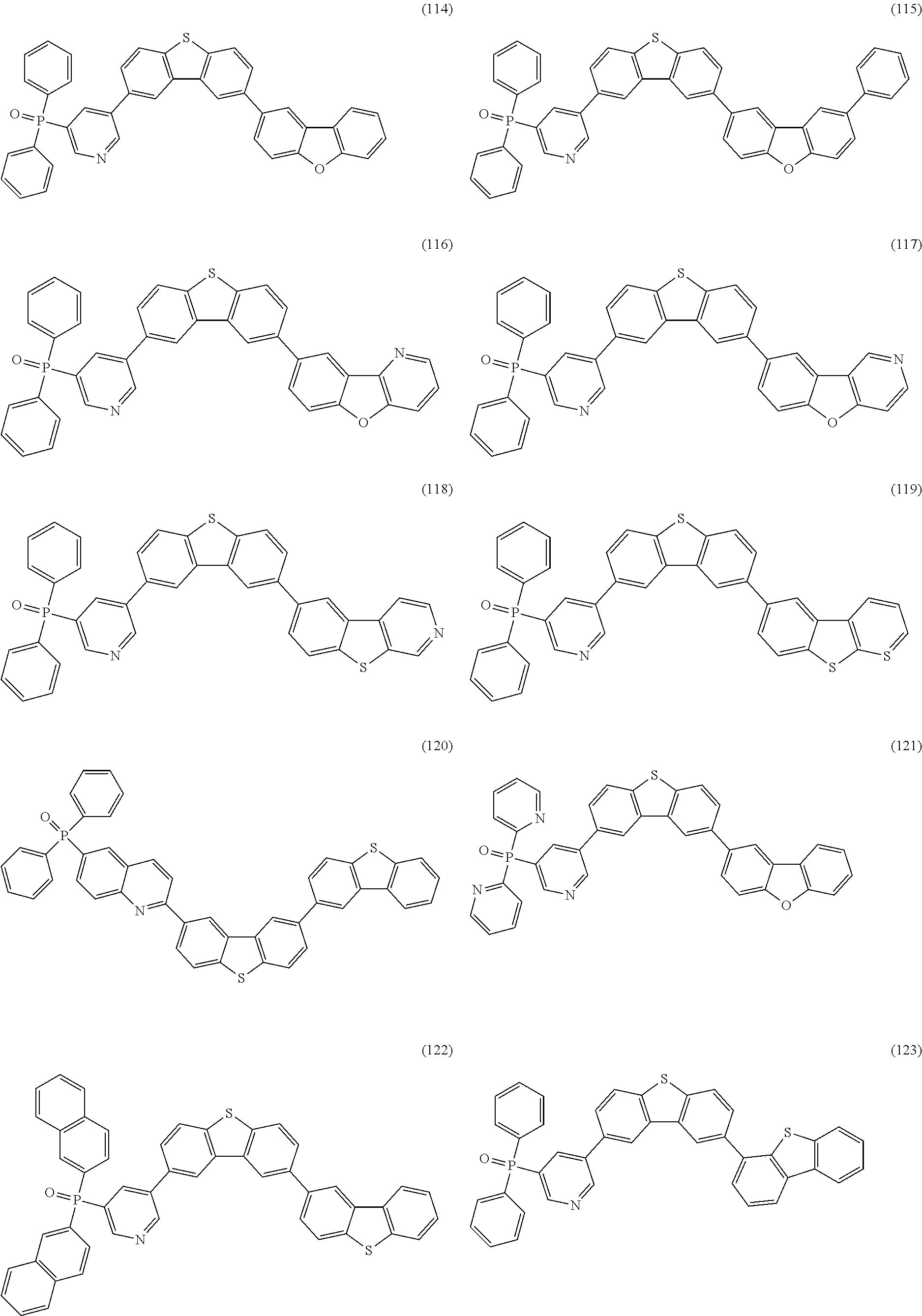

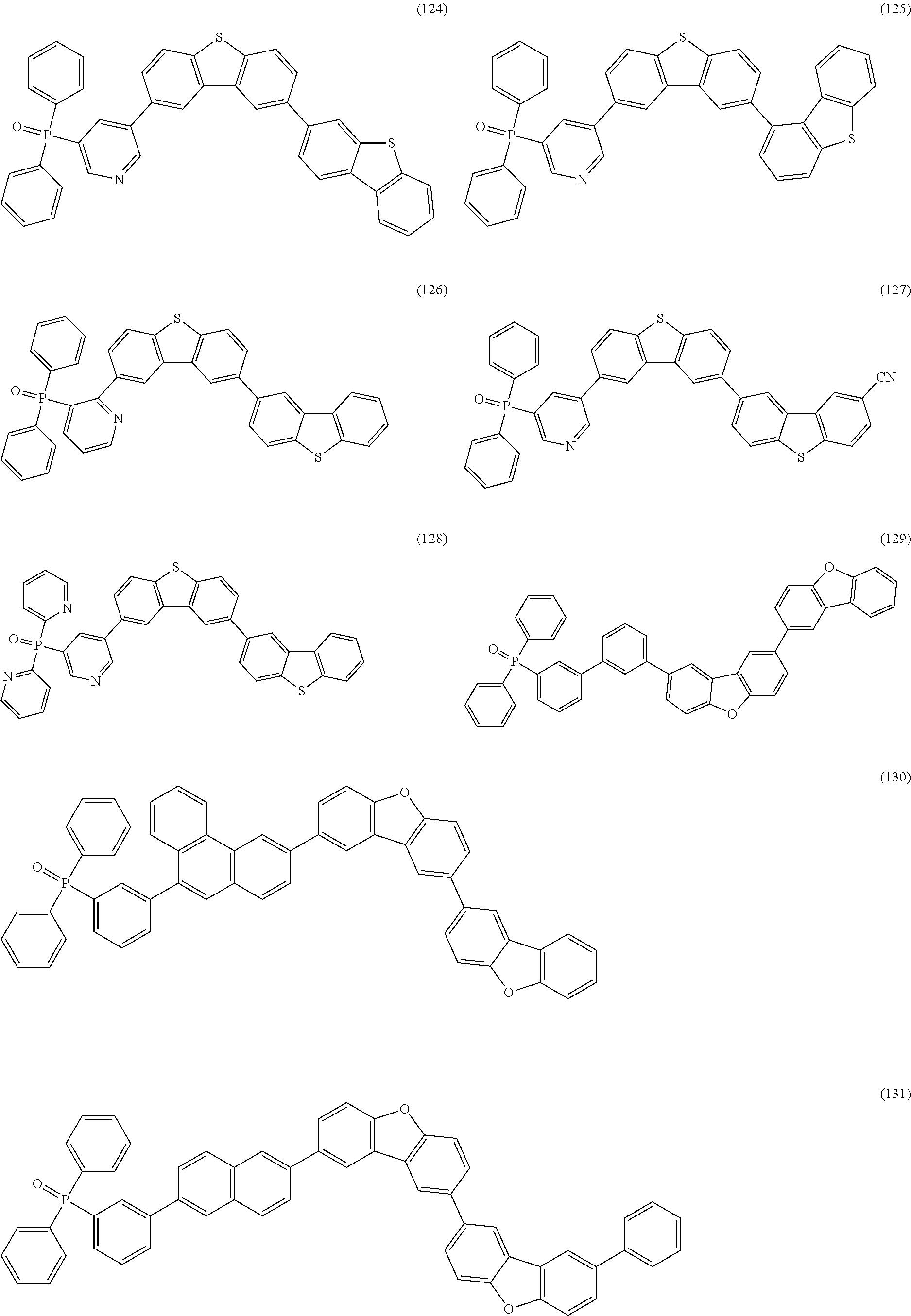

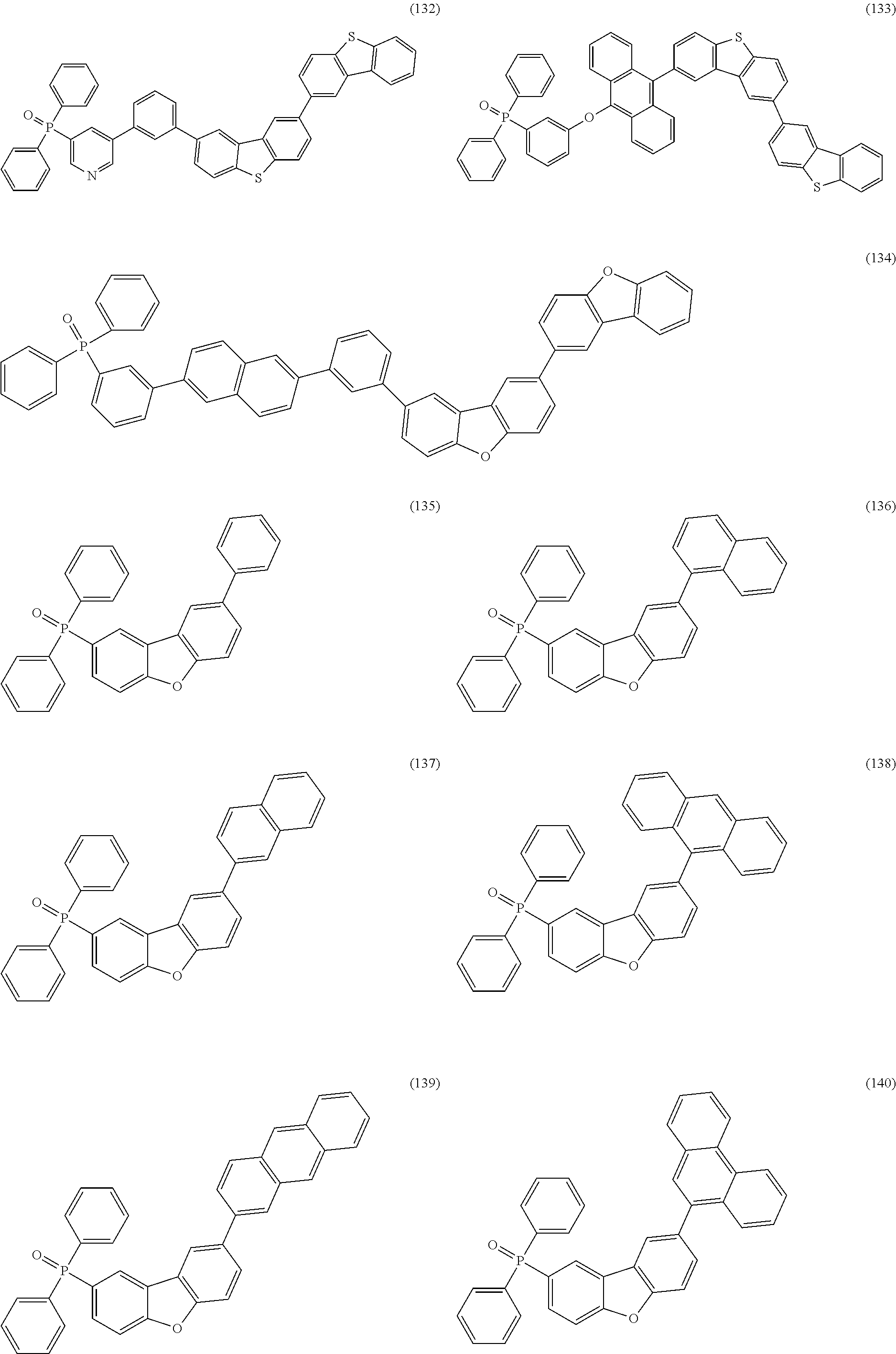

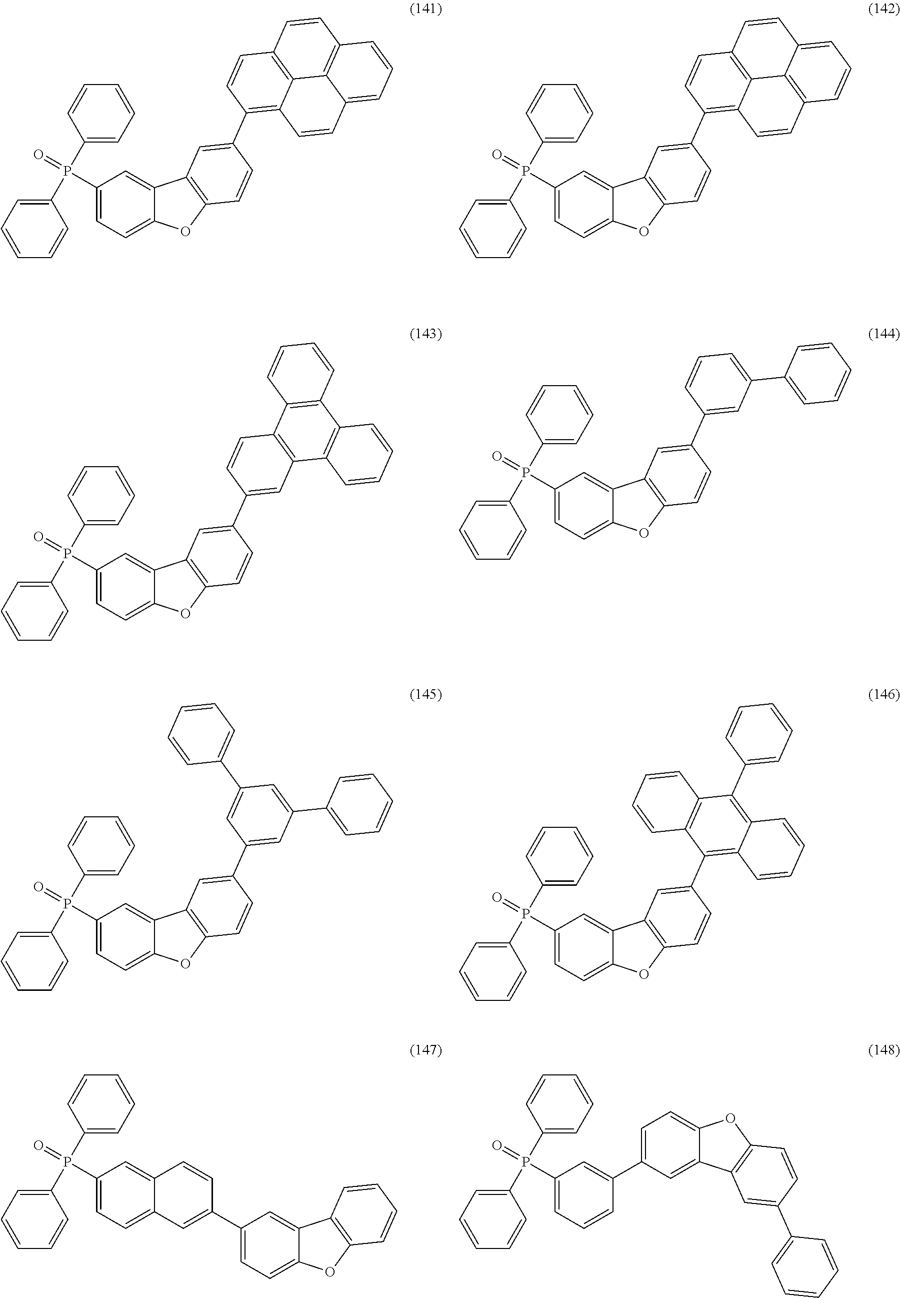

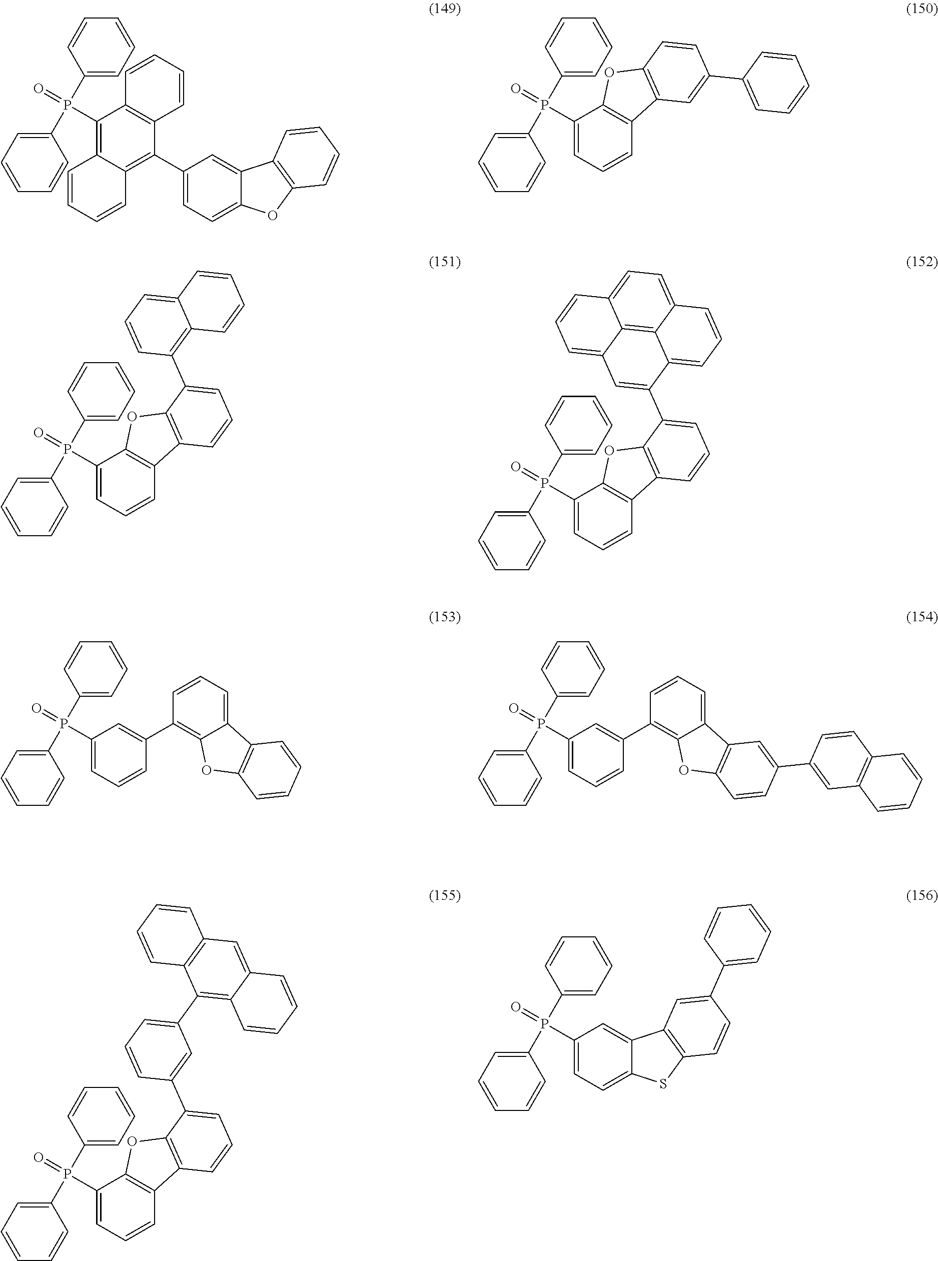

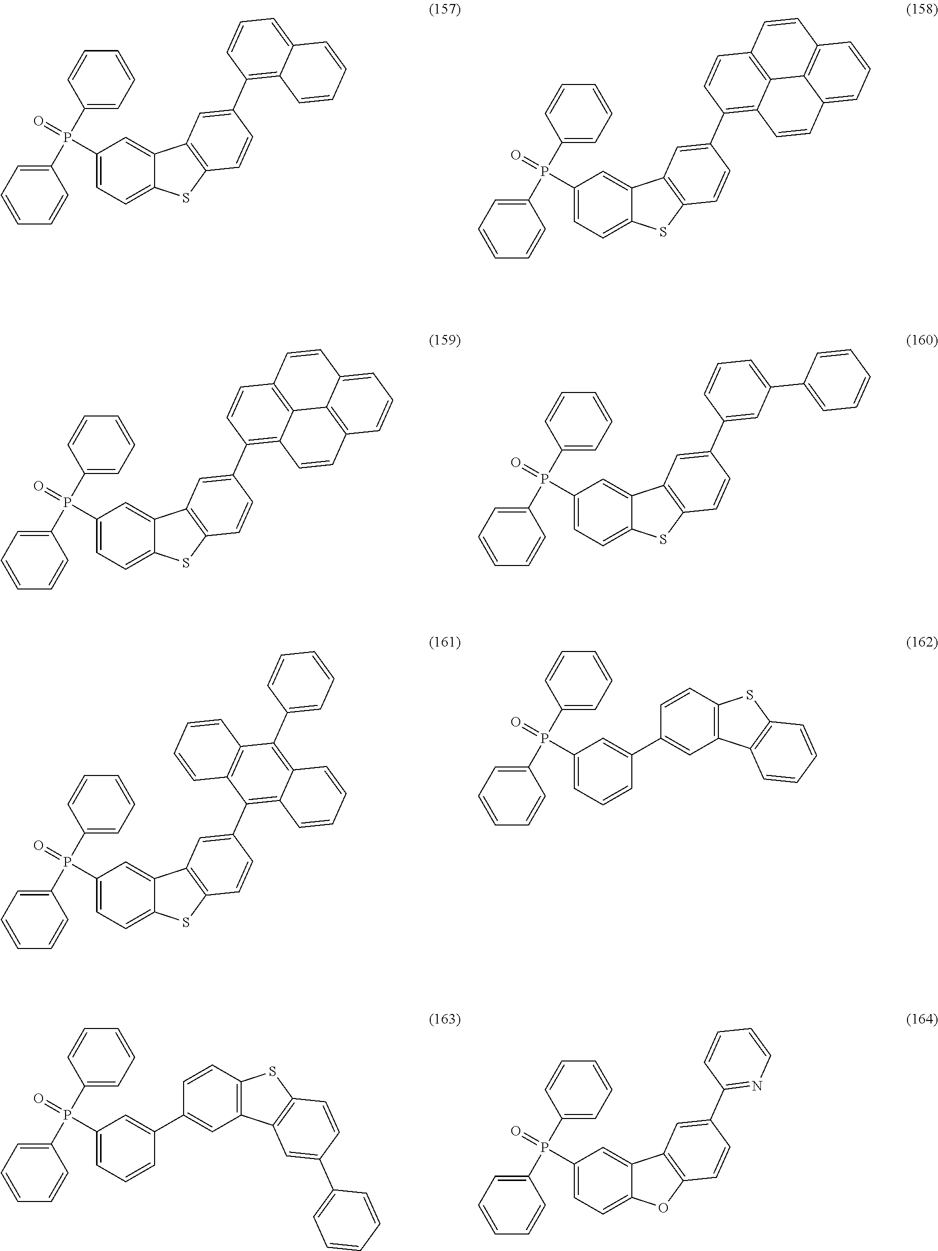

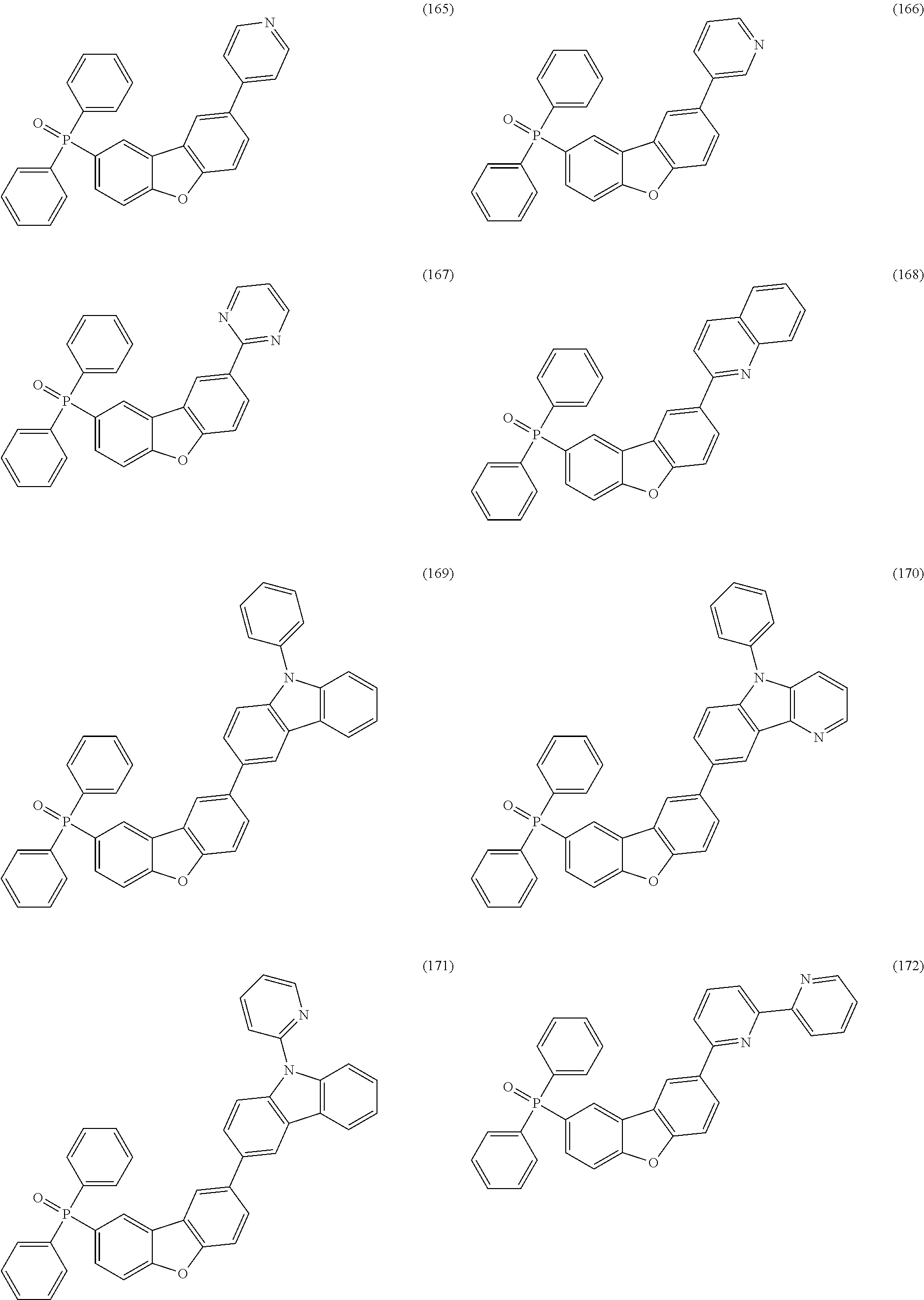

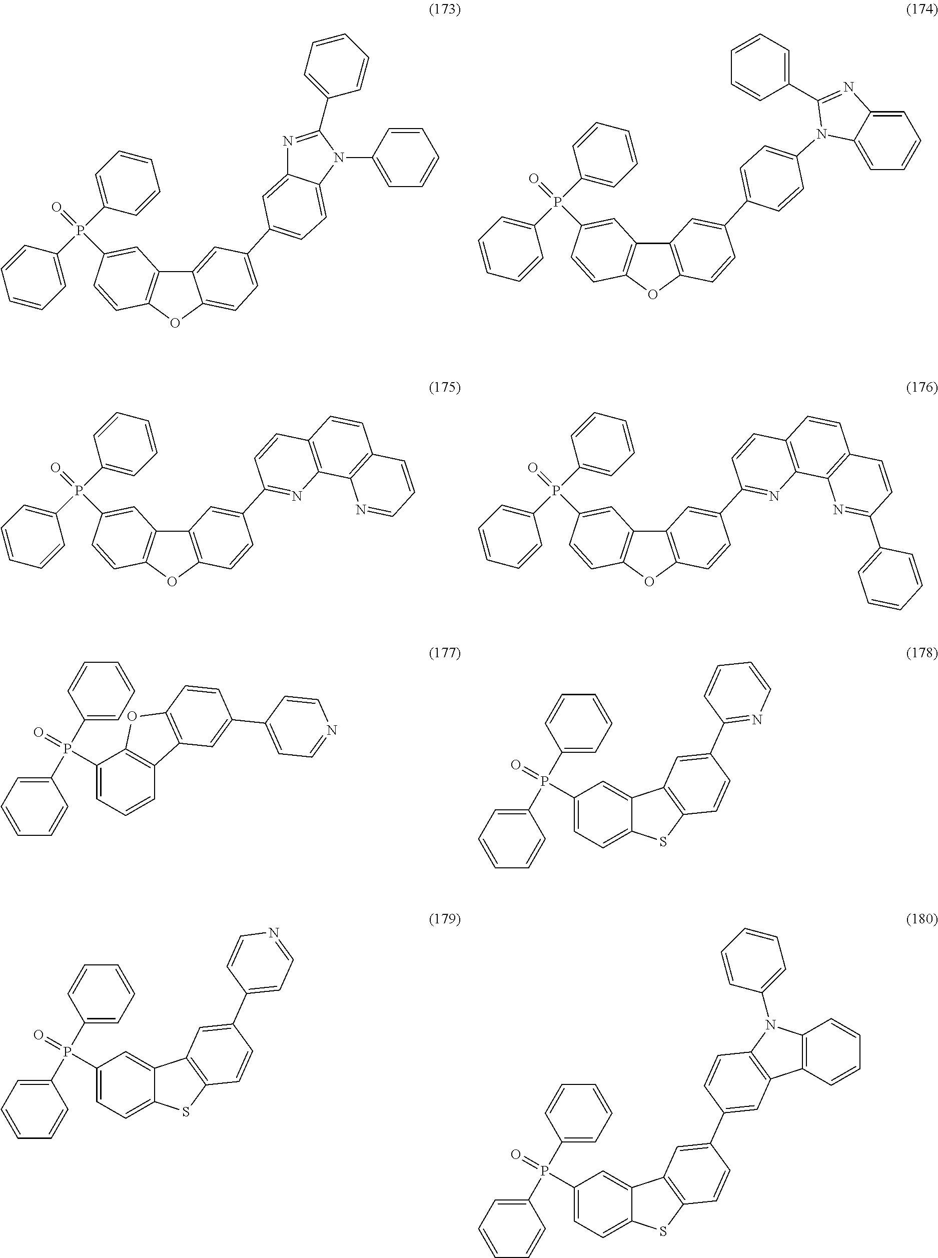

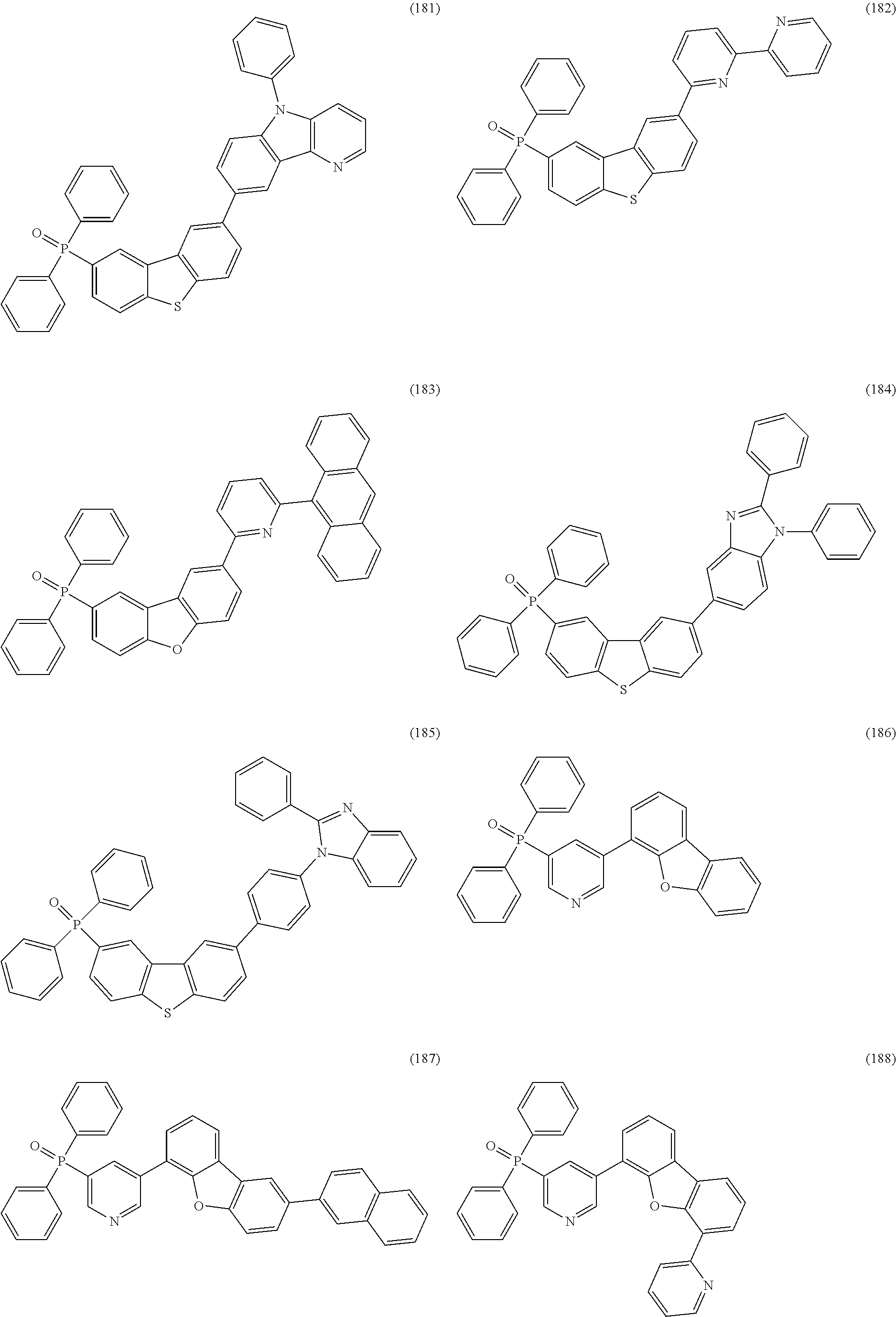

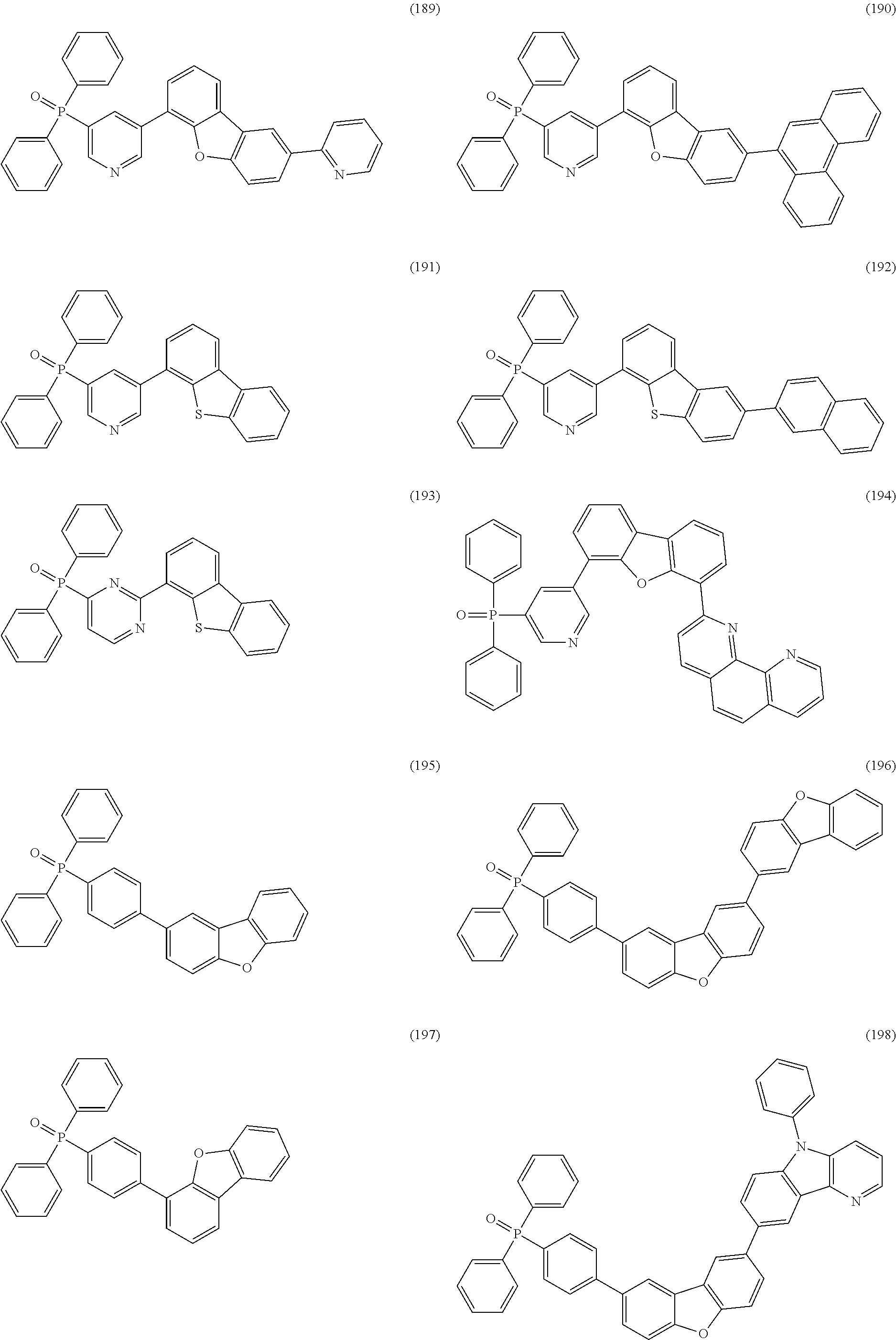

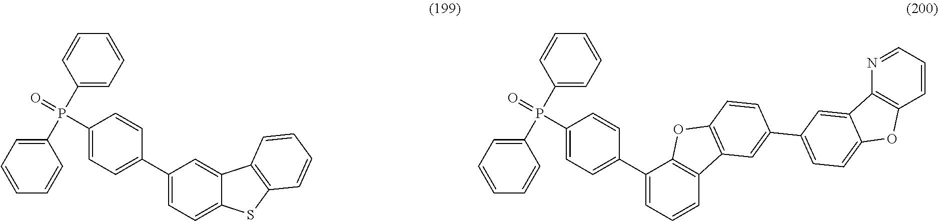 [SMILES: O=P(c1ccccc1)(c1ccccc1)c1ccc(-c2ccc3sc4ccccc4c3c2)cc1 ; O=P(c1ccccc1)(c1ccccc1)c1ccc(-c2cccc3c2oc2ccc(-c4ccc5oc6cccnc6c5c4)cc23)cc1]

### [Organic EL Device]

The compound of the invention that is represented by the formula (1-1) can be preferably used as a material for an organic EL device. The compound of the invention that is represented by the formula (1-2) is an electron-transporting material for an organic EL device. The compound of the invention that is represented by the formula (1-3) is a hole-blocking material for an organic EL device (hereinbelow, these materials will often comprehensively be referred to as the material for an organic EL device of the invention).

The material for an organic EL device of the invention may comprise only the compound of the invention, and may comprise other materials in addition to the compound of the invention.

Subsequently, the organic EL device of the invention will be explained.

A first EL device of the invention comprises, between an anode and a cathode, one or more organic thin film layers including an emitting layer. At least one layer of the organic thin film layers comprises a material for an organic EL device that comprises the compound represented by the formula (1-1).

A second organic EL device of the invention comprises one or more organic thin film layers including an emitting layer between an anode and a cathode and an electron-transporting zone between the cathode and the emitting layer. The electron-transporting zone comprises a material for an organic EL device that comprises the compound represented by the formula (1-2).

A third organic EL device of the invention comprises, between the anode and the cathode, one or more organic thin film layers including an emitting layer, and between the cathode and the emitting layer, a hole-barrier (blocking) layer. The hole-barrier (blocking) layer comprises a hole-blocking material for an organic EL device that comprises the compound represented by the formula (1-3). The third organic EL device preferably further comprises, between the cathode and the emitting layer, an electron-transporting zone.

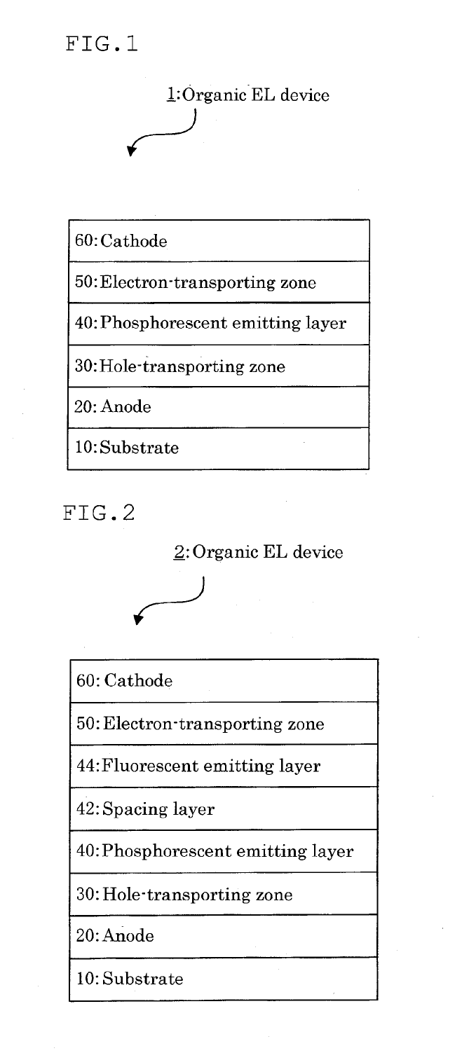

FIG. 1 is a schematic view showing the layer configuration of one embodiment of the organic EL device of the invention.

An organic EL device 1 has a configuration in which, on a substrate 10, an anode 20, a hole-transporting zone 30, a phosphorescent emitting layer 40, an electron-transporting zone 50 and a cathode 60 are stacked in this order.

The hole-transporting zone 30 means a hole-transporting layer and/or a hole-injecting layer or the like. Similarly, the electron-transporting zone 50 means an electron-transporting layer and/or an electron-injection layer or the like. They are not necessarily be formed. It is preferred that one or more of these layers be formed.

In this device 1, the organic thin film layer is each organic layer provided in the hole-transporting zone 30 and each organic layer provided in the phosphorescent layer 40 and an electron-transporting zone 50. At least one layer of these organic thin film layers comprises a material for an organic EL device of the invention. Due to such a configuration, the organic EL device can have a high efficiency. Further, the organic EL device of the invention can be driven at a low voltage.

The content of this material relative to the organic thin film layer containing the material for an organic EL device of the invention is preferably 1 to 100 mass %.

In the organic EL device of the invention, it is preferred that the phosphorescent emitting layer 40 comprise the material for an organic EL device of the invention that comprises the compound represented by the formula (1-1). In particular, it is preferred that the material for an organic EL device of the invention be used as a host material of the emitting layer.

The material for an organic EL device comprising the compound represented by the formula (1-1) of the invention has a sufficiently large triplet energy. Therefore, even if a blue phosphorescent dopant material is used, the triplet energy of the phosphorescent dopant material can be confined efficiently within the emitting layer. Further, the material for an organic EL device of the invention can be used not only in a blue-emitting layer but also in an emitting layer that emits light with a longer wavelength (green to red, or the like).

The material for an organic EL device of the invention has excellent carrier injection balance, and hence, can realize an organic EL device having a high efficiency and a low driving voltage. Further, the material for an organic EL device of the invention has an advantage effect of prolonging the life of an organic EL device due to improved carrier balance.

The phosphorescent emitting layer contains a phosphorescent emitting material (phosphorescent dopant). As the phosphorescent dopant, metal complex compounds can be given. Preferable is a compound having a metal atom selected from Ir, Pt, Os, Au, Cu, Re and Ru and a ligand. The ligand preferably has an ortho-metal bond.

In respect of a high phosphorescent quantum yield and capability of improving external quantum yield of an emitting device, the phosphorescent dopant is preferably a compound having a metal atom selected from Ir, Os and Pt. Further preferable are a metal complex such as an iridium complex, an osmium complex and a platinum complex. Among them, an iridium complex and a platinum complex are more preferable, and an ortho-metalated iridium complex is most preferable.

The dopant may be used singly or in combination of two or more.

A phosphorescent emitting material is preferably a compound represented by the following formula (E-1):

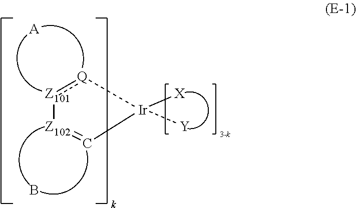

wherein Z₁₀₁ and Z₁₀₂ are independently a carbon atom or a nitrogen atom;

A₁ is a group of atoms that form a 5-membered or 6-membered hetero ring together with Z₁₀₁ and a nitrogen atom;

B is a group of atoms that form a 5-membered or 6-membered ring together with Z₁₀₂ and a carbon atom;

Q is a carbon atom, a nitrogen atom or a boron atom;

X—Y is a monoanionic bidentate ligand; and

k is an integer of 1 to 3.

As the 5-membered ring or the 6-membered hetero ring which is formed by A, Z₁₀₁ and a nitrogen atom, a pyridine ring, a pyrimidine ring, a pyrazine ring, a triazine ring, an imidazole ring, a pyrazole ring, an oxazole ring, a thiazole ring, a triazole ring, an oxadiazole ring, a thiadiazole ring or the like can be given. In respect of stability of a complex, control of emission wavelength and emission quantum yield, the 5-membered ring or the 6-membered hetero ring which is formed by A, Z₁₀₁ and a nitrogen atom is preferably a pyridine ring, a pyrazine ring, an imidazole ring and a pyrazole ring. A pyridine ring, an imidazole ring and a pyrazine ring are more preferable, with a pyridine ring and an imidazole ring being further preferable. A pyridine ring is most preferable.

The 5-membered hetero ring or the 6-membered hetero ring which is formed by A, Z₁₀₁ and a nitrogen atom may have a substituent.

As the substituent on the carbon atom, the following group A of substituents can be given. As the substituent on the nitrogen atom, the following group B of substituents can be given.

### (Substituent Group A)

Examples of the substituent include alkyl groups (preferably those including 1 to 30 carbon atoms, more preferably 1 to 20 carbon atoms, particularly preferably 1 to 10 carbon atoms, for example, methyl, ethyl, iso-propyl, tert-butyl, n-octyl, n-decyl, n-hexadecyl, cyclopropyl, cyclopentyl, cyclohexyl), alkenyl groups (preferably those including 2 to 30 carbon atoms, more preferably 2 to 20 carbon atoms, particularly preferably 2 to 10 carbon atoms, for example, vinyl, allyl, 2-butenyl, 3-pentenyl), alkynyl groups (preferably those including 2 to 30 carbon atoms, more preferably 2 to 20 carbon atoms, particularly preferably 2 to 10 carbon atoms, for example, propargyl, 3-pentynyl), aryl groups (preferably those including 6 to 30 carbon atoms, more preferably 6 to 20 carbon atoms, particularly preferably 6 to 12 carbon atoms, for example, phenyl, p-methyl phenyl, naphthyl, anthranyl), amino groups (preferably those including 0 to 30 carbon atoms, more preferably 0 to 20 carbon atoms, particularly preferably 0 to 10 carbon atoms, for example, amino, methylamino, dimethylamino, diethylamino, dibenzylamino, diphenylamino, ditolylamino), alkoxy groups (preferably those including 1 to 30 carbon atoms, more preferably 1 to 20 carbon atoms, particularly preferably 1 to 10 carbon atoms, for example, methoxy, ethoxy, butoxy, 2-ethylhexyloxy), aryloxy groups (preferably those including 6 to 30 carbon atoms, more preferably 6 to 20 carbon atoms, particularly preferably 6 to 12 carbon atoms, for example, phenyloxy, 1-naphthyloxy, 2-naphthyloxy), heterocyclic oxy groups (preferably those including 1 to 30 carbon atoms, more preferably 1 to 20 carbon atoms, particularly preferably 1 to 12 carbon atoms, for example, pyridyloxy, pyrazyloxy, pyrimidyloxy, quinolyloxy), acyl groups (preferably those including 2 to 30 carbon atoms, more preferably 2 to 20 carbon atoms, particularly preferably 2 to 12 carbon atoms, for example, acetyl, benzoyl, formyl, pivaloyl), alkoxycarbonyl groups (preferably those including 2 to 30 carbon atoms, more preferably 2 to 20 carbon atoms, particularly preferably 2 to 12 carbon atoms, for example, methoxycarbonyl, ethoxycarbonyl), aryloxycarbonyl groups (preferably those including 7 to 30 carbon atoms, more preferably 7 to 20 carbon atoms, particularly preferably 7 to 12 carbon atoms, for example, phenyloxycarbonyl), acyloxy groups (preferably those including 2 to 30 carbon atoms, more preferably 2 to 20 carbon atoms, particularly preferably 2 to 10 carbon atoms, for example, acetoxy, benzoyloxy), acylamino groups (preferably those including 2 to 30 carbon atoms, more preferably 2 to 20 carbon atoms, particularly preferably 2 to 10 carbon atoms, for example, acetylamino, benzoylamino), alkoxycarbonylamino groups (preferably those including 2 to 30 carbon atoms, more preferably 2 to 20 carbon atoms, particularly preferably 2 to 12 carbon atoms, for example, methoxycarbonylamino), aryloxycarbonylamino groups (preferably those including 7 to 30 carbon atoms, more preferably 7 to 20 carbon atoms, particularly preferably 7 to 12 carbon atoms, for example, phenyloxycarbonylamino), sulfonylamino groups (preferably those including 1 to 30 carbon atoms, more preferably 1 to 20 carbon atoms, particularly preferably 1 to 12 carbon atoms, for example, methanesulfonylamino, benzenesulfonylamino), sulfamoyl groups (preferably those including 0 to 30 carbon atoms, more preferably 0 to 20 carbon atoms, particularly preferably 0 to 12 carbon atoms, for example, sulfamoyl, methylsulfamoyl, dimethylsulfamoyl, phenylsulfamoyl), carbamoyl groups (preferably those including 1 to 30 carbon atoms, more preferably 1 to 20 carbon atoms, particularly preferably 1 to 12 carbon atoms, for example, carbamoyl, methylcarbamoyl, diethylcarbamoyl, phenylcarbamoyl), alkylthio groups (preferably those including 1 to 30 carbon atoms, more preferably 1 to 20 carbon atoms, particularly preferably 1 to 12 carbon atoms, for example, methylthio, ethylthio), arylthio groups (preferably those including 6 to 30 carbon atoms, more preferably 6 to 20 carbon atoms, particularly preferably 6 to 12 carbon atoms, for example, phenylthio), heterocyclic thio groups (preferably those including 1 to 30 carbon atoms, more preferably 1 to 20 carbon atoms, particularly preferably 1 to 12 carbon atoms, for example, pyridylthio, 2-benzimizoylthio, 2-benzoxazolylthio, 2-benzthiazolylthio), sulfonyl groups (preferably those including 1 to 30 carbon atoms, more preferably 1 to 20 carbon atoms, particularly preferably 1 to 12 carbon atoms, for example, mesyl, tosyl), sulfinyl groups (preferably those including 1 to 30 carbon atoms, more preferably 1 to 20 carbon atoms, particularly preferably 1 to 12 carbon atoms, for example, methanesulfinyl, benzenesulfinyl), ureido groups (preferably those including 1 to 30 carbon atoms, more preferably 1 to 20 carbon atoms, particularly preferably 1 to 12 carbon atoms, for example, ureido, methylureido, phenylureido), amide phosphate groups (preferably those including 1 to 30 carbon atoms, more preferably 1 to 20 carbon atoms, particularly preferably 1 to 12 carbon atoms, for example, amide diethyl phosphate, amide phenyl phosphate), a hydroxy group, a mercapto group, halogen atoms (for example, a fluorine atom, a chlorine atom, a bromine atom, an iodine atom), a cyano group, a sulfo group, a carboxyl group, a nitro group, a hydroxamic acid group, a sulfino group, a hydrazino group, an imino group, heterocyclic groups (also including an aromatic heterocyclic group and preferably including 1 to 30 carbon atoms, more preferably 1 to 12 carbon atoms, and as hetero atoms, a nitrogen atom, an oxygen atom, a sulfur atom, a phosphor atom, a silicon atom, a selenium atom, a tellurium atom can be given), for example, pyridyl, pyrazinyl, pyrimidyl, pyridanzinyl, pyrroyl, pyrazolyl, triazolyl, imidazolyl, oxazolyl, thiazolyl, isoxazolyl, isothiazolyl, quinolyl, furyl, thienyl, selenophenyl, tellurophenyl, piperidyl, piperidino, morpholino, pyrrolidyl, pyrrolidino, benzoxazolyl, benzimidazolyl, benzothiazolyl, carbazoyl group, azepinyl, silolyl), silyl groups (preferably those including 3 to 40 carbon atoms, more preferably 3 to 30 carbon atoms, particularly preferably 3 to 24 carbon atoms, for example, trimethylsilyl, triphenylsilyl), silyloxy groups (preferably those including 3 to 40 carbon atoms, more preferably 3 to 30 carbon atoms, particularly preferably 3 to 24 carbon atoms, for example, trimethylsilyloxy, triphenylsilyloxy), and phosphoryl groups (for example, diphenylphosphoryl, dimethylphosphoryl). These substituents may be further substituted. As further substituents, a group selected from the substituent group A can be given. The substitutes introduced to the substituent may further be substituted, and as the further substituent, a group selected from the substituent group A can be given.

### (Substituent Group B)

Examples of the substituent include alkyl groups (preferably those including 1 to 30 carbon atoms, more preferably 1 to 20 carbon atoms, particularly preferably 1 to 10 carbon atoms, for example, methyl, ethyl, iso-propyl, tert-butyl, n-octyl, n-decyl, n-hexadecyl, cyclopropyl, cyclopentyl, cyclohexyl), alkenyl groups (preferably including 2 to 30 carbon atoms, more preferably 2 to 20 carbon atoms, particularly preferably 2 to 10 carbon atoms, for example, vinyl, allyl, 2-butenyl, 3-pentenyl), alkynyl groups (preferably those including 2 to 30 carbon atoms, more preferably 2 to 20 carbon atoms, particularly preferably 2 to 10 carbon atoms, for example, propargyl, 3-pentynyl), aryl groups (preferably those including 6 to 30 carbon atoms, more preferably 6 to 20 carbon atoms, particularly preferably 6 to 12 carbon atoms, for example, phenyl, p-methylphenyl, naphthyl, anthranyl), cyano groups, heterocyclic groups (also including an aromatic heterocyclic groups and preferably including 1 to 30 carbon atoms, more preferably 1 to 12 carbon atoms, and as hetero atoms, a nitrogen atom, an oxygen atom, a sulfur atom, a phosphor atom, a silicon atom, a selenium atom, a tellurium atom can be given), for example, pyridyl, pyrazinyl, pyrimidyl, pyridazinyl, pyrroyl, pyrazolyl, triazolyl, imidazolyl, oxazolyl, thiazolyl, isoxazolyl, isothiazolyl, quinolyl, furyl, thienyl, selenophenyl, tellurophenyl, piperidyl, piperidino, morpholino, pyrrolidyl, pyrrolidino, benzoxazolyl, benzimidazolyl, benzothiazolyl, carbazolyl group, azepinyl, silolyl). These substituents may be further substituted. As substituents, a group selected from the group B can be given. The substituent introduced to the substituent may further be substituted, and as the further substituent, a group selected from the substituent group B can be given.

As the substituent on the carbon, an alkyl group, a perfluoroalkyl group, an aryl group, an aromatic heterocyclic group, a dialkylamino group, a diarylamino group, an alkoxy group, a cyano group and a fluorine atom can preferably be given.

The substituent is appropriately selected in respect of emission wavelength or control of potential. In order to allow the emitted light to have a shorter wavelength, an electron-donating group, a fluorine atom and an aromatic ring group are preferable. For example, an alkyl group, a dialkylamino group, an alkoxy group, a fluorine atom, an aryl group, an aromatic heterocyclic group or the like are selected. In order to allow the emitted light to have a longer wavelength, an electron-attracting group is preferable. For example, a cyano group, a perfluoroalkyl group or the like are selected.

As the substituent on the nitrogen, an alkyl group, an aryl group, an aromatic heterocyclic group are preferable. In respect of stability of a complex, an alkyl group and an aryl group are preferable.

The substituents may be bonded to each other to form a fused ring. As the ring to be formed includes a benzene ring, a pyridine ring, a pyrazine ring, a pyridazine ring, a pyrimidine ring, an imidazole ring, an oxazole ring, a thiazole ring, a pyrazole ring, a thiophene ring, a furan ring or the like can be given. These rings to be formed may have a substituent, and as the substituent, the substituent on the carbon atom and the substituent on the nitrogen atom, mentioned above, can be given.

As the 5-membered ring or the 6-membered ring formed by B with Z₁₀₂ and a carbon atom, a benzene ring, a pyridine ring, a pyrimidine ring, a pyrazine ring, a pyridazine ring, a triazine ring, an imidazole ring, a pyrazole ring, an oxazole ring, a thiazole ring, a triazole ring, an oxadiazole ring, a thiadiazole ring, a thiophene ring, a furan ring or the like can be given.

In respect of stability of a complex, control of emission wavelength and emission quantum yield, as the 5-membered ring or the 6-membered ring formed by B, Z₁₀₂ and a carbon atom, a benzene ring, a pyridine ring, a pyrazine ring, an imidazole ring, a pyrazole ring and a thiophene ring are preferable. Among these, a benzene ring, a pyridine ring and a pyrazole ring are more preferable, and a benzene ring and a pyridine ring are further preferable.

The 5-membered ring or the 6-membered ring formed by B, Z₁₀₂ and a carbon atom may have a substituent. As the substituent on the carbon atom, the above-mentioned substituent group A, and as the substituent on the nitrogen atom, the above-mentioned substituent group B can be applied. As the substituent on the carbon atom, an alkyl group, a perfluoroalkyl group, an aryl group, an aromatic heterocyclic group, a dialkylamino group, a diarylamino group, an alkoxy group, a cyano group and a fluorine atom can be given.

As the substituent on nitrogen, an alkyl group, an aryl group and an aromatic heterocyclic group are preferable. In respect of stability of a complex, an alkyl group and an aryl group are preferable.

The substituent is appropriately selected in respect of emission wavelength or control of potential. In order to allow the emitted light to have a longer wavelength, an electron-donating group and an aromatic ring group are preferable. For example, an alkyl group, a dialkylamino group, an alkoxy group, an aryl group, an aromatic heterocyclic group or the like are selected. In order to allow the emitted light to have a shorter wavelength, an electron-attracting group is preferable. For example, a fluorine atom, a cyano group, a perfluoroalkyl group or the like are selected.

The above-mentioned substituents may be bonded to each other to form a fused ring. As examples of the ring formed, a benzene ring, a pyridine ring, a pyrazine ring, a pyridazine ring, a pyrimidine ring, an imidazole ring, an oxazole ring, a thiazole ring, a pyrazole ring, a thiophene ring, a furan ring or the like can be given. These rings to be formed may have a substituent, and as the substituent, the above-mentioned substituent on the carbon atom and the above-mentioned substituent on the nitrogen atom can be mentioned.

Further, the substituent on the 5-membered ring or the 6-membered ring formed by A, Z₁₀₁ and a nitrogen atom may be bonded to the substituent on the 5-membered ring or the 6-membered ring formed by B. Z₁₀₂ and a carbon atom to form a fused ring.

As the monoanionic bidental ligand represented by X—Y, various known ligands used in a conventional metal complex can be given. For example, a ligand described in H. Yersin: “Photochemistry and Photophysics of Coordination Compounds”, published by Springer-verlag (1987), a ligand described in Akio Yamamoto: “Organometallic Chemistry-Principles and Applications”, published by Shokobo Co., Ltd. (1982) (for example, a halogen ligand (preferably chlorine ligand), a nitrogen-containing heteroaryl ligand (bipyridine, phenanthroline or the like), and a diketone ligand (for example, acetylacetone)) can be given. As the ligand represented by (X—Y), a diketone and a picolinic acid derivative are preferable. In respect of stability of a complex and a high luminous efficiency, it is most preferred that the ligand be acetyl acetonate (acac) shown below.

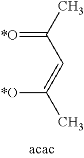

(in the formula, * shows the coordination position to iridium)

As the ligand represented by (X—Y), those represented by the following formulas (I-1) to (I-15) are preferable.

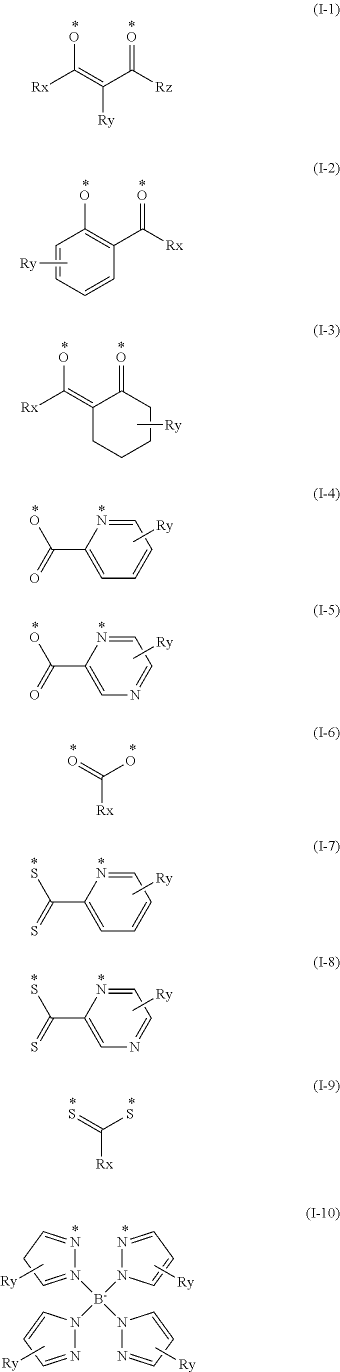

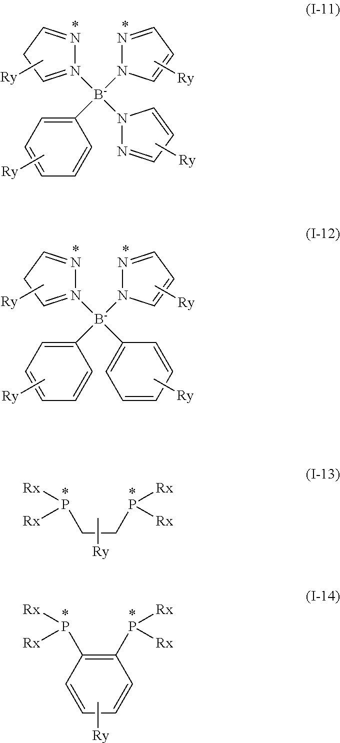

In the formulas (I-1) to (I-15), * is a coordination position to iridium in the formula (I). Rx, Ry and Rz are independently a hydrogen atom or a substituent.

When Rx, Ry and Rz each represent a substituent, as the substituent, substituents selected from the substituent group A can be mentioned. It is preferred that Rx and Rz be independently any of an alkyl group, a perfluoroalkyl group, a fluorine atom and an aryl group. More preferably, the substituent is an alkyl group including 1 to 4 carbon atoms, a perfluoroalkyl group including 1 to 4 carbon atoms, a fluorine atom and a phenyl group that may be substituted. Most preferably, the substituent is a methyl group, an ethyl group, a trifluoromethyl group, a fluorine atom and a phenyl group. Ry is preferably any of a hydrogen atom, an alkyl group, a perfluoroalkyl group, a fluorine atom and an aryl group, more preferably a hydrogen atom, an alkyl group including 1 to 4 carbon atoms and a phenyl group that may be substituted. Most preferably, the substituent is any of a hydrogen atom and a methyl group.

It is considered that these ligands are not a site where carriers are transported in the device or electrons are concentrated by excitation. Therefore, it suffices that Rx, Ry and Rz be a chemically stable substituent, and they do not affect adversely the advantageous effects of the invention. Since a ligand can be synthesized easily, the ligands represented by the formulas (I-1), (I-4) and (I-5) are preferable, with the ligands represented by the formula (I-1) being most preferable. The complex having these ligands can be synthesized similarly as in the case of known synthesis examples by using corresponding ligand precursors. For example, by the same method as that described on page 46 of WO2009/073245, it can be synthesized by the following method by using commercially available difluoroacetylacetone.

The Ir complex represented by the formula (E-1) is preferably an Ir complex represented by the following formula (E-2):

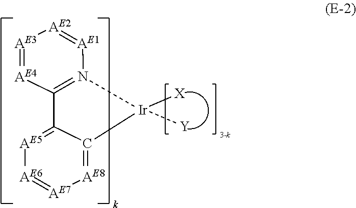

In the formula (E-2), A^{E1} to A^{E8} are independently a nitrogen atom or C—R^{E}.

R^{E} is a hydrogen atom or a substituent.

(X—Y) is a monoanionic bidentate ligand.

k is an integer of 1 to 3.

A^{E1} to A^{E8} are independently a nitrogen atom or C—R^{E}.

R^{E} is a hydrogen atom or a substituent, and R^{E}s may be bonded with each other to form a ring. As the ring to be formed, the same rings as the fused rings mentioned in the formula (E-1) can be given. As the substituent represented by R^{E}, those given as the substituent group A can be applied.

A^{E1} to A^{E4} are preferably C—R^{E}, and when A^{E1} to A^{E4} are C—R^{E}, R^{E} of A^{E3} is preferably a hydrogen atom, an alkyl group, an aryl group, an amino group, an alkoxy group, an aryloxy group, a fluorine atom or a cyano group, more preferably a hydrogen atom, an alkyl group, an amino group, an alkoxy group, an aryloxy group or a fluorine atom, and particularly preferably a hydrogen atom or a fluorine atom. R^{E} of A^{E1}, A^{E2} and A^{E4} is preferably a hydrogen atom, an alkyl group, an aryl group, an amino group, an alkoxy group, an aryloxy group, a fluorine atom or a cyano group. R^{E} is more preferably a hydrogen atom, an alkyl group, an amino group, an alkoxy group, an aryloxy group or a fluorine atom, with a hydrogen atom being particularly preferable.

A^{E5} to A^{E8} are preferably C—R^{E}, and when A^{E5} to A^{E8} are C—R^{E}, R^{E} is preferably a hydrogen atom, an alkyl group, a perfluoroalkyl group, an aryl group, an aromatic heterocyclic group, a dialkylamino group, a diarylamino group, an alkyloxy group, a cyano group or a fluorine atom. R^{E} is more preferably a hydrogen atom, an alkyl group, a perfluoroalkyl group, an aryl group, a dialkylamino group, a cyano group or a fluorine atom. Further preferably, R^{E} is a hydrogen atom, an alkyl group, a trifluoromethyl group or a fluorine atom. If possible, the substituents may be bonded with each other to form a fused ring structure. When an emission wavelength is shifted to a shorter wavelength side, it is preferred that A^{E6} be a nitrogen atom.

(X—Y) and k are the same as (X—Y) and k in the formula (E-1), and the preferable range is also the same.

The Ir complex represented by the formula (E-2) is preferably an Ir complex represented by the following formula (E-3).

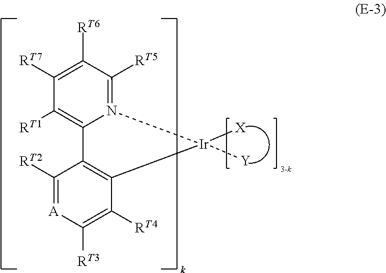

In the formula (E-3), R^{T1}, R^{T2}, R^{T3}, R^{T4}, R^{T5}, R^{T6} and R^{T7} are independently a hydrogen atom, an alkyl group, a cycloalkyl group, an alkenyl group, an alkynyl group, —CN, a perfluoroalkyl group, a trifluorovinyl group, —CO₂R, —C(O)R, —NR₂, —NO₂, —OR, a halogen atom, an aryl group or a heteroaryl group. It may further have a substituent Z. Rs are independently a hydrogen atom, an alkyl group, a perhaloalkyl group, an alkenyl group, an alkynyl group, a heteroalkyl group, an aryl group or a heteroaryl group.

A is CR′ or a nitrogen atom, and R′ is a hydrogen atom, an alkyl group, a cycloalkyl group, an alkenyl group, an alkynyl group, —CN, a perfluoroalkyl group, a trifluorovinyl group, —CO₂R, —C(O)R, —NR₂, —NO₂, —OR, a halogen atom, an aryl group or a heteroaryl group. It may further have a substituent Z. Rs are independently a hydrogen atom, an alkyl group, a perhaloalkyl group, an alkenyl group, an alkynyl group, a heteroalkyl group, an aryl group or a heteroaryl group.

As for R^{T1} to R^{T7} and R′, arbitral two may be bonded with each other to form a fused 4 to 7-membered ring. The fused 4 to 7-membered ring is cycloalkyl, aryl or heteroaryl. The fused 4 to 7-membered ring may further have a substituent Z. Among them, a case is preferable in which R^{T1} and R^{T7} or R^{T5} and R^{T6} are fused to form a benzene ring. A case where R^{T5} and R^{T6} are fused to form a benzene ring is particularly preferable.

The substituent Z is independently a halogen atom, —R″, —OR″, —N(R′)₂, —SR″, —C(O)R″, —C(O)OR″, —C(O)N(R′)₂, —CN, —NO₂, —SO₂, —SOR″, —SO₂R″ or —S₃R″, and R″ is independently a hydrogen atom, an alkyl group, a perhaloalkyl group, an alkenyl group, an alkynyl group, a heteroalkyl group, an aryl group or a heteroaryl group.

(X—Y) is a mono-anionic bidentate ligand. k is an integer of 1 to 3.

The alkyl group may have a substituent, and may be either saturated or unsaturated. As the group that may be substituted, the above-mentioned substituent Z can be mentioned. As the alkyl group that is represented by R^{T1} to R^{T7} and R′, an alkyl group including 1 to 8 carbon atoms in total is preferable. An alkyl group including 1 to 6 carbon atoms in total is more preferable. For example, a methyl group, an ethyl group, an i-propyl group, a cycloalkyl group, a t-butyl group or the like can be mentioned.

The cycloalkyl group may have a substituent, and may be either saturated or unsaturated. As the group that may be substituted, the above-mentioned substituent Z can be mentioned. As the cycloalkyl group that is represented by R^{T1} to R^{T7} and R′, a 4 to 7-membered cycloalkyl group is preferable. A cycloalkyl group including 5 to 6 carbon atoms in total is more preferable. For example, a cyclopentyl group, a cyclohexyl group or the like can be mentioned.

As the alkenyl group represented by R^{T1} to R^{T7} and R′, an alkenyl group including 2 to 30 carbon atoms is preferable. An alkenyl group including 2 to 20 carbon atoms are more preferable, and one including 2 to 10 carbon atoms is particularly preferable. Examples thereof include vinyl, allyl, 1-propenyl, 1-isopropenyl, 1-butenyl, 2-butenyl, 3-pentenyl or the like.

As the alkynyl group represented by R^{T1} to R^{T7} and R′, an alkynyl group including 2 to 30 carbon atoms is preferable, more preferably 2 to 20 carbon atoms. One including 2 to 10 carbon atoms is particularly preferable. Examples thereof include ethynyl, propargyl, 1-propinyl, 3-pentynyl or the like.

As the perfluoroalkyl group represented by R^{T1} to R^{T7} and R′, one in which all of the hydrogen atoms in the alkyl group are substituted by a fluorine atom can be given.

As the aryl group represented by R^{T1} to R^{T7} and R′, a substituted or unsubstituted aryl group including 6 to 30 carbon atoms, e.g. a phenyl group, a tolyl group, a naphthyl group or the like, can be given.

As the heteroaryl group represented by R^{T1} to R^{T7} and R′, a heteroaryl group including 5 to 8 carbon atoms is preferable. A 5- or 6-membered substituted or unsubstituted heteroaryl group is more preferable. Examples thereof include a pyridyl group, a pyrazinyl group, a pyridazinyl group, a pyrimidinyl group, a triazinyl group, a quinolinyl group, an isoquinolinyl group, a quinazolinyl group, a cinnolinyl group, a phthalazinyl group, a quinoxalinyl group, a pyrrolyl group, an indolyl group, a furyl group, a benzofuryl group, a thienyl group, a benzothienyl group, a pyrazolyl group, an imidazolyl group, benzimidazoyl group, a triazoyl group, an oxazolyl group, a benzoxazolyl group, a thiazolyl group, a benzothiazolyl group, an isothiazolyl group, a benzisothiazolyl group, a thiadiazolyl group, an isoxazolyl group, a benzisoxazolyl group, a pyrrolidinyl group, a piperidinyl group, a piperazinyl group, imidazolidinyl group, a thiazolinyl group, a sulforanyl group, a carbazolyl group, a dibenzofuryl group, a dibenzothienyl group and a 7-pyridindolyl group. A pyridyl group, a pyrimidinyl group, an imidazoyl group and a thienyl group are preferable, with a pyridyl group and a pyrimidinyl group being more preferable.

Preferable examples of R^{T1} to R^{T7} and R′ include a hydrogen atom, an alkyl group, a cyano group, a trifluoromethyl group, a perfluoroalkyl group, a dialkylamino group, a fluoro group, an aryl group and a heteroaryl group. A hydrogen atom, an alkyl group, a cyano group and a trifluoromethyl group are more preferable, with a hydrogen atom, an alkyl group and an aryl group being further preferable. As the substituent Z, an alkyl group, an alkoxy group, a fluoro group, a cyano group and a dialkylamino group are preferable, with a hydrogen atom being more preferable.

As for R^{T1} to R^{T7} and R′, arbitral two may be bonded with each other to form a fused 4 to 7-membered ring. The fused 4 to 7-membered ring is cycloalkyl, aryl or heteroaryl. The fused 4 to 7-membered ring may further have a substituent Z. Definition and preferable range of the cycloalkyl, the aryl and the heteroaryl formed are the same as those of the cycloalkyl group, the aryl group and the heteroaryl group defined in R^{T1} to R^{T7} and R′.

A case where A is CR′ and 0 to 2 of R^{T1} to R^{T7} and R′ is/are an alkyl group or a phenyl group and the remainder is hydrogen atoms is particularly preferable.

It is preferred that k be 2 or 3. It is preferred that the kind of the ligand in a complex be 1 or 2, with one kind being particularly preferable. When a reactive group is introduced into molecules of a complex, it is preferred that the complex be formed of two types of ligands in respect of easiness in synthesis.

(X—Y) is the same as (X—Y) in the formula (E-1), and the preferable range thereof is also the same.

The Ir complex represented by the formula (E-3) is preferably an Ir complex represented by the following formula (E-4):

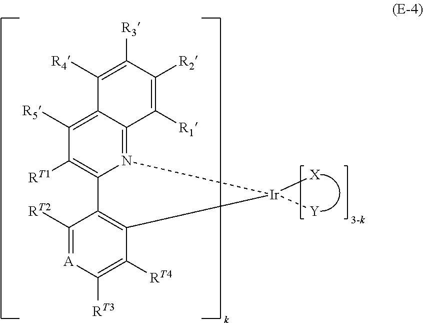

R^{T1} to R^{T4}, A, (X—Y) and k in the formula (E-4) are the same as R^{T1} to R^{T4}, A, (X—Y) and k in the formula (E-3), and the preferable ranges thereof are also the same. R₁′ to R₅′ are independently a hydrogen atom, an alkyl group, a cycloalkyl group, an alkenyl group, an alkynyl group, a cyano group, a perfluroalkyl group, a trifluorovinyl group, —CO₂R, —C(O)R, —NR₂, —NO₂, —OR, a halogen atom, an aryl group and a heteroaryl group. They may further have a substituent Z. Rs are independently a hydrogen atom, an alkyl group, a perhaloalkyl group, an alkenyl group, an alkynyl group, a heteroalkyl group, an aryl group or a heteroaryl group.

As for R₁′ to R₅′, arbitral two may be bonded with each other to form a fused 4 to 7-membered ring. The fused 4 to 7-membered ring is cycloalkyl, aryl or heteroaryl, and the fused 4 to 7-membered ring may further have a substituent Z.

Z are independently a halogen atom, —R″, —OR″, —N(R″)₂, —SR″, —C(O)R″, —C(O)OR″, —C(O)N(R″)₂, —CN, —NO₂, —SO₂, —SOR″, —SO₂R″, or —SO₃R″. R″ are independently a hydrogen atom, an alkyl group, a perhaloalkyl group, an alkenyl group, an alkynyl group, a heteroalkyl group, an aryl group or a heteroaryl group.

The preferable range in R₁′ to R₅′ is the same as R^{T1} to R^{T4} and R′ in the formula (E-3). A case where A is CR′ and 0 to 2 of R^{T1} to R^{T4} and R′ and R₁′ to R₅′ is/are an alkyl group or a phenyl group and the remainder is hydrogen atoms is particularly preferable. A case where 0 to 2 of R^{T1} to R^{T4} and R′ and R₁′ to R₅′ is/are an alkyl group and the remainder is hydrogen atoms is further preferable.

The Ir complex represented by the formula (E-3) is preferably an Ir complex represented by the following formula (E-5):

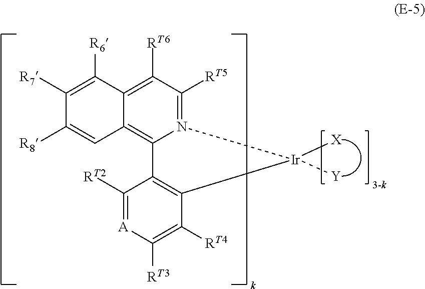

R^{T2} to R^{T6}, A, (X—Y) and k in the formula (E-5) are the same as R^{T2} to R^{T6}, A, (X—Y) and k in the formula (E-3), and the preferable ranges thereof are the same. R₆′ to R₈′ are independently a hydrogen atom, an alkyl group, a cycloalkyl group, an alkenyl group, an alkynyl group, a cyano group, a perfluoroalkyl group, a trifluorovinyl group, —CO₂R, —C(O)R, —NR₂, —NO₂, —OR, a halogen atom, an aryl group or a heteroaryl group. They may further have a substituent Z. R is independently a hydrogen atom, an alkyl group, a perhaloalkyl group, an alkenyl group, an alkynyl group, a heteroalkyl group, an aryl group or a heteroaryl group.

As for R^{T5}, R^{T6}, R₆′ to R₈′, arbitral two may be bonded with each other to form a fused 4 to 7-membered ring. The fused 4 to 7-membered ring is cycloalkyl, aryl or heteroaryl, and the fused 4 to 7-membered ring may further have a substituent Z.

Z is independently a halogen atom, —R″, —OR″, —N(R″)₂, —SR″, —C(O)R″, —C(O)OR″, —C(O)N(R″)₂, —CN, —NO₂, —SO₂, —SOR″, —SO₂R″ or —SO₃R′, and R″ is independently a hydrogen atom, an alkyl group, a perhaloalkyl group, an alkenyl group, an alkynyl group, a heteroalkyl group, an aryl group or a heteroaryl group.

The preferable range in R₆′ to R₈′ is the same as R^{T1} to R^{T7} and R′ in the formula (E-3). A case where A is CR′ and 0 to 2 of R^{T2} to R^{T6} and R₆′ and R₈′ to R′ is/are an alkyl group or a phenyl group and the remainder is hydrogen atoms is particularly preferable. A case where 0 to 2 of R^{T2} to R^{T6} and R′ and R₆′ to R₆′ is/are an alkyl group and the remainder is hydrogen atoms is further preferable.

The Ir complex represented by the formula (E-1) is preferably an Ir complex represented by the following formula (E-6):

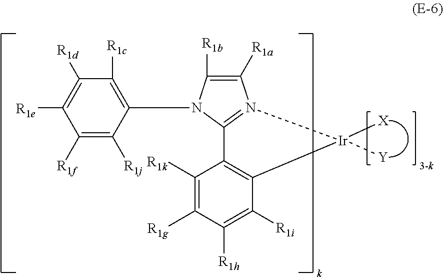

In the formula (E-6), R₁ₐ to R₁ₖ are independently a hydrogen atom, an alkyl group, a cycloalkyl group, an alkenyl group, an alkynyl group, a cyano group, a perfluoroalkyl group, a trifluorovinyl group, —CO₂R, —C(O)R, —NR₂, —NO₂, —OR, a halogen atom, an aryl group or a heteroaryl group. They may further have a substituent Z. R is independently a hydrogen atom, an alkyl group, a perhaloalkyl group, an alkenyl group, an alkynyl group, a heteroalkyl group, an aryl group or a heteroaryl group.

As for R₁ₐ to R₁ₖ, arbitral two may be bonded with each other to form a fused 4 to 7-membered ring. The fused 4 to 7-membered ring is cycloalkyl, aryl or heteroaryl, and the fused 4 to 7-membered ring may further have a substituent Z.

Z are independently a halogen atom, —R″, —OR″, —N(R″)₂, —SR″, —C(O)R″, —C(O)OR″, —C(O)N(R″)₂, —CN, —NO₂, —SO₂, —SOR″, —SO₂R″ or —SO₃R″ and R″ are independently a hydrogen atom, an alkyl group, a perhaloalkyl group, an alkenyl group, an alkynyl group, a heteroalkyl group, an aryl group or a heteroaryl group.

(X—Y) is a monoanionic bidentate ligand.

k is an integer of 1 to 3.

The preferable range in R₁ₐ to R₁ₖ in the formula (E-6) is the same as R^{T1} to R^{T7} and R′ in the formula (E-3). A case where 0 to 2 of R₁ₐ to R₁ₖ is/are an alkyl group or a phenyl group and the remainder is hydrogen atoms is particularly preferable. A case where 0 to 2 of R₁ₐ to R₁ₖ is/are an alkyl group and the remainder is hydrogen atoms is further preferable.

A case where R₁ⱼ and R₁ₖ are bonded to form a single bond is particularly preferable.

The preferable ranges of (X—Y) and k are the same as (X—Y) and k in the formula (E-3).

The Ir complex represented by the formula (E-6) is preferably an Ir complex represented by the following formula (E-7):

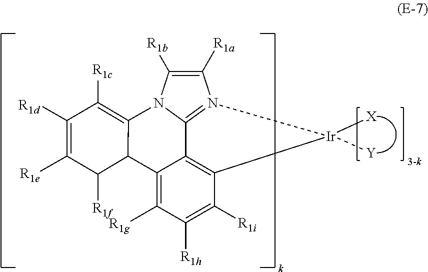

In the formula (E-7), R₁ₐ to R₁ᵢ are independently a hydrogen atom, an alkyl group, a cycloalkyl group, an alkenyl group, an alkynyl group, a cyano group, a perfluoroalkyl group, a trifluorovinyl group, —CO₂R, —C(O)R, —NR₂, —NO₂, —OR, a halogen atom, an aryl group or a heteroaryl group. They may further have a substituent Z. R is independently a hydrogen atom, an alkyl group, a perhaloalkyl group, an alkenyl group, an alkynyl group, a heteroalkyl group, an aryl group or a heteroaryl group.

As for R₁ₐ to R₁ₖ, arbitral two may be bonded with each other to form a fused 4 to 7-membered ring. The fused 4 to 7-membered ring is cycloalkyl, aryl or heteroaryl, and the fused 4 to 7-membered ring may further have a substituent Z.

Z are independently a halogen atom, —R″, —OR″, —N(R″)₂, —SR″, —C(O)R″, —C(O)OR″, —C(O)N(R″)₂, —CN, —NO₂, —SO₂, —SOR″, —SO₂R″ or —SO₃R″ and R″ are independently a hydrogen atom, an alkyl group, a perhaloalkyl group, an alkenyl group, an alkynyl group, a heteroalkyl group, an aryl group or a heteroaryl group.

(X—Y) is a monoanionic bidentate ligand.

k is an integer of 1 to 3.

In the formula (E-7), the definition and the preferable range of R₁ₐ to R₁ᵢ are the same as R₁ₐ to R₁ᵢ in the formula (E-6). A case where 0 to 2 of R₁ₐ to R₁ᵢ is/are an alkyl group or an aryl group and the remainder is hydrogen atoms is particularly preferable.

The definition and the preferable range of (X—Y) and k are the same as those of (X—Y) and k in the formula (E-3).

Specific examples of the compound represented by the formula (E-1) that is a phosphorescent emitting material are shown below. The compounds represented by the formula (E-1) are not limited to those shown below.

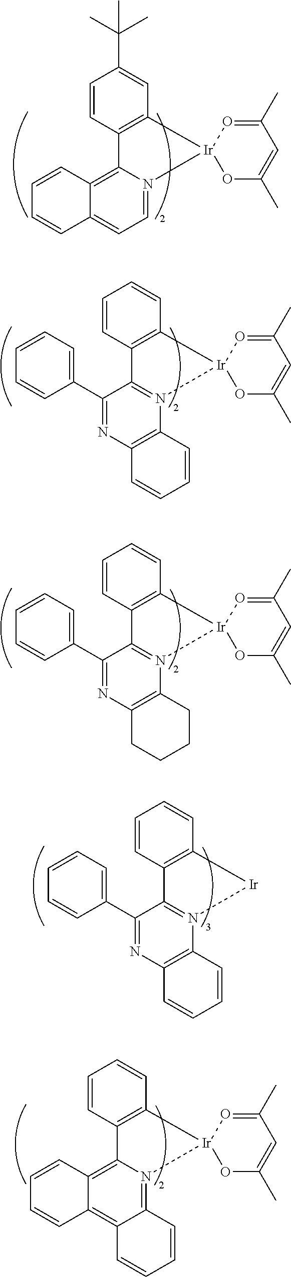

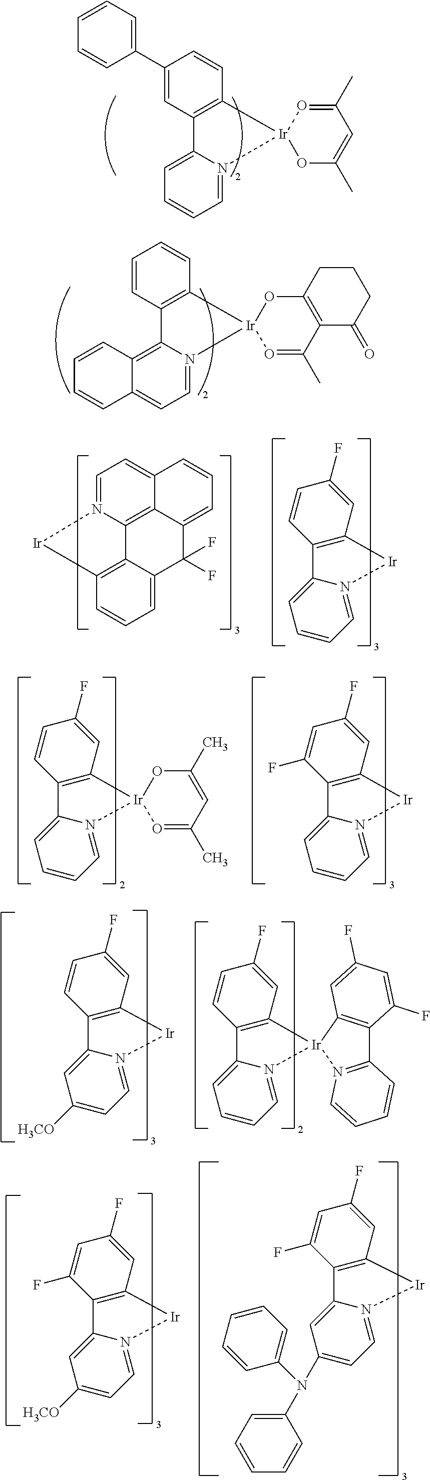

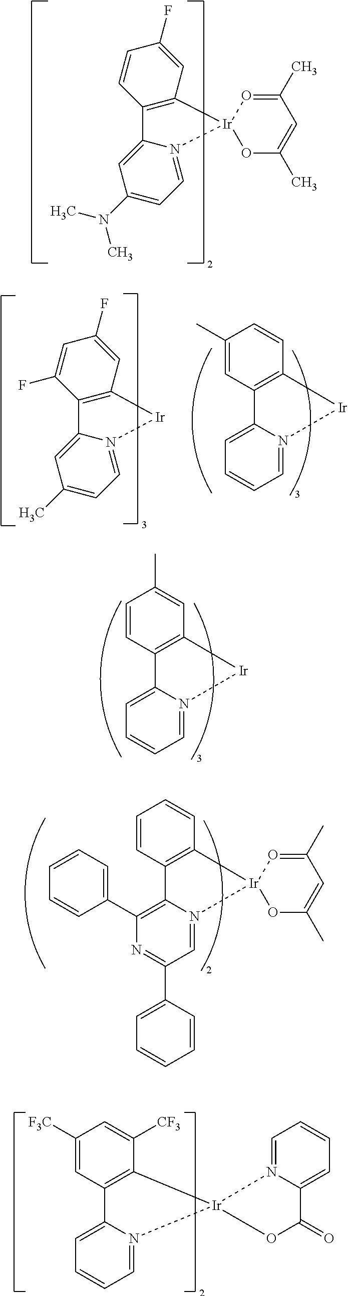

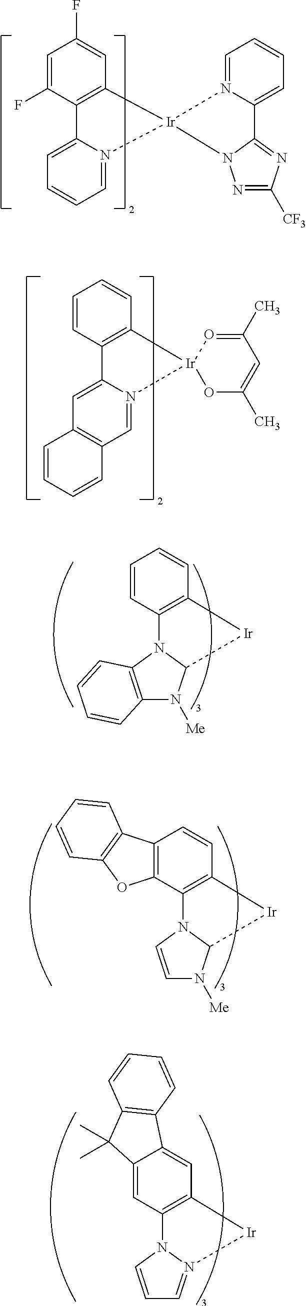

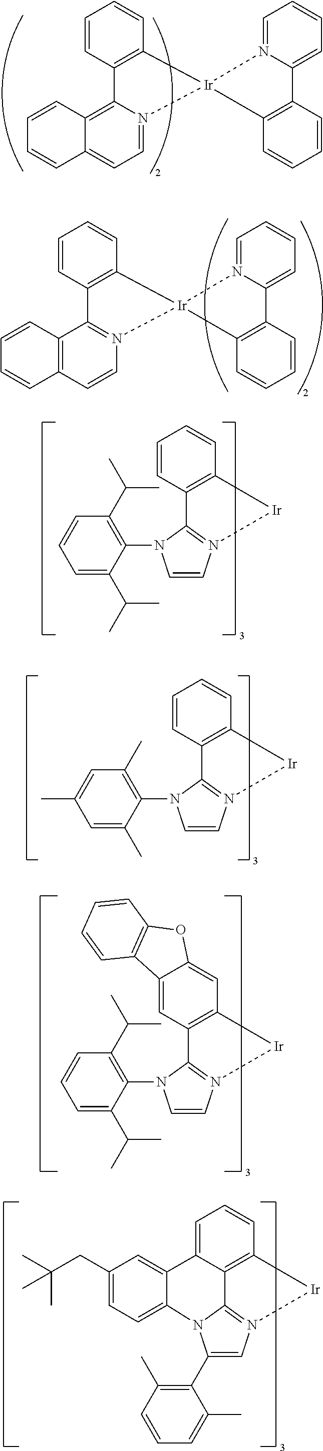

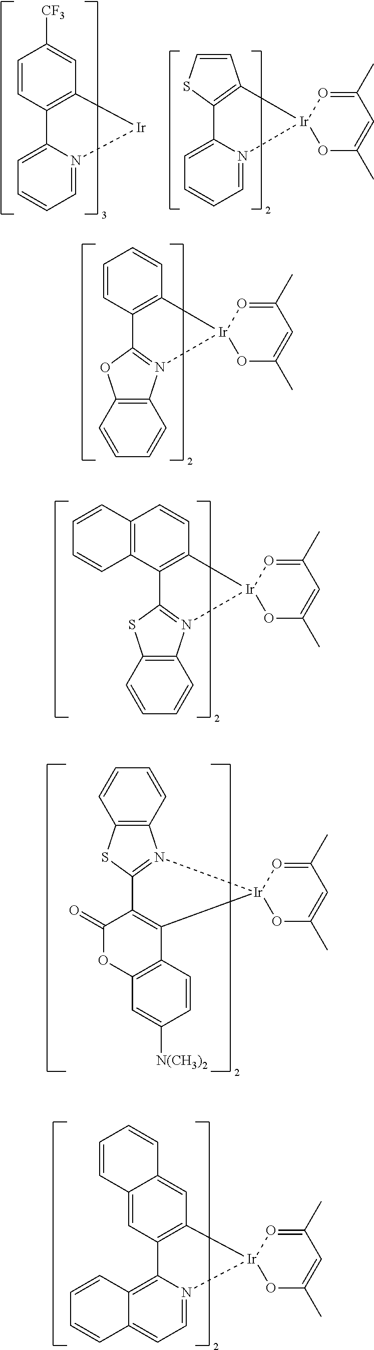

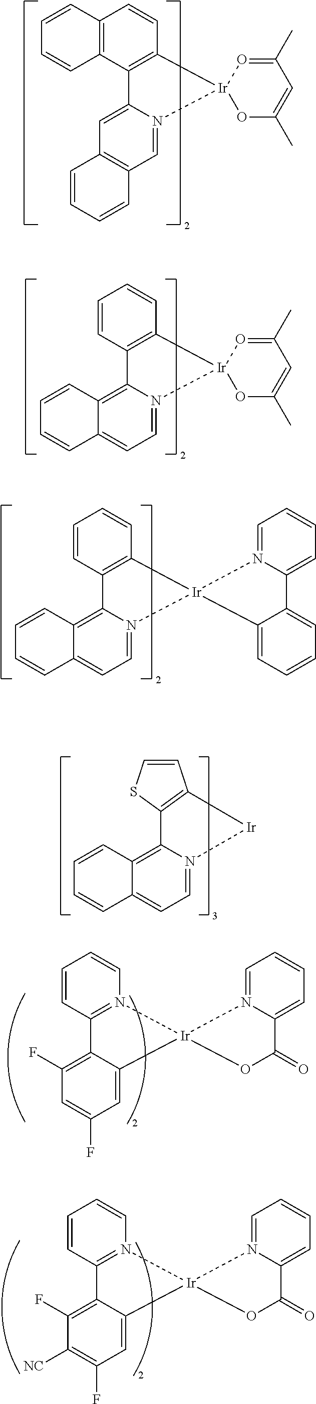

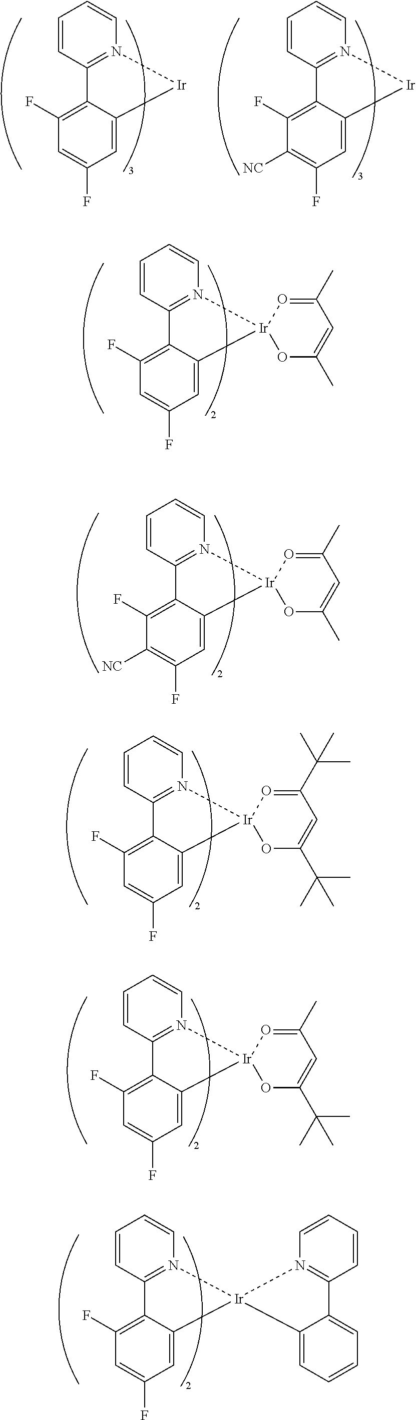

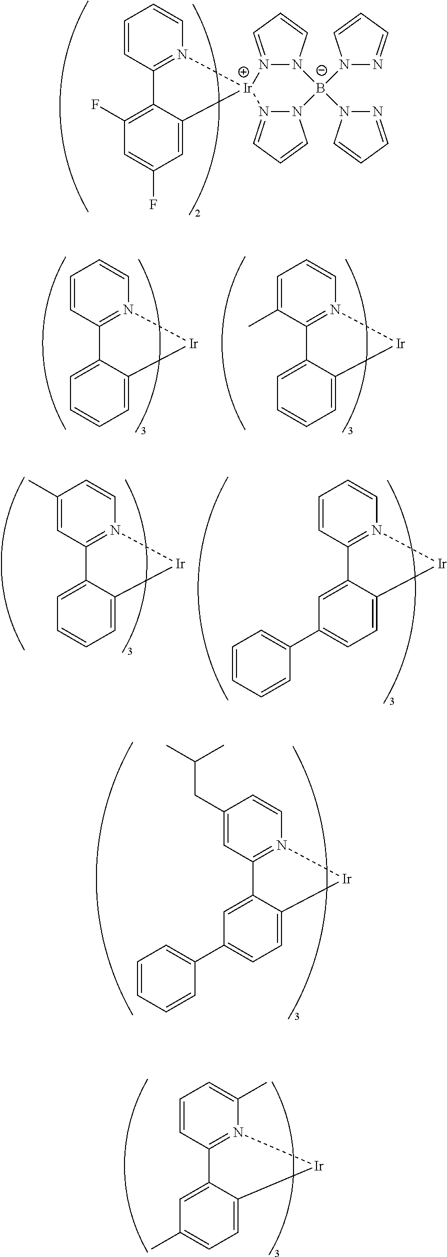

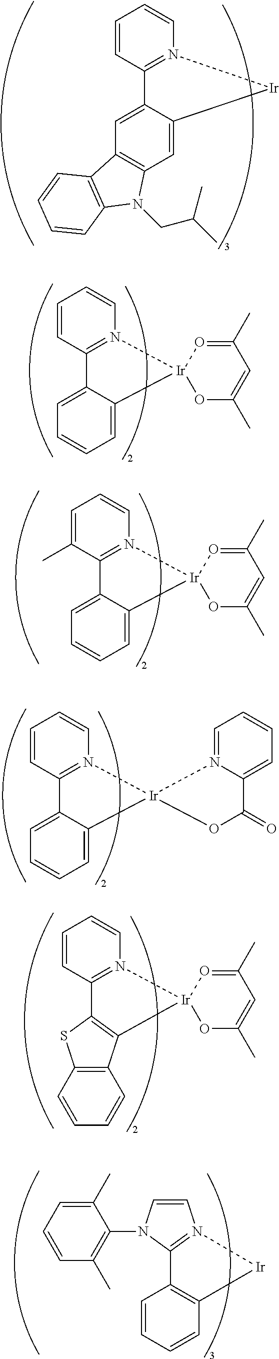

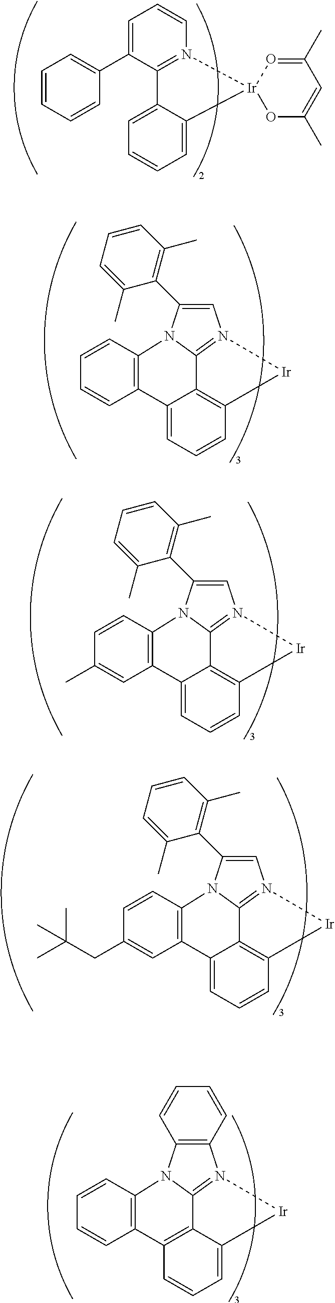

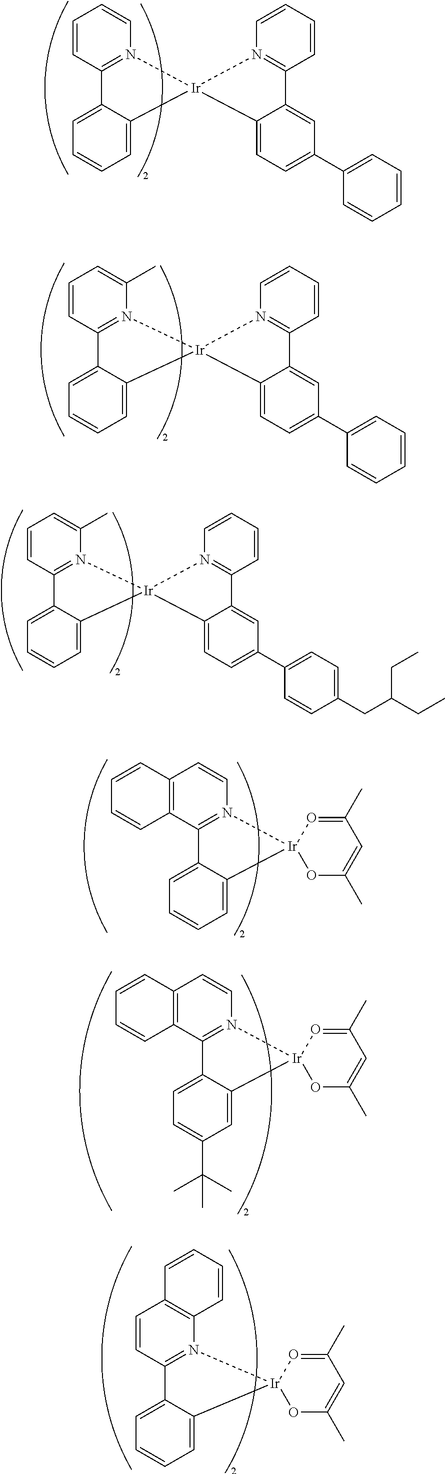

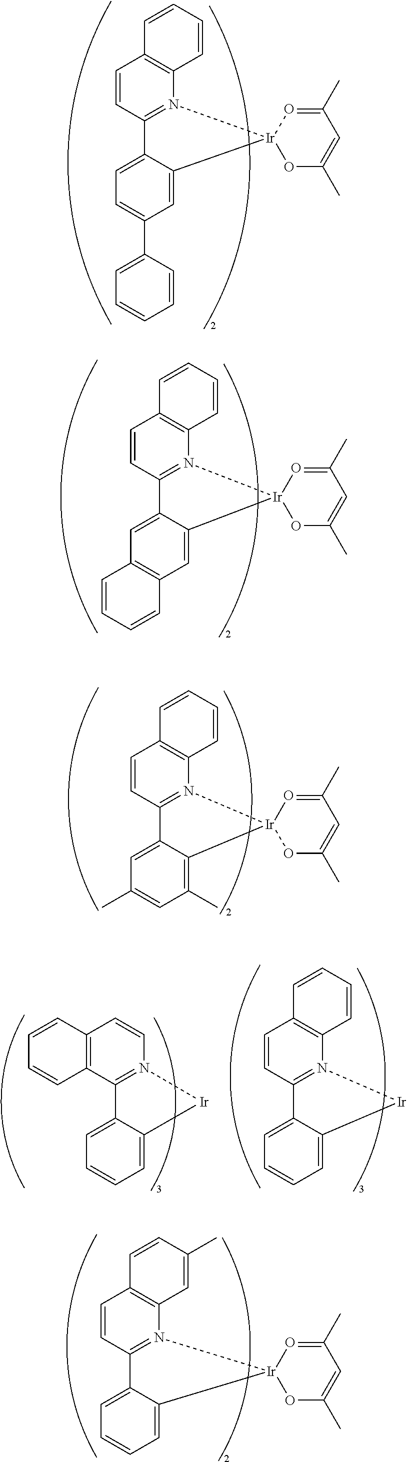

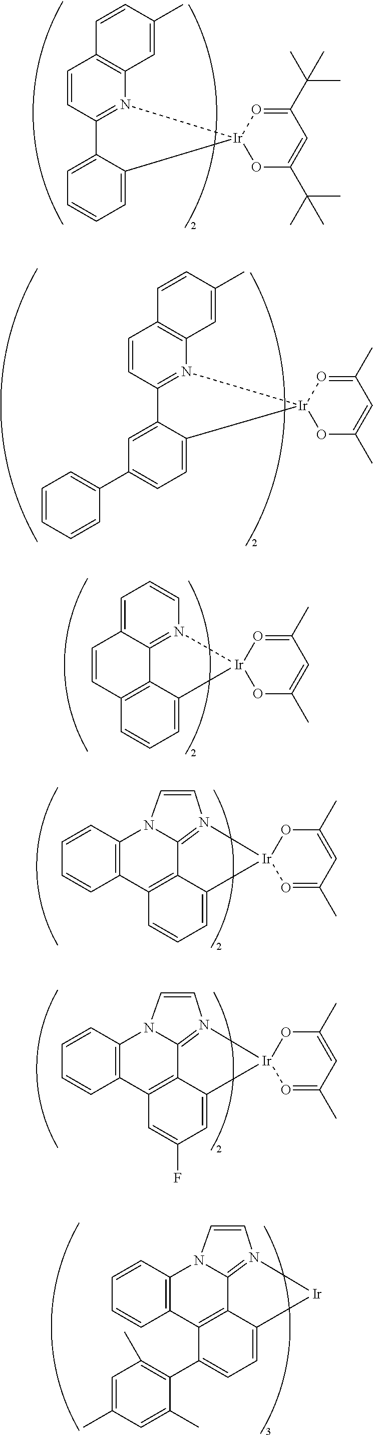

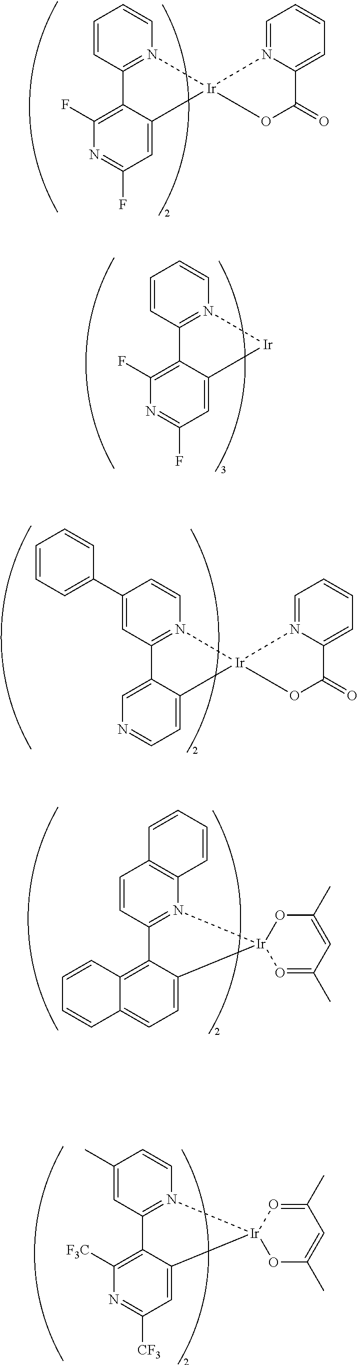

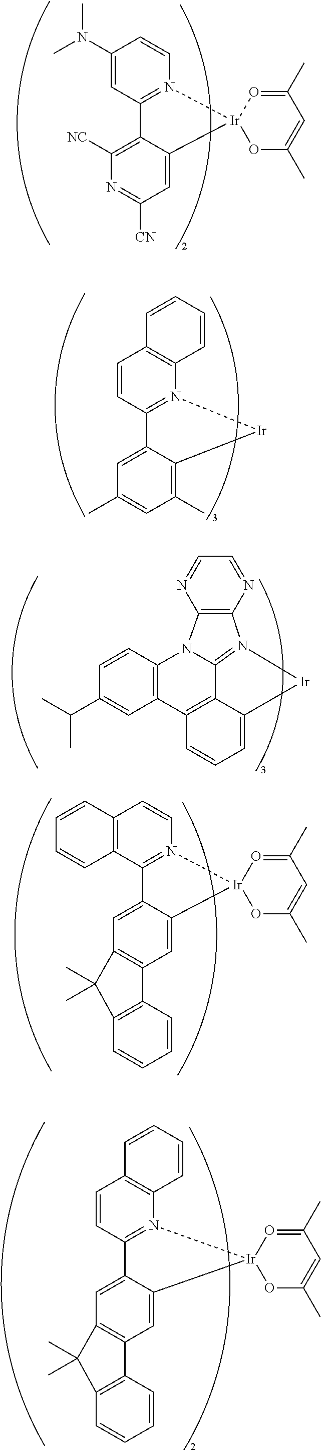

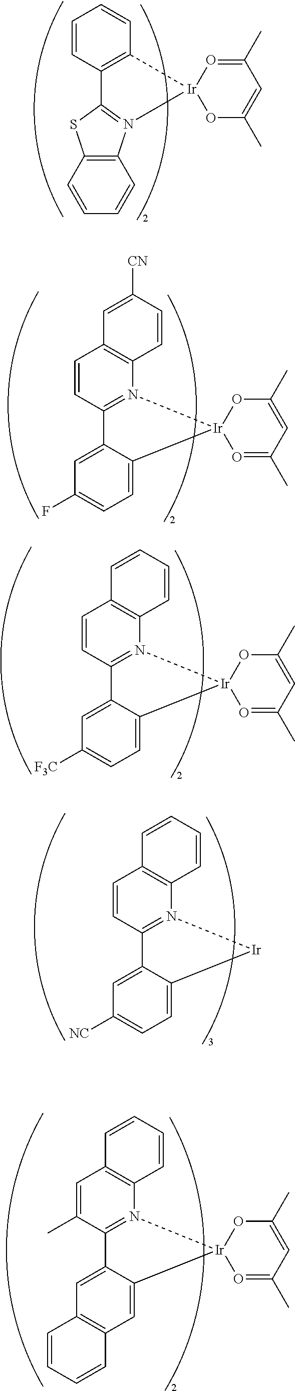

Other than the above-mentioned iridium complex, an osmium complex, a ruthenium complex, a platinum complex or the like can be used.

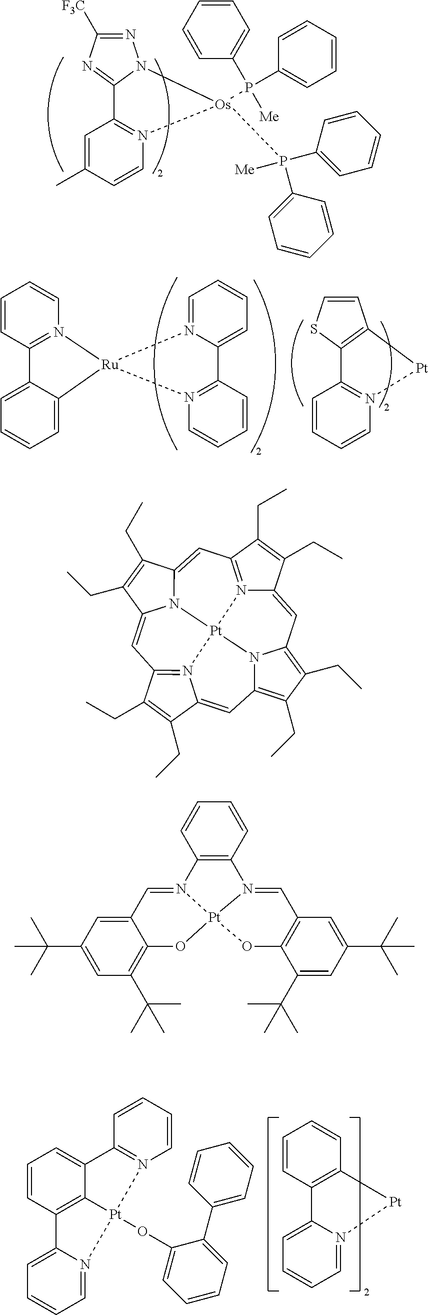

The concentration of a phosphorescent dopant added to a phosphorescent emitting layer is not particularly limited, but is preferably 0.1 to 30% by mass, with 0.1 to 20% by mass being more preferable.

Moreover, it is preferred that the compound of the invention represented by the formula (1-1) be used in layers adjacent to the phosphorescent emitting layer 40. For example, in the device shown in FIG. 1, when layers containing the compound of the invention represented by the formula (1-1) (adjacent layers nearer to the anode) are formed between the hole-transporting zone 30 and the phosphorescent emitting layer 40, the layers function as an electron-blocking layer or an exciton-barrier layer.

On the other hand, when layers containing the compound of the invention represented by the formula (1-3) (adjacent layers nearer to the cathode) are formed between the phosphorescent emitting layer 40 and the electron-transporting zone 50, the layers function as a hole-blocking layer or an exciton-barrier layer.

Meanwhile, the blocking (barrier) layer is a layer which blocks transporting of carriers or diffusion of excitons. The organic layer which prevents electrons from leaking from an emitting layer into a hole-transporting zone is mainly defined as the electron-blocking layer. The organic layer which prevents holes from leaking from an emitting layer into an electron-transporting zone is often defined as the hole-blocking layer. In addition, the organic layer which prevents triplet excitons generated in an emitting layer from diffusing to the peripheral layers having lower triplet energy than that of the emitting layer is often defined as the exciton-barrier layer (triplet-blocking layer).

The material for an organic EL device comprising the compound of the invention represented by the formula (1-2) is used in an electron-transporting layer or an electron-injecting layer in the electron-transporting zone 50. By using the material for an organic EL device comprising the compound represented by the formula (1-2) in an electron-transporting layer or an electron-injecting layer in the electron-transporting zone 50, the driving voltage of an organic EL device can be reduced.

Further, when two or more emitting layers are formed, the material for an organic EL device of the invention is preferable as a spacing layer formed between the emitting layers. FIG. 2 is a schematic view showing the layer configuration of another embodiment of the organic EL device 2 of the invention.

An organic EL device 2 is an example of a hybrid-type organic EL device in which a phosphorescent emitting layer and a fluorescent emitting layer are stacked.

The organic EL device 2 has the same construction as the organic EL device 1 mentioned above, except that a spacing layer 42 and a fluorescent emitting layer 44 are formed between a phosphorescent emitting layer 40 and an electron-transporting zone 50. In the construction in which the phosphorescent emitting layer 40 and the fluorescent emitting layer 44 are stacked, for preventing excitons generated in the phosphorescent emitting layer 40 from diffusing into the fluorescent emitting layer 44, the spacing layer 42 may be provided between the fluorescent emitting layer 44 and the phosphorescent emitting layer 40. Since the material for an organic EL device of the invention has a large triplet energy, it can function as a spacing layer.

In the organic EL device 2, for example, by allowing the phosphorescent emitting layer 40 to emit yellow light and by allowing the fluorescent emitting layer 44 to emit blue light, an organic EL device which emits white light can be obtained. Meanwhile, in this embodiment, the phosphorescent emitting layer 40 and the fluorescent emitting layer 44 are each formed as a single layer. However, the configuration is not limited thereto, and they may be each formed as two or more layers. Their manner of formation can be selected appropriately depending on the intended use such as lightning or a display device. For example, when a full-color emitting device is realized by utilizing white emitting devices and color filters, the phosphorescent emitting layer and the fluorescent emitting layer preferably include emissions in the plural wavelength regions such as red, green and blue (RGB), or red, green, blue and yellow (RGBY) in respect of color rendering properties.

In addition to the above-mentioned embodiments, the organic EL device of the invention can employ various known structures. Further, the emission from an emitting layer can be outcoupled from the anode side, the cathode side or the both sides.

In the organic EL device of the invention, at least any of an electron-donating dopant and an organic metal complex be provided in an interfacial region of the cathode and the organic thin film layer.

Due to such a configuration, the organic EL device can have improved luminance and a prolonged lifetime.

In the invention, it is preferred that the electron-transporting layer or the electron-injecting layer in the electron-transporting zone 50 contain the material for an organic EL device of the invention that comprises the compound represented by the formula (1-2) and an electron-donating dopant. Due to such a configuration, the driving voltage of the organic EL device can be further lowered.

As the electron-donating dopant, at least one selected from an alkali metal, an alkali metal compound, an alkaline-earth metal, an alkaline-earth metal compound, a rare-earth metal and a rare-earth metal compound can be given.

As the organic metal complex, at least one selected from an organic metal complex including an alkali metal, an organic metal complex including an alkaline-earth metal and an organic metal complex including a rare-earth metal can be given.

As the alkali metal, lithium (Li) (work function: 2.93 eV), sodium (Na) (work function: 2.36 eV), potassium (K) (work function: 2.28 eV), rubidium (Rb) (work function: 2.16 eV), cesium (Cs) (work function: 1.95 eV) and the like can be given. One having a work function of 2.9 eV or less is preferable. Of these, K, Rb and Cs are preferable, Rb or Cs is further preferable, and Cs is most preferable.

As the alkaline-earth metal, calcium (Ca) (work function: 2.9 eV), strontium (Sr) (work function: 2.0 eV or more and 2.5 eV or less), barium (Ba) (work function: 2.52 eV) and the like can be given. One having a work function of 2.9 eV or less is particularly preferable.

As the rare-earth metal, scandium (Sc), yttrium (Y), cerium (Ce), terbium (Tb), ytterbium (Yb) and the like can be given. One having a work function of 2.9 eV or less is particularly preferable.

Among the above-mentioned metals, the preferable metals have a particularly high reducing ability, and hence can provide the resulting organic EL device with an improved luminance and a prolonged lifetime by adding a relative small amount to an electron-injecting region.

Examples of the alkali metal compound include an alkali oxide such as lithium oxide (Li₂O), cesium oxide (Cs₂O) or potassium oxide (K₂O), and an alkali halide such as lithium fluoride (LiF), sodium fluoride (NaF), cesium fluoride (CsF) or potassium fluoride (KF). Of these, lithium fluoride (LiF), lithium oxide (Li₂O) and sodium fluoride (NaF) are preferable.

Examples of the alkaline-earth metal compound include barium oxide (BaO), strontium oxide (SrO), calcium oxide (CaO), and mixtures thereof such as barium strontium acid (BaₓSr₁₋ₓO) (0<x<1) and barium calcium acid (BaₓCa₁₋ₓO) (0<x<1). Among these, BaO, SrO and CaO are preferred.

Examples of the rare-earth metal compound include ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃) and terbium fluoride (TbF₃). Among these, YbF₃, ScF₃ and TbF₃ are preferable.

The organic metal complexes are not particularly limited as long as they contain, as a metal ion, at least one of alkali metal ions, alkaline-earth metal ions, and rare-earth metal ions, as mentioned above. Meanwhile, preferred examples of the ligand include, but are not limited to, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzoimidazole, hydroxybenzotriazole, hydroxyfluborane, bipyridyl, phenanthroline, phthalocyanine, porphyrin, cyclopentadiene, β-diketones, azomethines, and derivatives thereof.

Regarding the addition form of the electron-donating dopant and the organic metal complex, it is preferred that the electron-donating dopant and the organic metal complex be formed in a shape of a layer or an island in the interfacial region. A preferred method for the formation is a method in which an organic substance as a light emitting material or an electron-injecting material for forming the interfacial region is deposited at the same time as at least one of the electron-donating dopant and the organic metal complex is deposited by a resistant heating deposition method, thereby dispersing at least one of the electron-donating dopant and the organic metal complex in the organic substance. The dispersion concentration by molar ratio of the organic substance to the electron-donating dopant and/or the organic metal complex is normally 100:1 to 1:100, preferably 5:1 to 1:5.

In a case where at least one of the electron-donating dopant and the organic metal complex is formed into the shape of a layer, the light-emitting material or electron-injecting material which serves as an organic layer in the interface is formed into the shape of a layer. After that, at least one of the electron-donating dopant and the organic metal complex is solely deposited by the resistant heating deposition method to form a layer preferably having a thickness of 0.1 nm or more and 15 nm or less.

In a case where at least one of the electron-donating dopant and the organic metal complex is formed into the shape of an island, the light emitting material or the electron injecting material which serves as an organic layer in the interface is formed into the shape of an island. After that, at least one of the electron-donating dopant and the organic metal complex is solely deposited by the resistant heating deposition method to form an island preferably having a thickness of 0.05 nm or more and 1 nm or less.

In addition, the ratio of the main component to at least one of the electron-donating dopant and the organic metal complex in the organic EL device of the invention is preferably 5:1 to 1:5, more preferably 2:1 to 1:2 in terms of molar ratio.

In the organic EL device of the invention, configurations of other layers than those in which the above-mentioned material for an organic EL device of the invention is used are not particularly restricted, and known materials or the like can be used. Hereinbelow, a brief explanation will be made on the layer of the device according to one embodiment. However, materials to be applied to the organic EL device of the invention are not limited to those mentioned below.

### [Substrate]

As the substrate, a glass sheet, a polymer sheet or the like can be used.

Examples of the glass sheet include soda lime glass, barium-strontium-containing glass, lead glass, aluminosilicate glass, borosilicate glass, barium borosilicate glass, quartz, and the like. Examples of materials of the polymer sheet include polycarbonate, acryl, polyethylene terephthalate, polyethersulfone, polysulfone, and the like.

### [Anode]

The anode is formed of a conductive material, for example. A conductive material having a work function larger than 4 eV is suitable.

As the conductive material, carbon, aluminum, vanadium, iron, cobalt, nickel, tungsten, silver, gold, platinum, palladium, alloys thereof, an oxide metal such as tin oxide and indium oxide used in an ITO substrate and a NESA substrate and an organic conductive resin such as polythiophene and polypyrrole can be given.

If necessary, the anode may be formed of two or more layers.

### [Cathode]

The cathode is formed of a conductive material, for example. A conductive material having a work function smaller than 4 eV is suitable.

As the conductive material, magnesium, calcium, tin, lead, titanium, yttrium, lithium, ruthenium, manganese, aluminum, lithium fluoride and alloys thereof can be given. The conductive material is not limited thereto.

As the alloy, a magnesium/silver alloy, a magnesium/indium alloy, a lithium/aluminum alloy or the like can be given as representative examples. The alloys are not limited thereto. The amount ratio of metals forming an alloy is controlled by the temperature of a deposition source, the atmosphere, the degree of vacuum or the like, and an appropriate ratio is selected.

If necessary, the cathode may be formed of two or more layers. The cathode can be formed by forming a thin film by subjecting the above-mentioned conductive material to a method such as deposition, sputtering or the like.

When outcoupling light from the emitting layer through the cathode, it is preferable that the cathode have a light transmittance of more than 10%.

The sheet resistance of the cathode is preferably several hundred Ω/square or less. The thickness of the cathode is normally 10 nm to 1 μm, and preferably 50 to 200 nm.

### [Emitting Layer]

When a phosphorescent emitting layer is formed by using materials other than the material for an organic EL device of the invention, materials which are known as a material for a phosphorescent emitting layer can be used. Specifically, reference can be made to the Japanese Patent Application No. 2005-517938 or the like.

The organic EL device of the invention may comprise a fluorescent emitting layer as the device shown in FIG. 2. As the fluorescent emitting layer, known materials can be used.

The emitting layer can be a double-host (often referred to as host/co-host) type. Specifically, in the emitting layer, an electron-transporting host and a hole-transporting host may be combined to control the carrier balance.

The emitting layer also can be of a double-dopant type. By incorporating two or more kinds of dopant materials having a high quantum yield to the emitting layer, each dopant emits. For example, there may be a case that a yellow emitting layer is realized by co-depositing a host, and a red dopant and a green dopant.

As the host material in the emitting layer other than the material for an organic EL device of the invention, a compound comprising any of a carbazole ring, a dibenzofuran ring and a dibenzothiophene ring is preferable.

As the host material in the emitting layer other than the material for an organic EL device of the invention, a compound represented by the following formula (a) can preferably be given.

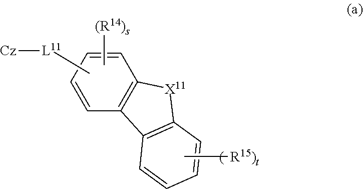

wherein L¹¹ is a single bond, a substituted or unsubstituted arylene group including 6 to 30 ring carbon atoms or a heteroarylene group including 5 to 30 ring atoms;

X¹¹ is O, S, Se or Te;

R¹⁴ and R¹⁵ are independently a substituted or unsubstituted aryl group including 6 to 30 ring carbon atoms, a heteroaryl group including 5 to 30 ring atoms, a substituted or unsubstituted alkyl group including 1 to 30 carbon atoms, a substituted or unsubstituted alkylsily group, a substituted or unsubstituted arylsilyl group and a substituted or unsubstituted heteroarylsilyl group;

s is an integer of 0 to 3;

t is an integer of 0 to 4; and

Cz is a group represented by the following formula (a-1) or the following formula (a-2):

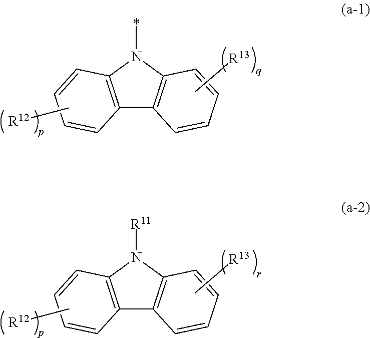

wherein * is a bonding position with L¹¹;

R¹¹ is a hydrogen atom, a substituted or unsubstituted aryl group including 6 to 30 ring carbon atoms, a heteroaryl group including 5 to 30 ring atoms or a substituted or unsubstituted alkyl group including 1 to 30 carbon atoms;

R¹² and R¹³ are independently a substituted or unsubstituted aryl group including 6 to 30 ring carbon atoms, a heteroaryl group including 5 to 30 ring atoms or a substituted or unsubstituted alkyl group including 1 to 30 carbon atoms;

p and q are independently an integer of 0 to 4; and

r is an integer of 0 to 3.

As the arylene group including 6 to 30 ring carbon atoms in the formula (a) and the heteroarylene group including 5 to 30 ring atoms of L¹¹ in the formula (a), the same groups as those for L in the formula (1) can be mentioned.

As the aryl group including 6 to 30 ring carbon atoms, the heteroaryl group including 5 to 30 ring atoms and the alkyl group including 1 to 30 carbon atoms of R¹¹ in the formula (a), the same groups as those of R₁ and Rₐ in the formula (1) can be given. As the alkylsilyl group, the arylsilyl group and the heteroaryl group of R¹¹ are independently a group obtained by arbitrarily combining the alkyl group, the aryl group and the heteroaryl group mentioned above.

As the aryl group including 6 to 30 ring carbon atoms, the heteroaryl group including 5 to 30 ring atoms and the alkyl group including 1 to 30 carbon atoms of R₁₂ to R₁₅ in the formula (a), the same groups as those of Rₐ in the formula (1) can be given.

Specific examples of the compound represented by the formula (a) will be given below.

The compounds represented by the formula (a) are not restricted to those shown below. Among the compounds shown below, X is an oxygen atom or a sulfur atom, and R′ is a hydrogen atom or a methyl group.

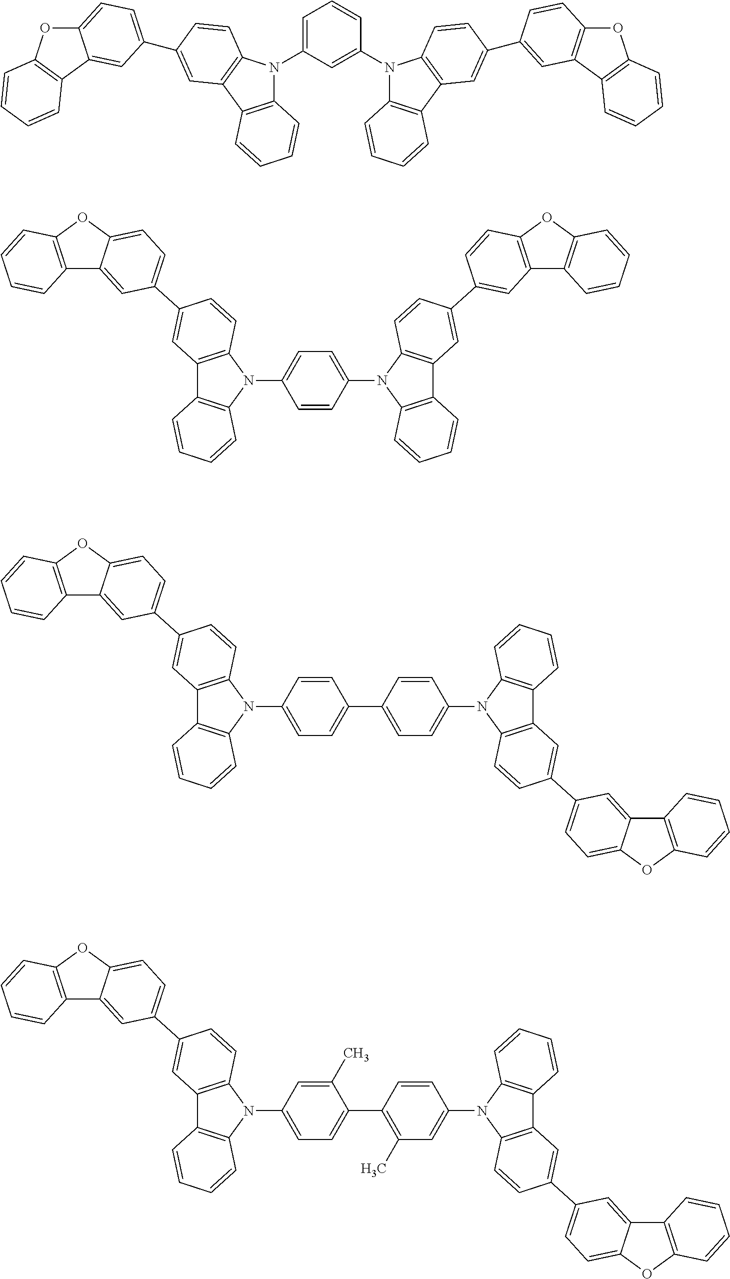 [SMILES: c1cc(-n2c3ccccc3c3cc(-c4ccc5oc6ccccc6c5c4)ccc32)cc(-n2c3ccccc3c3cc(-c4ccc5oc6ccccc6c5c4)ccc32)c1 ; c1ccc2c(c1)oc1ccc(-c3ccc4c(c3)c3ccccc3n4-c3ccc(-n4c5ccccc5c5cc(-c6ccc7oc8ccccc8c7c6)ccc54)cc3)cc12 ; c1ccc2c(c1)oc1ccc(-c3ccc4c(c3)c3ccccc3n4-c3ccc(-c4ccc(-n5c6ccccc6c6cc(-c7ccc8oc9ccccc9c8c7)ccc65)cc4)cc3)cc12 ; Cc1cc(-n2c3ccccc3c3cc(-c4ccc5oc6ccccc6c5c4)ccc32)ccc1-c1ccc(-n2c3ccccc3c3cc(-c4ccc5oc6ccccc6c5c4)ccc32)cc1C]

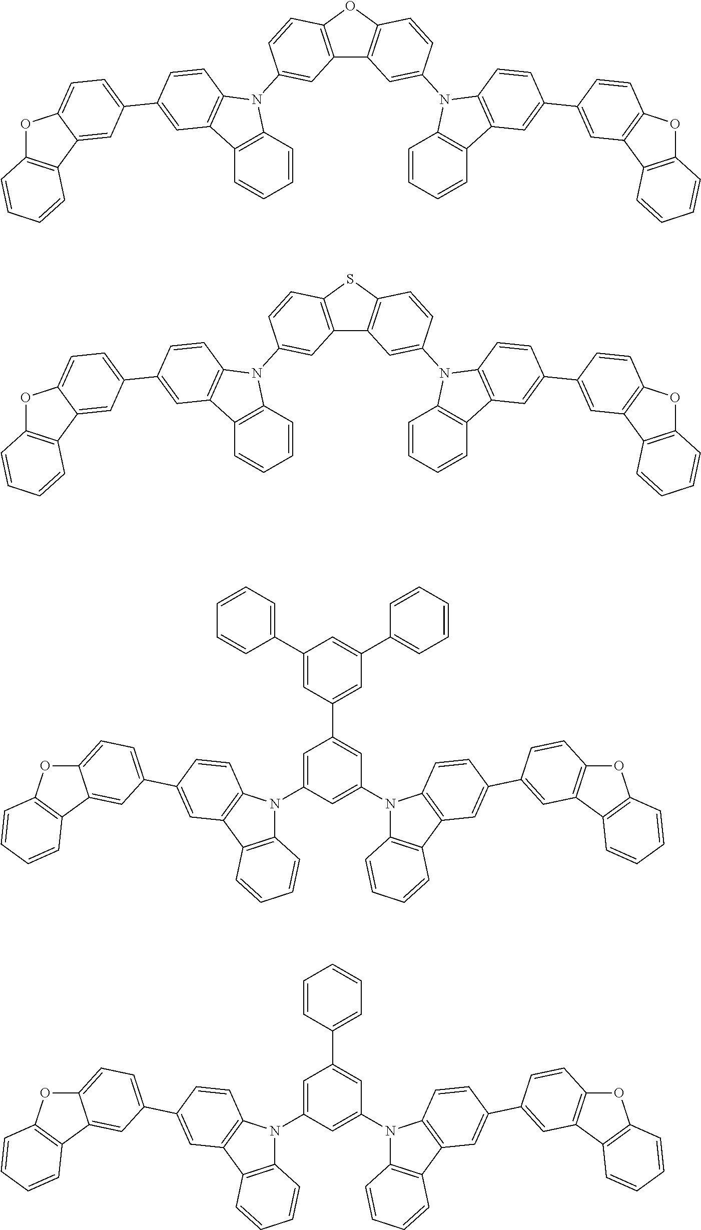 [SMILES: c1ccc2c(c1)oc1ccc(-c3ccc4c(c3)c3ccccc3n4-c3ccc4oc5ccc(-n6c7ccccc7c7cc(-c8ccc9oc%10ccccc%10c9c8)ccc76)cc5c4c3)cc12 ; c1ccc2c(c1)oc1ccc(-c3ccc4c(c3)c3ccccc3n4-c3ccc4sc5ccc(-n6c7ccccc7c7cc(-c8ccc9oc%10ccccc%10c9c8)ccc76)cc5c4c3)cc12 ; c1ccc(-c2cc(-c3ccccc3)cc(-c3cc(-n4c5ccccc5c5cc(-c6ccc7oc8ccccc8c7c6)ccc54)cc(-n4c5ccccc5c5cc(-c6ccc7oc8ccccc8c7c6)ccc54)c3)c2)cc1 ; c1ccc(-c2cc(-n3c4ccccc4c4cc(-c5ccc6oc7ccccc7c6c5)ccc43)cc(-n3c4ccccc4c4cc(-c5ccc6oc7ccccc7c6c5)ccc43)c2)cc1]

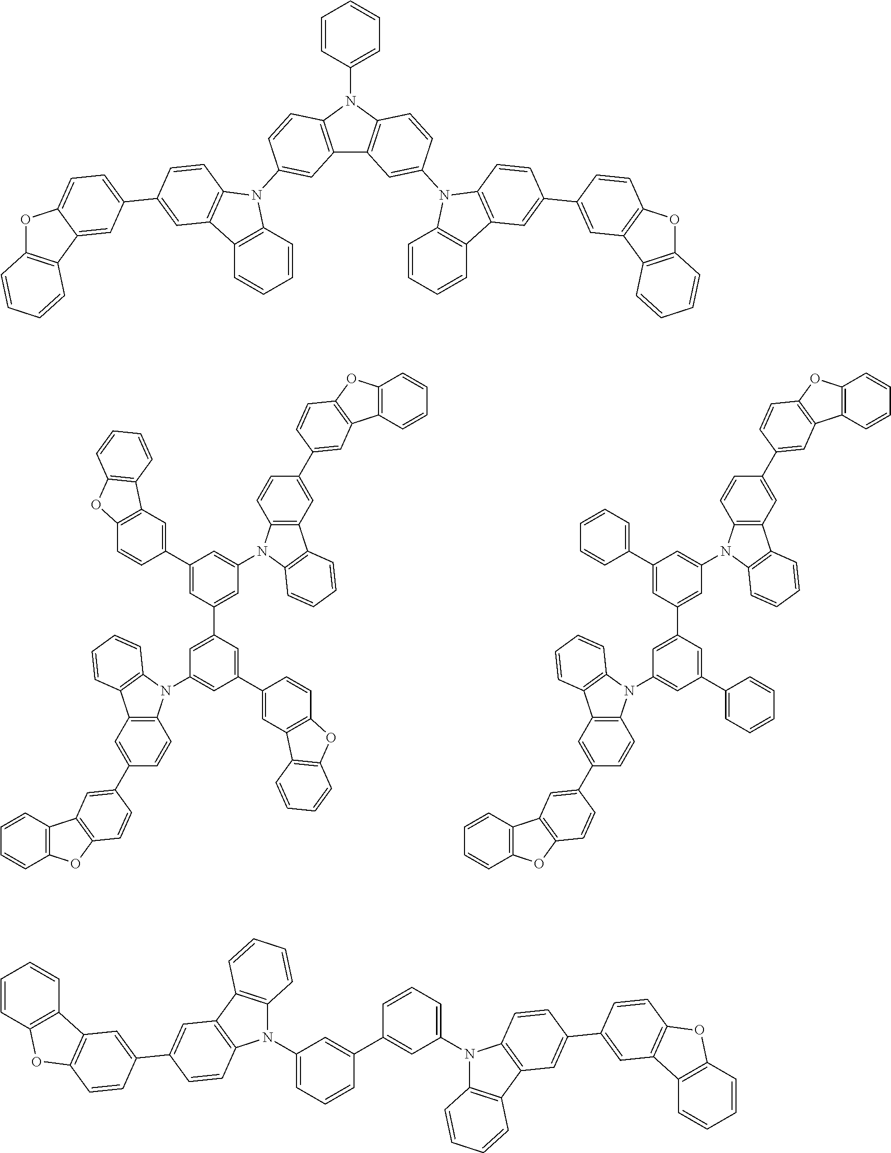

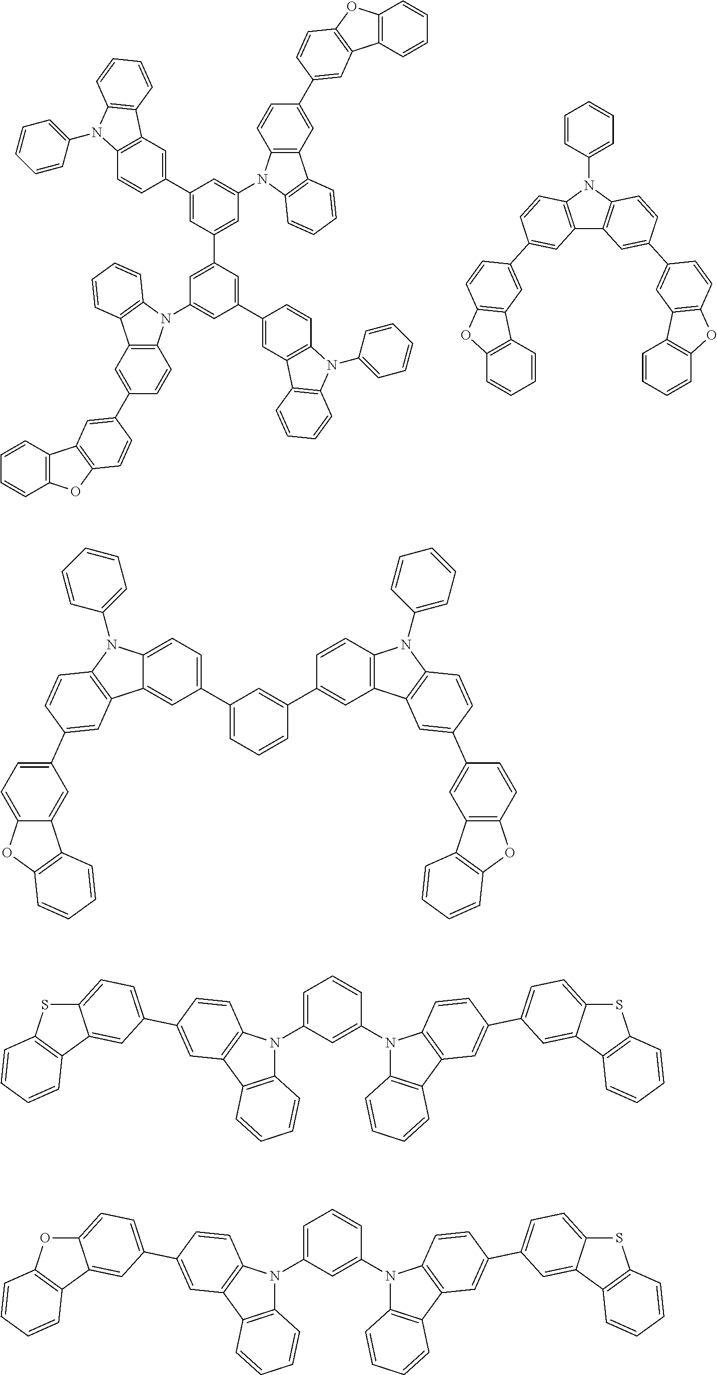

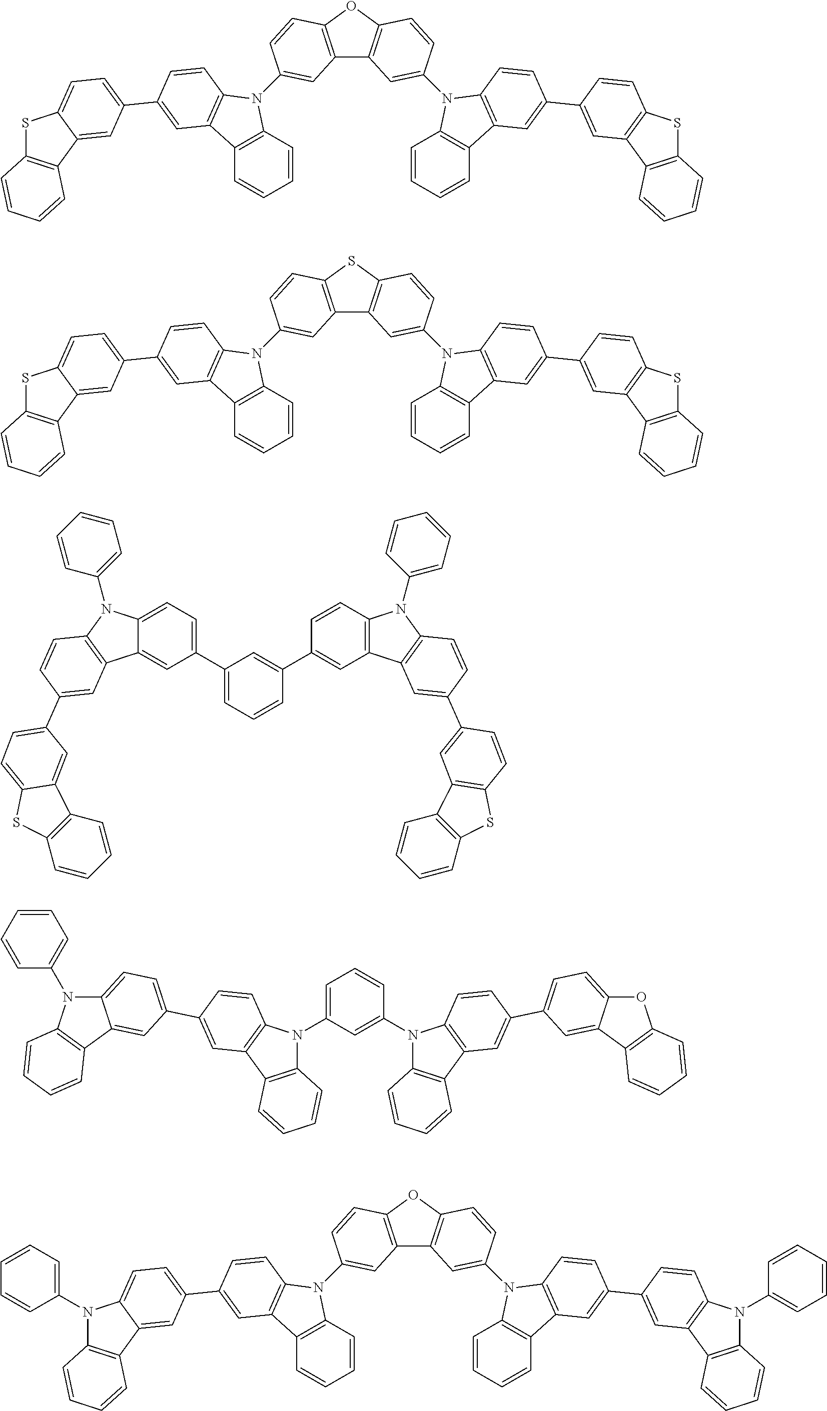

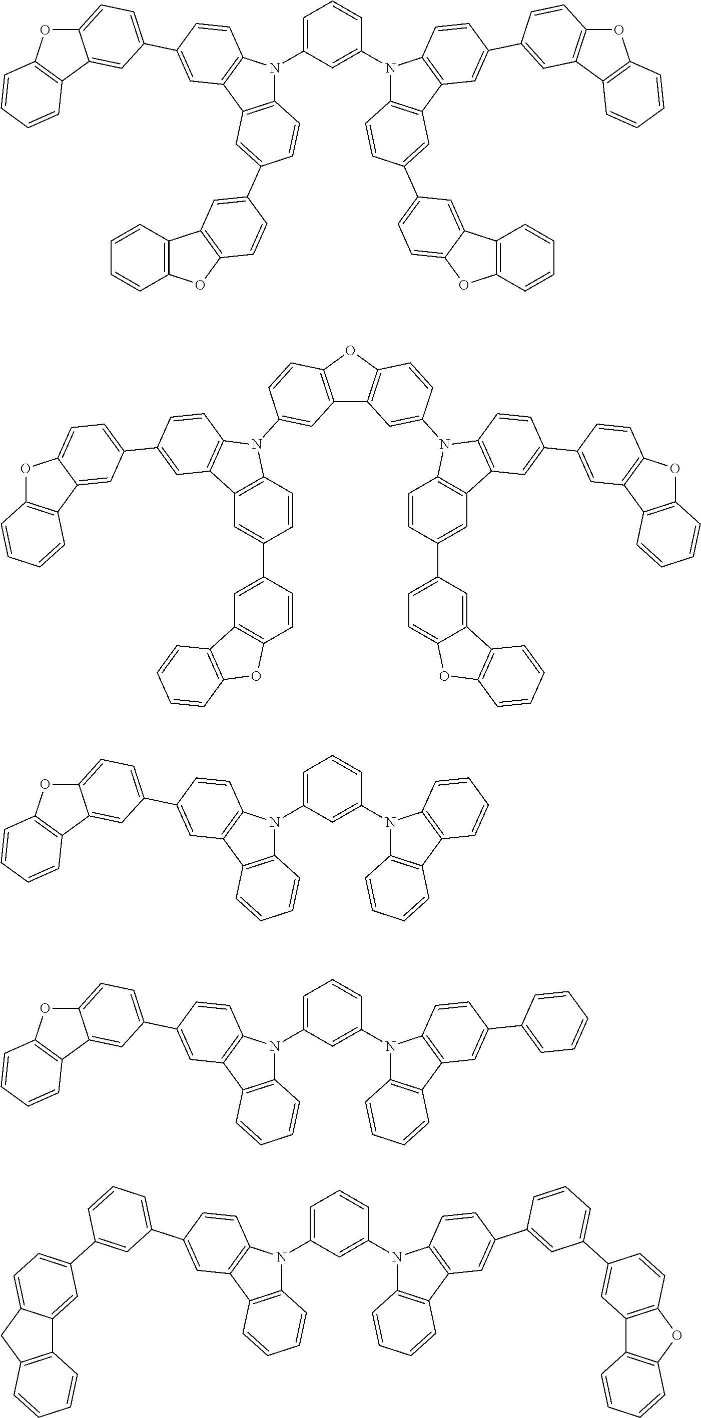

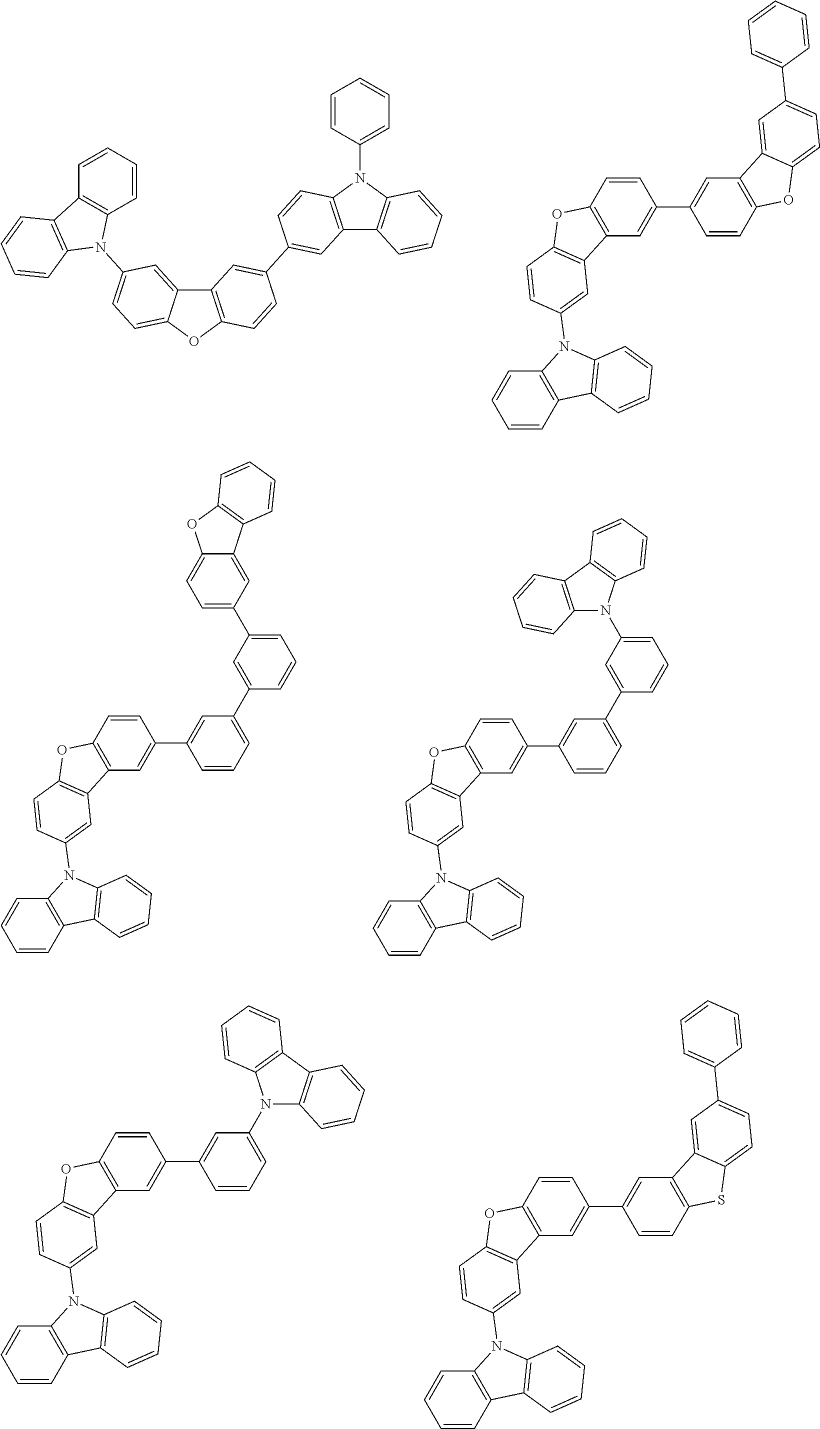 [SMILES: c1ccc(-n2c3ccccc3c3cc(-c4ccc5oc6ccc(-n7c8ccccc8c8ccccc87)cc6c5c4)ccc32)cc1 ; c1ccc(-c2ccc3oc4ccc(-c5ccc6oc7ccc(-n8c9ccccc9c9ccccc98)cc7c6c5)cc4c3c2)cc1 ; c1cc(-c2cccc(-c3ccc4oc5ccc(-n6c7ccccc7c7ccccc76)cc5c4c3)c2)cc(-c2ccc3oc4ccccc4c3c2)c1 ; c1cc(-c2cccc(-n3c4ccccc4c4ccccc43)c2)cc(-c2ccc3oc4ccc(-n5c6ccccc6c6ccccc65)cc4c3c2)c1 ; c1cc(-c2ccc3oc4ccc(-n5c6ccccc6c6ccccc65)cc4c3c2)cc(-n2c3ccccc3c3ccccc32)c1 ; c1ccc(-c2ccc3sc4ccc(-c5ccc6oc7ccc(-n8c9ccccc9c9ccccc98)cc7c6c5)cc4c3c2)cc1]

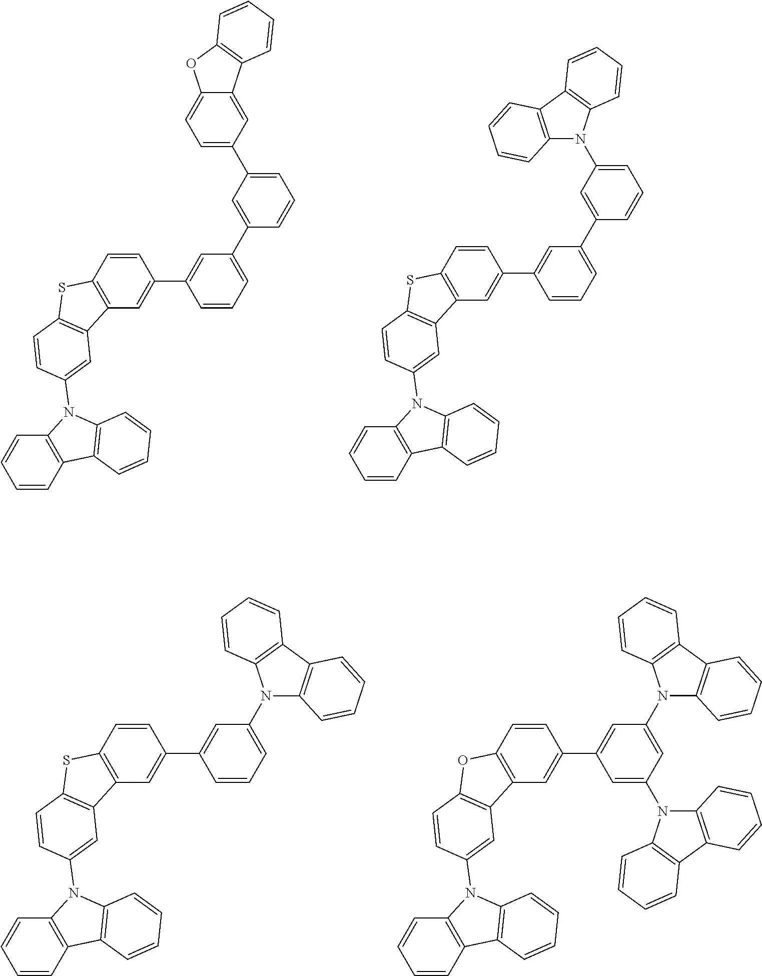 [SMILES: c1cc(-c2cccc(-c3ccc4sc5ccc(-n6c7ccccc7c7ccccc76)cc5c4c3)c2)cc(-c2ccc3oc4ccccc4c3c2)c1 ; c1cc(-c2cccc(-n3c4ccccc4c4ccccc43)c2)cc(-c2ccc3sc4ccc(-n5c6ccccc6c6ccccc65)cc4c3c2)c1 ; c1cc(-c2ccc3sc4ccc(-n5c6ccccc6c6ccccc65)cc4c3c2)cc(-n2c3ccccc3c3ccccc32)c1 ; c1ccc2c(c1)c1ccccc1n2-c1cc(-c2ccc3oc4ccc(-n5c6ccccc6c6ccccc65)cc4c3c2)cc(-n2c3ccccc3c3ccccc32)c1]

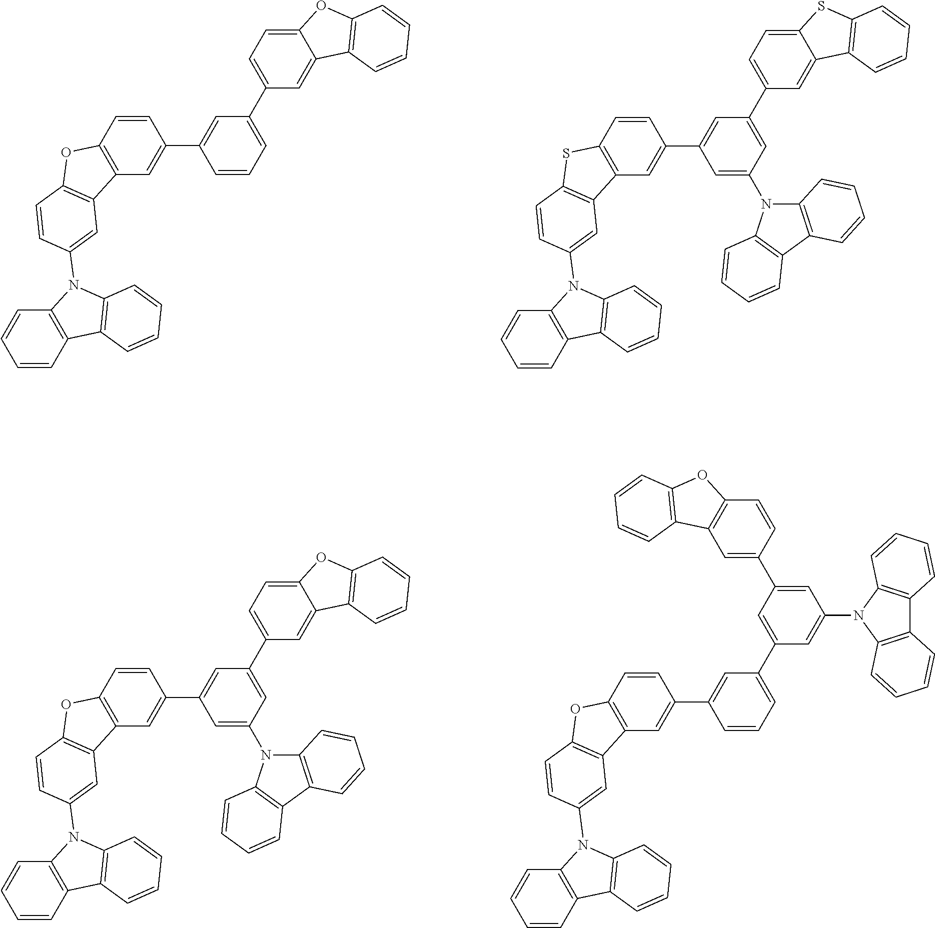 [SMILES: c1cc(-c2ccc3oc4ccccc4c3c2)cc(-c2ccc3oc4ccc(-n5c6ccccc6c6ccccc65)cc4c3c2)c1 ; c1ccc2c(c1)sc1ccc(-c3cc(-c4ccc5sc6ccc(-n7c8ccccc8c8ccccc87)cc6c5c4)cc(-n4c5ccccc5c5ccccc54)c3)cc12 ; c1ccc2c(c1)oc1ccc(-c3cc(-c4ccc5oc6ccc(-n7c8ccccc8c8ccccc87)cc6c5c4)cc(-n4c5ccccc5c5ccccc54)c3)cc12 ; c1cc(-c2cc(-c3ccc4oc5ccccc5c4c3)cc(-n3c4ccccc4c4ccccc43)c2)cc(-c2ccc3oc4ccc(-n5c6ccccc6c6ccccc65)cc4c3c2)c1]

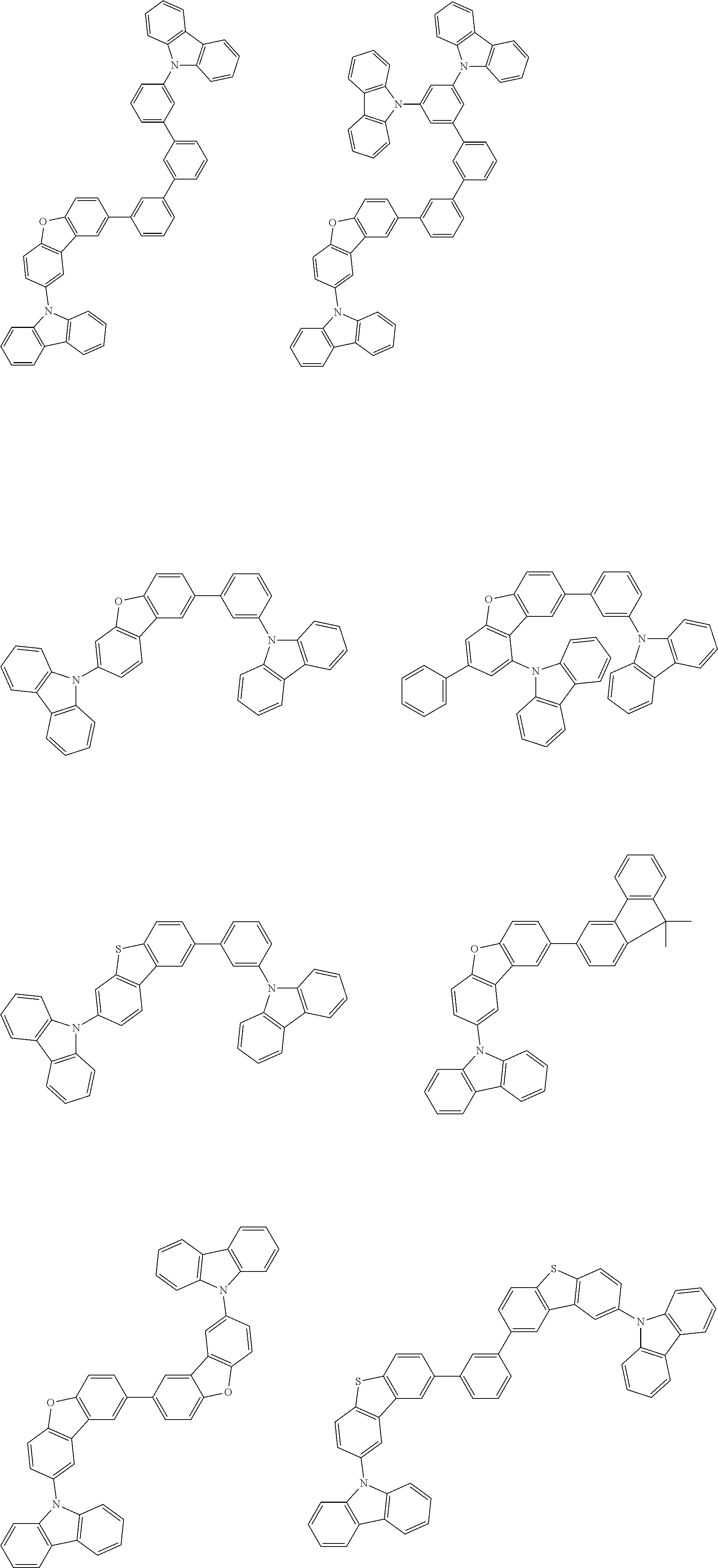

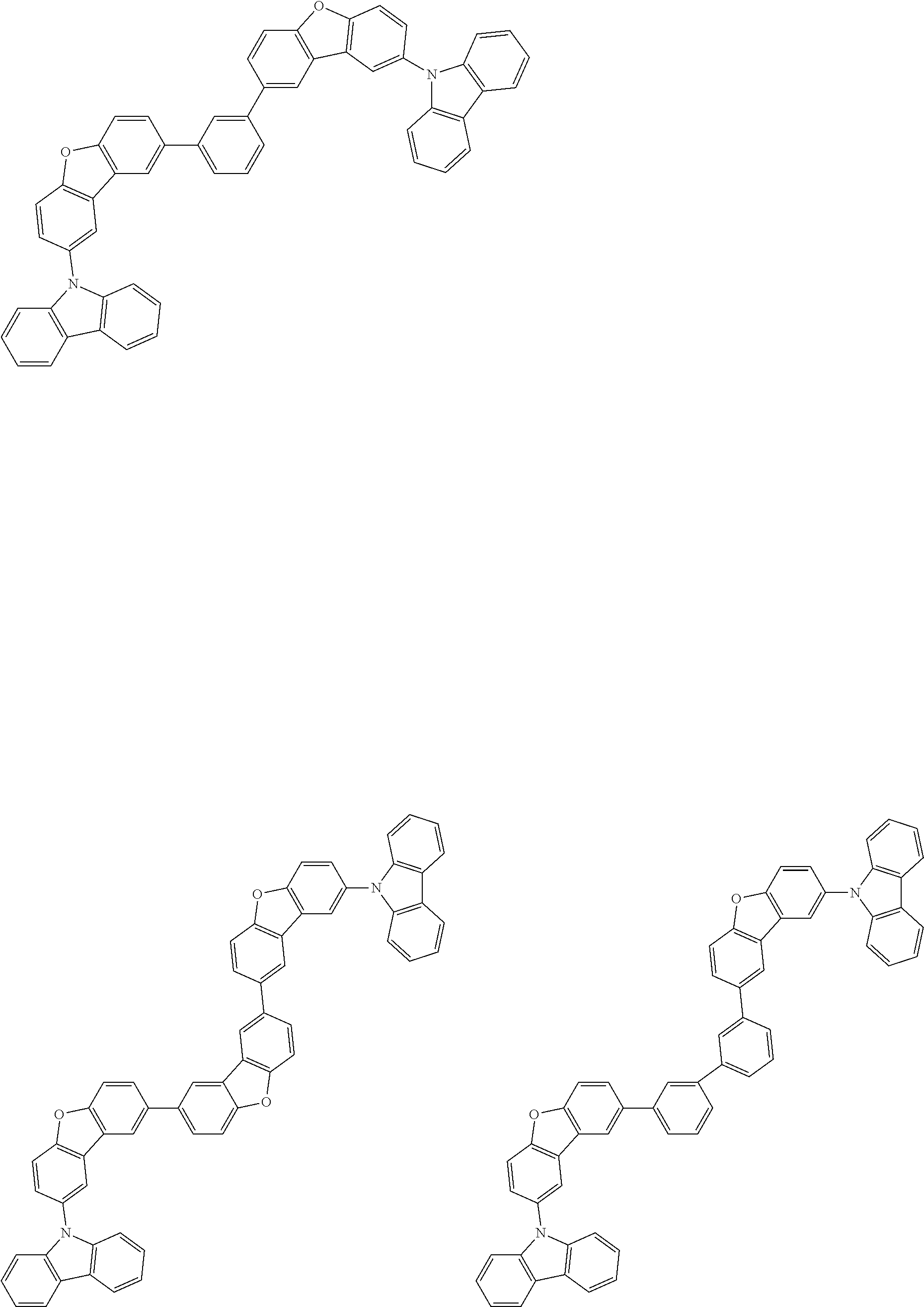 [SMILES: c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1 ; c1ccc2c(c1)c1ccccc1n2-c1ccc2oc3ccc(-c4ccc5oc6ccc(-c7ccc8oc9ccc(-n%10c%11ccccc%11c%11ccccc%11%10)cc9c8c7)cc6c5c4)cc3c2c1 ; c1cc(-c2cccc(-c3ccc4oc5ccc(-n6c7ccccc7c7ccccc76)cc5c4c3)c2)cc(-c2ccc3oc4ccc(-n5c6ccccc6c6ccccc65)cc4c3c2)c1]

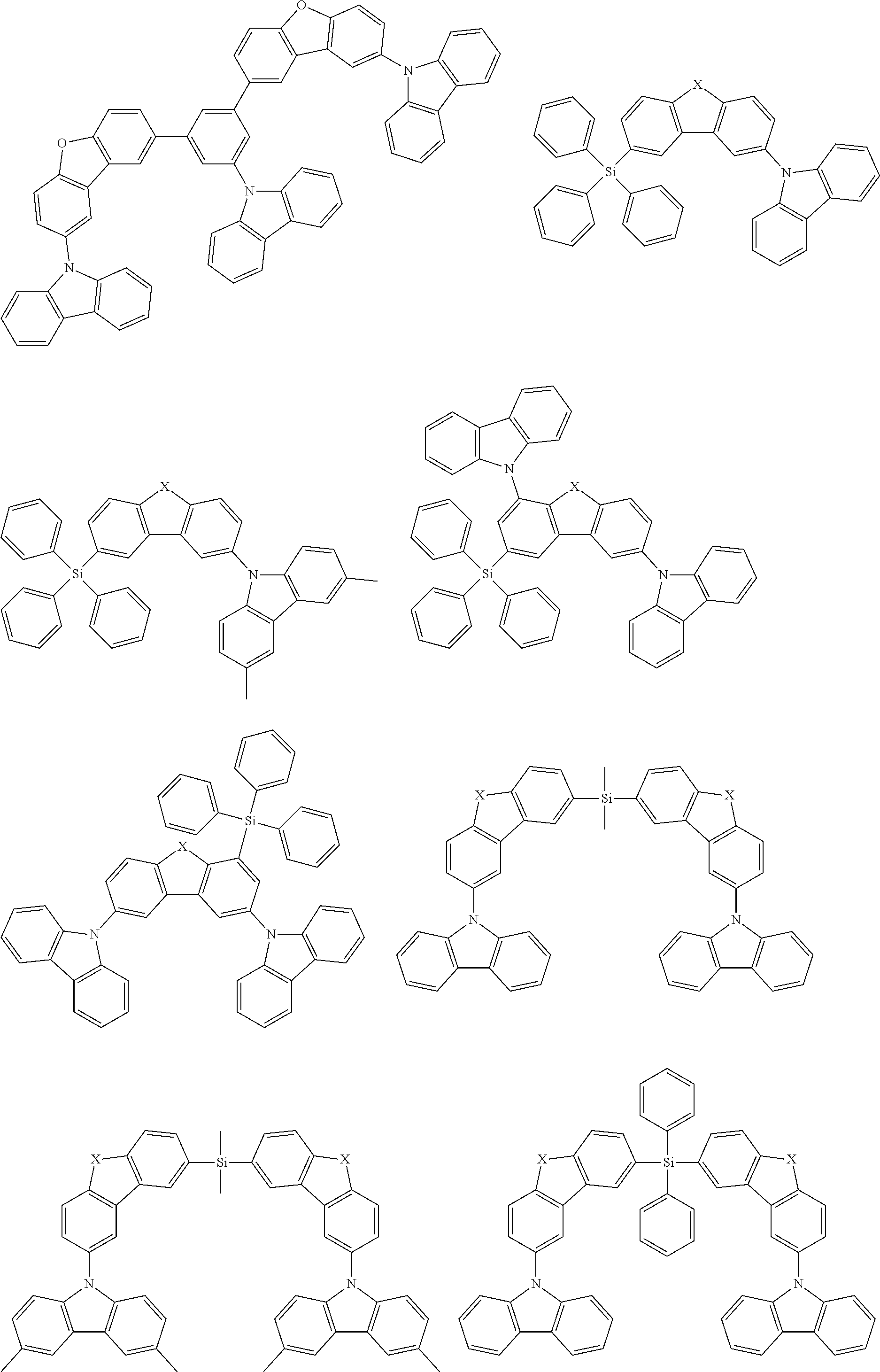

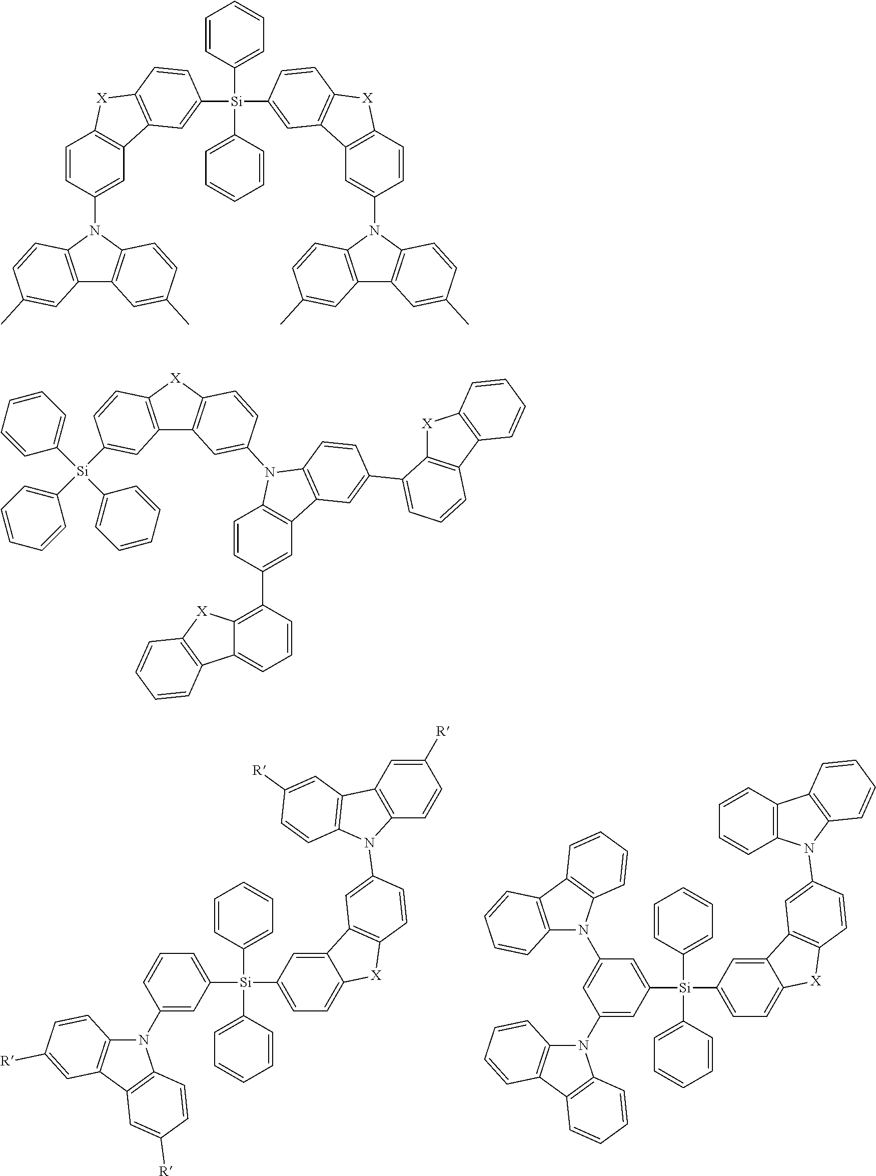

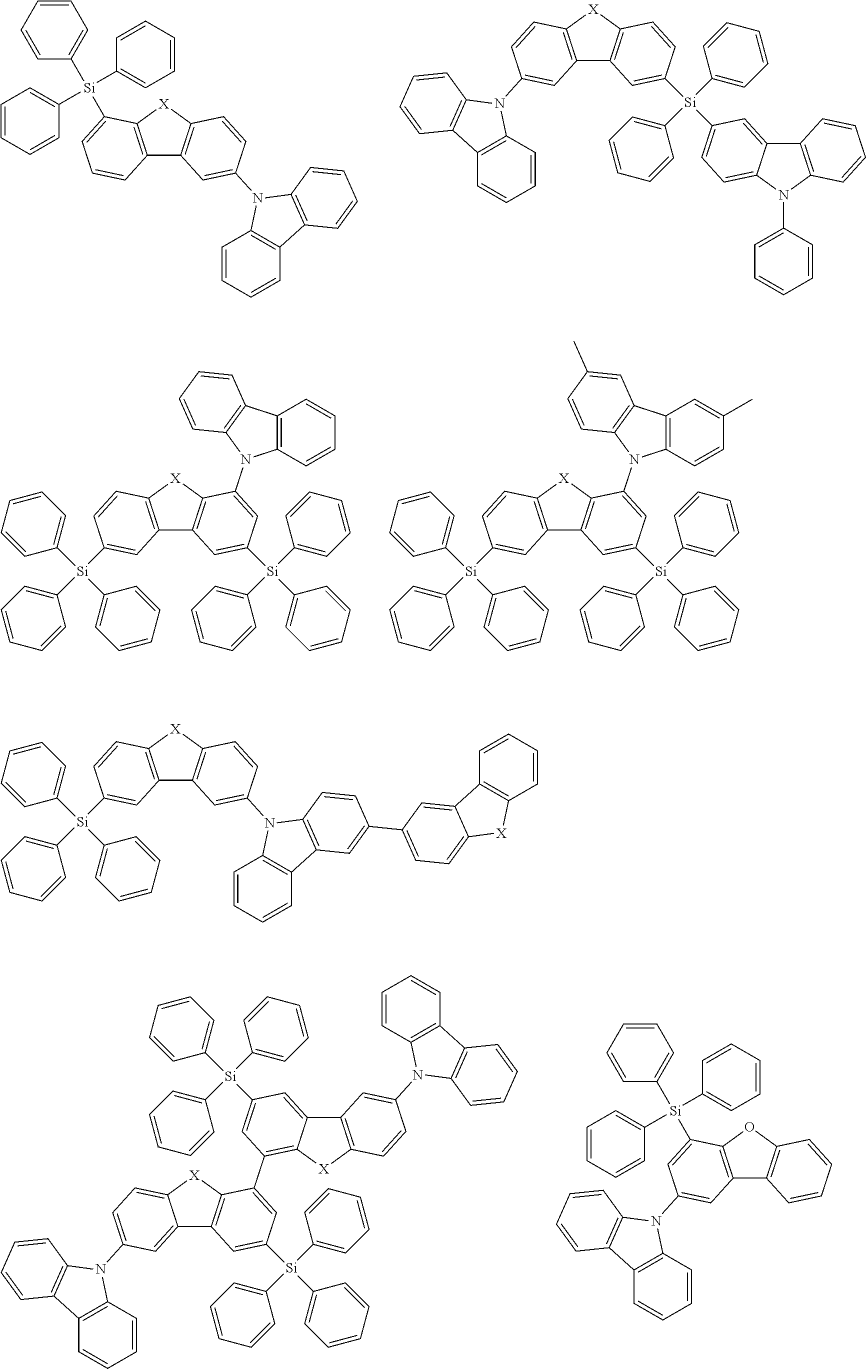

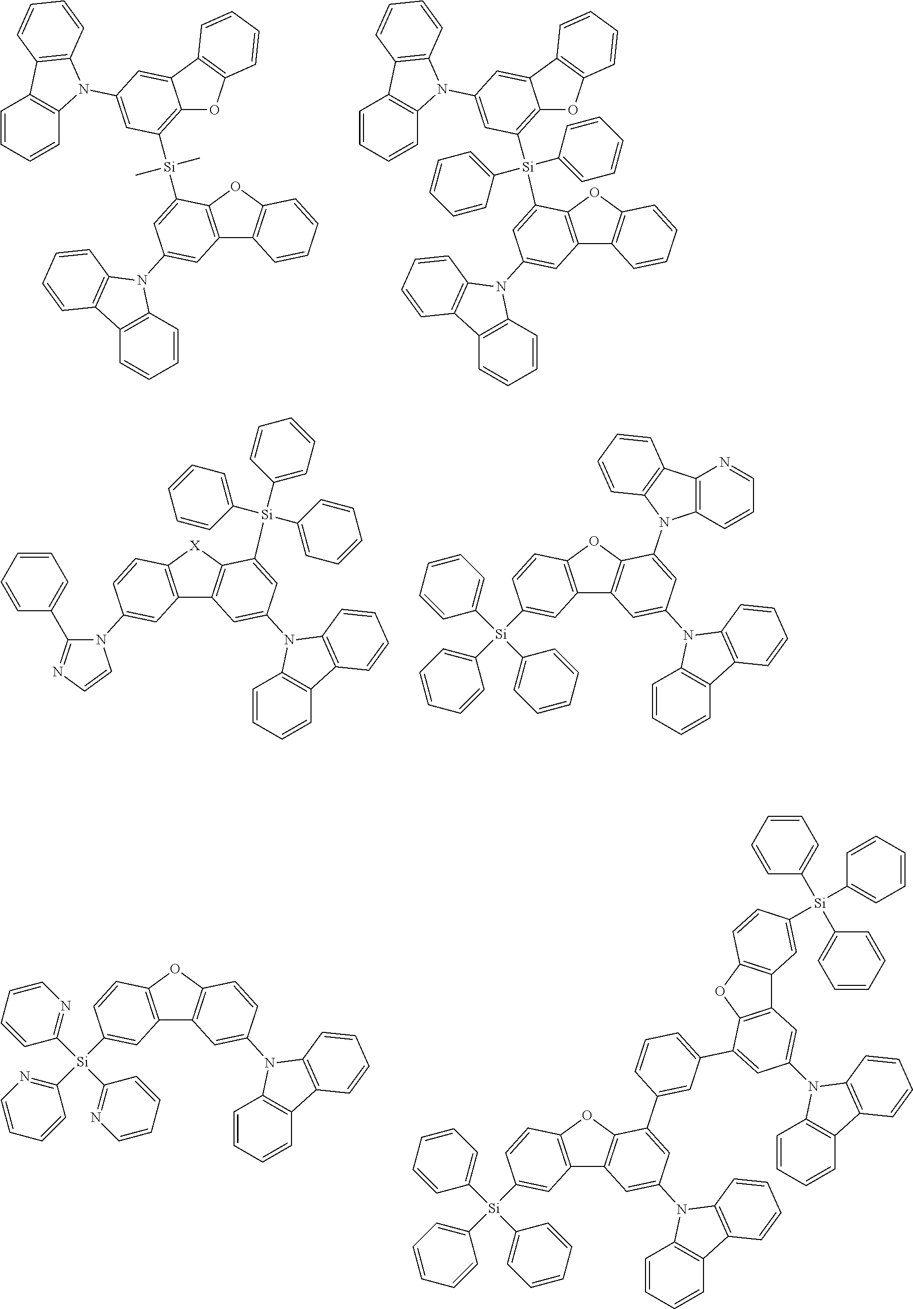

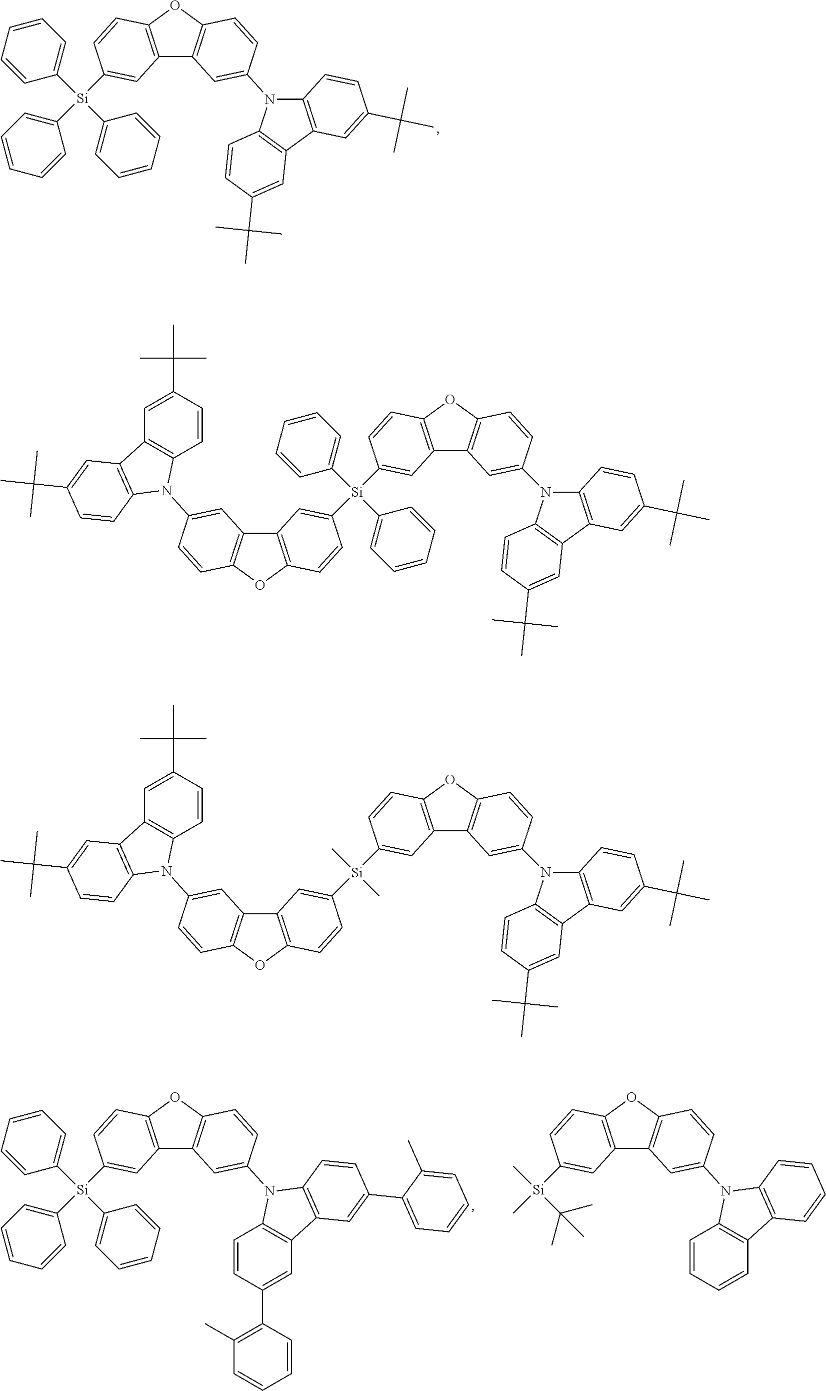

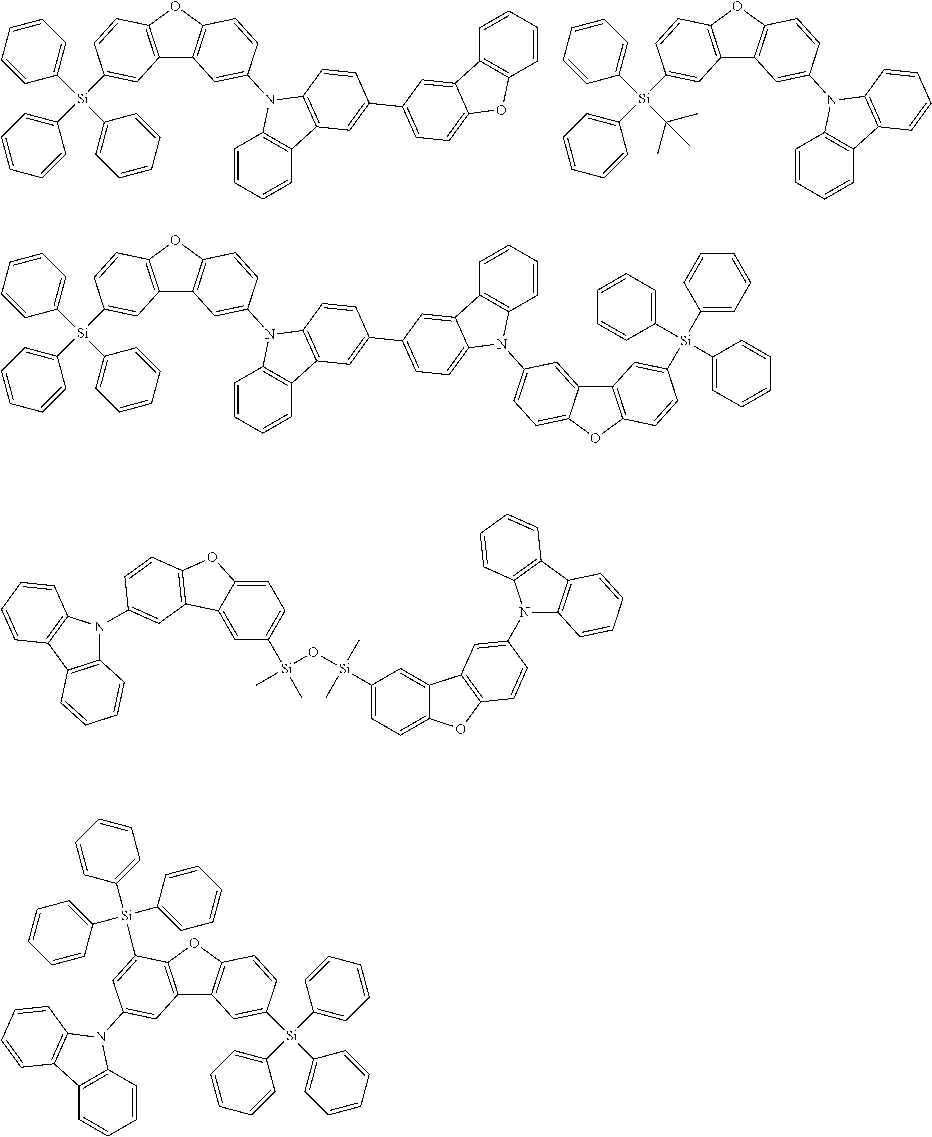

As the host material in the emitting layer other than the material for an organic EL device of the invention, a compound including a carbazole ring and a dibenzofuran ring is particularly preferable.

The emitting layer may be a single layer or may have a stacked layer structure. When the emitting layers are stacked, due to accumulation of electrons and holes in the interface of the emitting layer, the recombination region may be concentrated in the emitting layer interface, whereby quantum efficiency is improved.

### [Hole-Injecting Layer and Hole-Transporting Layer]

The hole-injecting/transporting layer is a layer that helps holes to be injected to an emitting layer and transports the injected holes to an emitting region. It has a large hole mobility and normally a small ionization energy of 5.6 eV or less.

As the material for a hole-injecting/transporting layer, materials which can transport holes to an emitting layer at lower electric field intensity are preferable. In addition, it is preferred that the hole mobility be at least 10⁻⁴ cm²/V·second when an electric field having an intensity of 10⁴ to 10⁶ V/cm is applied, for example.

Specific examples of materials for a hole-injecting/transporting layer include triazole derivatives (see U.S. Pat. No. 3,112,197 and others), oxadiazole derivatives (see U.S. Pat. No. 3,189,447 and others), imidazole derivatives (see JP-B-37-16096 and others), polyarylalkane derivatives (see U.S. Pat. Nos. 3,615,402, 3,820,989 and 3,542,544, JP-B-45-555 and 51-10983, JP-A-51-93224, 55-17105, 56-4148, 55-108667, 55-156953 and 56-36656, and others), pyrazoline derivatives and pyrazolone derivatives (see U.S. Pat. Nos. 3,180,729 and 4,278,746, JP-A-55-88064, 55-88065, 49-105537, 55-51086, 56-80051, 56-88141, 57-45545, 54-112637 and 55-74546, and others), phenylene diamine derivatives (see U.S. Pat. No. 3,615,404, JP-B-51-10105, 46-3712, 47-25336 and 54-119925, and others), arylamine derivatives (see U.S. Pat. Nos. 3,567,450, 3,240,597, 3,658,520, 4,232,103, 4,175,961 and 4,012,376, JP-B-49-35702 and 39-27577, JP-A-55-144250, 56-119132 and 56-22437, DE1,110,518, and others), amino-substituted chalcone derivatives (see U.S. Pat. No. 3,526,501, and others), oxazole derivatives (ones disclosed in U.S. Pat. No. 3,257,203, and others), styrylanthracene derivatives (see JP-A-56-46234, and others), fluorenone derivatives (JP-A-54-110837, and others), hydrazone derivatives (see U.S. Pat. No. 3,717,462, JP-A-54-59143, 55-52063, 55-52064, 55-46760, 57-11350, 57-148749 and 2-311591, and others), stilbene derivatives (see JP-A-61-210363, 61-228451, 61-14642, 61-72255, 62-47646, 62-36674, 62-10652, 62-30255, 60-93455, 60-94462, 60-174749 and 60-175052, and others), silazane derivatives (U.S. Pat. No. 4,950,950), polysilanes (JP-A-2-204996), and aniline copolymers (JP-A-2-282263).

Further, an inorganic compound such as P-type Si and P-type SiC can be used as the hole-injecting material.

As the material for a hole-injecting/transporting layer, a cross-linking material can be used. As the cross-linking hole-injecting/transporting layer, a layer formed of the cross-linking material disclosed in Chem. Mater. 2008, 20, 413-422, Chem. Mater. 2011, 23(3), 658-681, WO2008108430, WO2009102027, WO2009123269, WO2010016555, WO2010018813 or the like insolubilized by heat, light or the like can be given, for example.

### [Electron-Injecting Layer and Electron-Transporting Layer]

The electron-injecting/transporting layer helps electrons to be injected to an emitting layer and transports the injected electrons to an emitting region. It has a large electron mobility.

In the organic EL device, it is known that since emitted light is reflected by an electrode (a cathode, for example), emission outcoupled directly from an anode interferes with emission outcoupled after being reflected by the electrode. In order to utilize the interference effect efficiently, the film thickness of the electron injecting/transporting layer is appropriately selected to be several nm to several μm. When the film thickness is particularly large, it is preferred that the electron mobility be at least 10⁴ cm²/Vs or more at an applied electric field intensity of 10⁴ to 10⁶ V/cm in order to avoid an increase in voltage.

As the electron-transporting material used in the electron-injecting/transporting layer other than the material for an organic EL device of the invention containing the compound represented by the formula (1-2), an aromatic heterocyclic compound containing one or more hetero atoms in the molecule is preferably used, with a nitrogen-containing ring derivative being particularly preferable. Further, as the nitrogen-containing ring derivative, an aromatic ring compound having a nitrogen-containing 6-membered ring or 5-membered ring skeleton, or a fused aromatic ring compound having a nitrogen-containing 6-membered ring or 5-membered ring skeleton is preferable. Examples thereof include compounds containing a pyridine ring, a pyrimidine ring, a triazine ring, a benzimidazole ring, a phenanthroline ring, a quinazoline ring or the like in the skeleton.

In addition, an organic layer with a semiconductor property may be formed by doping a donor material (n) or doping an acceptor material (p). Representative examples of N-doping include one obtained by doping an electron-transporting material with a metal such as Li or Cs. Representative examples of P-doping include one obtained by doping a hole-transporting material with an acceptor material such as F4TCNQ (2,3,5,6-tetrafluoro-7,7,8,8-tetracyanoquinodimethane) (see Japan Patent No. 3695714, for example).

Each layer of the organic EL device of the invention can be formed by using known methods including the dry-type film formation such as vacuum deposition, sputtering, plasma, ion-plating or the like and the wet-type film formation such as spin coating, dipping, flow coating or the like.

The film thickness of each layer is not particularly limited, but should be set to be a proper thickness. If the film thickness is too large, a large voltage is required to be applied in order to obtain the certain light output, thereby leading to lowering in efficiency. If the film thickness is too small, due to generation of pinholes or the like, sufficient luminance cannot be obtained when an electric field is applied. Normally, the film thickness is preferably 5 nm to 10 μm, and the range of 10 nm to 0.2 μm is further preferable.

### EXAMPLES

The invention will be described in more detail in accordance with Synthesis Examples and Examples, which should not be construed as limiting the scope of the invention.

### Synthesis Example 1

### Synthesis of Compound (1)

### (1) Synthesis of Compound (1-a)

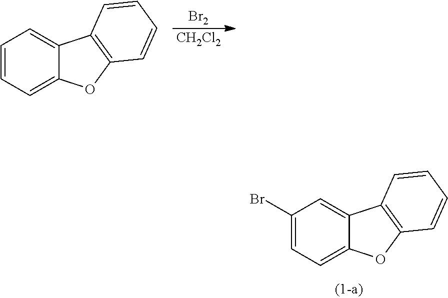

In a three-neck flask, 269.1 g (1600 mmol) of dibenzofuran and 1280 mL of dichloromethane were put, and the reactor was cooled to 0° C. in a nitrogen atmosphere. Then, 100 mL of a dichloromethane solution of 204.6 g of bromine was added dropwise to the reactor over a period of 40 minutes, followed by stirring at room temperature for 12 hours. After completion of the reaction, the reactor was cooled to 0° C., and 500 mL of water was added. Further, 100 mL of a 20% aqueous NaHSO₄ solution was added. The sample solution was transferred to a separating funnel, and extracted several times with dichloromethane. The thus extracted sample was washed with 300 mL of a 1N aqueous sodium hydroxide solution, dried with anhydrous magnesium sulfate, filtrated and concentrated. The resultant was washed by dispersing in hexane, thereby to obtain white solids.

The yield amount was 136 g. The yield was 55%.

### (2) Synthesis of Compound (1-b)

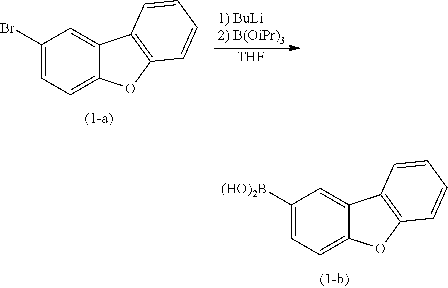 [SMILES: Brc1ccc2oc3ccccc3c2c1 ; OB(O)c1ccc2oc3ccccc3c2c1 ; "THF"]

In a three-neck flask, 20.0 g (80.9 mmol) of compound (1-a) and 200 mL of dehydrated tetrahydrofuran were put. The reactor was cooled to −70° C. in a nitrogen atmosphere. Then, 53 mL (88.9 mmol) of a 1.68M n-butyllithium hexane solution was added dropwise to the reactor, followed by stirring at −70° C. for 1 hour. Further, 37.3 mL (162 mmol) of triisopropyl borate was added, and stirred at room temperature for 6 hours. After completion of the reaction, 100 mL of a 1N aqueous HCl solution was added, and stirred for 30 minutes. The sample solution was transferred to a separating funnel, and extracted several times with dichloromethane. The thus extracted sample was dried with anhydrous magnesium sulfate, filtrated and concentrated. The resultant was washed by dispersing in hexane, thereby to obtain white solids.

The yield amount was 15.9 g. The yield was 93%.

### (3) Synthesis of Compound (1-c)

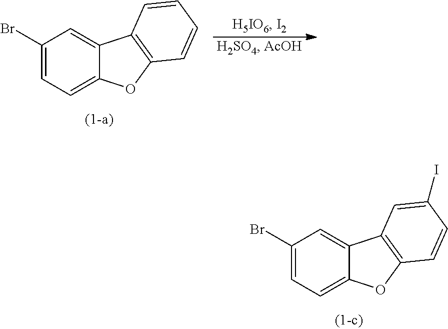

In a three-neck flask, 10.0 g (40.4 mmol) of compound (1-a), 1.96 g (8.60 mmol) of orthoperiodical acid, 4.08 g (16.1 mmol) of iodine, 8 mL of dilute sulfuric acid and 40 mL of acetic acid were put, and stirred at 70° C. for 3 hours. After cooling the reactor to room temperature, the reaction liquid was added to ice water. Precipitated solids were separated by filtration. The resulting solids were washed with methanol, thereby to obtain white solids.

The yield amount was 6.78 g. The yield was 45%.

### (4) Synthesis of Compound (1-d)

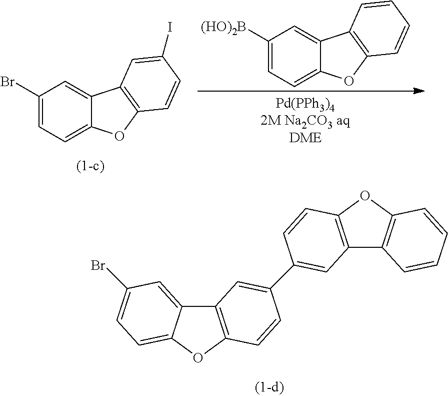 [SMILES: Brc1ccc2oc3ccc(I)cc3c2c1 ; OB(O)c1ccc2oc3ccccc3c2c1 ; Brc1ccc2oc3ccc(-c4ccc5oc6ccccc6c5c4)cc3c2c1]

In a three-neck flask, 9.72 g (26.1 mmol) of compound (1-c), 6.36 g (30.0 mmol) of compound (1-b), 45 mL of a 2M aqueous sodium carbonate solution, 90 mL of 1,2-dimethoxyethane and 1.51 g (1.31 mmol) of Pd(PPh₃)₄ were put. The resultant was refluxed in a nitrogen atmosphere for 12 hours.

After completion of the reaction, the sample solution was transferred to a separating funnel, and extracted several times with ethyl acetate. The thus extracted sample was dried with anhydrous magnesium sulfate, filtrated and concentrated. The resultant was purified by silica gel chromatography (hexane:ethyl acetate=10:1), thereby to obtain white solids.

The yield amount was 4.53 g. The yield was 42%.

### (5) Synthesis of Compound (1-e)

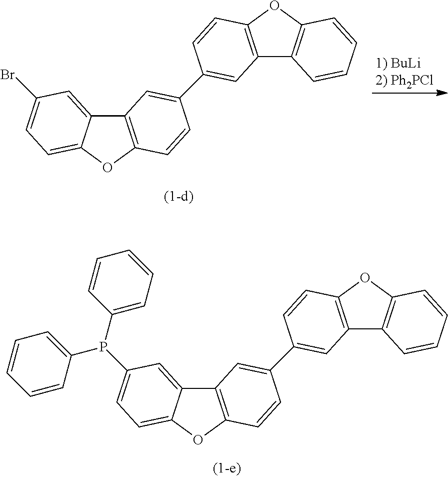 [SMILES: Brc1ccc2oc3ccc(-c4ccc5oc6ccccc6c5c4)cc3c2c1 ; c1ccc(P(c2ccccc2)c2ccc3oc4ccc(-c5ccc6oc7ccccc7c6c5)cc4c3c2)cc1]

In a three-neck flask, 4.00 g (9.68 mmol) of compound (1-d) and 25 mL of dehydrated tetrahydrofuran were put. The reactor was cooled to −70° C. in a nitrogen atmosphere. Then, 5.3 mL (8.71 mmol) of a 1.65M n-butyllithium hexane solution was added dropwise to the reactor, followed by stirring at −70° C. for 1 hour. Further, 3.57 mL (19.4 mmol) of chlorodiphenyl phosphine was added, and stirred at room temperature for 8 hours.

After completion of the reaction, 50 mL of water was added, and the mixture was transferred to a separating funnel, and extracted several times with ethyl acetate. The thus obtained organic layer was dried with anhydrous magnesium sulfate, filtrated and concentrated. The resultant was purified by silica gel chromatography (hexane:dichloromethane=3:1), thereby to obtain white solids.

The yield amount was 3.70 g. The yield was 82%.

### (6) Synthesis of Compound (1)

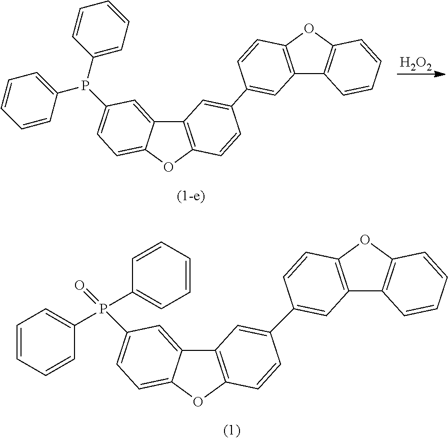

In a three-neck flask, 2.50 g (4.82 mmol) of compound (1-e) and 45 mL of dichloromethane were put. The reactor was cooled to 0° C. in a nitrogen atmosphere. 6 ml of an aqueous 30% hydrogen peroxide solution was added to the reactor, followed by stirring at room temperature for 6 hours.

After completion of the reaction, 50 mL of water was added, and the mixture was transferred to a separating funnel, and extracted with dichloromethane several times. The resulting organic layer was dried with anhydrous magnesium sulfate, filtrated and concentrated. The resultant was purified by silica gel chromatography (dichloromethane:ethyl acetate=2:1), thereby to obtain white solids.

The yield amount was 2.19 g. The yield was 85%.

### Example 1

### Fabrication of Organic EL Device

A glass substrate having a thickness of 130 nm having an ITO electrode line (manufactured by Geomatec Co., Ltd.) was subjected to ultrasonic-cleaning in isopropyl alcohol for five minutes, and then UV/ozone-cleaning for 30 minutes.

The cleaned glass substrate having an ITO electrode line was mounted on a substrate holder of a vacuum evaporation apparatus. Initially, compound (HI1) was deposited by resistant heating deposition on a surface of the glass substrate where the ITO electrode line was formed so as to cover the ITO electrode line, thereby forming a 20 nm-thick film of compound (HI1). Next, on this film, compound (HT1) was deposited by resistant heating deposition to form a 60 nm-thick film, and thin films were formed in sequence. The deposition rate was 1 Å/s. These thin films function as a hole-injecting layer and a hole-transporting layer, respectively.

Subsequently, on the hole-injecting/transporting layer, compound (H1) and compound (BD1) were simultaneously deposited by resistant heating deposition, whereby a 50 nm-thick thin film was formed. At this time, the compound (BD1) was deposited such that the mass of the compound (BD1) became 20% relative to the total mass of the compound (H1) and the compound (BD1). The deposition rates were 1.2 Å/s and 0.3 Å/s, respectively. This thin film functions as a phosphorescent emitting layer.

Subsequently, on this phosphorescent emitting layer, compound (H1) was deposited by resistant heating deposition to form a 10 nm-thick thin film. The deposition rate was 1.2 Å/s. This thin film functions as a hole-blocking layer.

Then, on this blocking layer, compound (1) was deposited by resistant heating deposition, whereby a 10 nm-thick thin film was formed. The deposition rate was 1.0 Å/s. This film functions as an electron-injecting layer.

Subsequently, on the electron-injecting layer, LiF was deposited at a deposition rate of 0.1 Å/s to form a 1.0 nm-thick film.

Next, on the LiF film, metal aluminum was deposited at a deposition rate of 8.0 Å/s to form a metal cathode having a film thickness of 80 nm, whereby an organic EL device was obtained.

### Example 2

### Fabrication of Organic EL Device

An organic EL device was fabricated and evaluated in the same manner as in Example 1, except that the hole-blocking layer was formed by using compound (HBL1) instead of compound (H1). The results are shown in Table 1.

### Example 3

### Fabrication of Organic EL Device

In Example 1, on the phosphorescent emitting layer, compound (1) was deposited by resistant heating deposition to form a 20 nm-thick thin film at a deposition rate of 1 Å/s. This thin film functions as a hole-blocking layer and an electron-injecting layer.

Subsequently, on the hole-blocking layer and the electron-injecting layer, LiF was formed into a 1.0 nm-thick film at a deposition rate of 0.1 Å/s. Then, on this LiF film, metal aluminum was deposited at a deposition rate of 8.0 Å/s to form an 80 nm-thick metal cathode, whereby an organic EL device was fabricated and evaluated. The results are shown in Table 1.

The structural formulas of the compounds used are shown below.

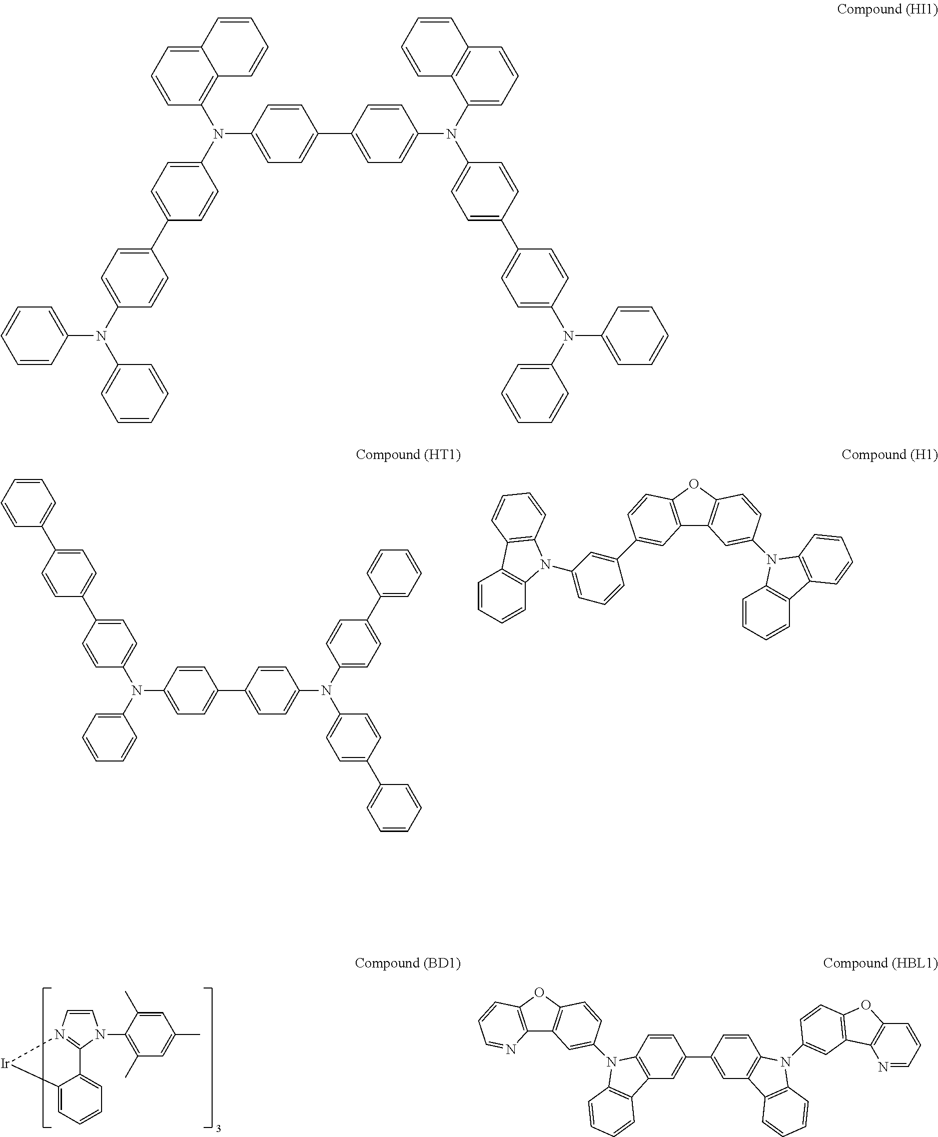

### [Evaluation of Organic EL Device]

The organic EL devices obtained by the method mentioned above were evaluated by the method described below. The results are shown in Table 1.

### (1) Voltage (V)

In a dry nitrogen gas atmosphere of 23° C., a voltage was applied to a device in which electric wiring had been conducted by means of KEITHLY 236 SOURCE MEASURE UNIT, thereby to cause the device to emit light. Then, a voltage concerning on the wiring resistance other than the device was deducted, whereby the voltage applied to the device was measured. The luminance was measured at the same time of applying and measuring the voltage, by using a luminance meter (spectroradiometer CS-1000 manufactured by Konica Minolta, Inc.). The voltage at a device luminance of 100 cd/m² was determined from these measurement results.

### (2) External Quantum Efficiency (%)

In a dry nitrogen gas atmosphere of 23° C., the external quantum efficiency at a luminance of 1000 cd/m² was measured by using a luminance meter (spectroradiometer CS-1000 manufactured by Konica Minolta, Inc.).

### (3) Half Life (Hour(s))

A continuous current test (direct current) was conducted at an initial luminance of 1000 cd/m². A time that elapsed until the initial luminance was reduced by half was measured.

### Comparative Example 1

An organic EL device was fabricated and evaluated in the same manner as in Example 1, except that, in Example 1, the electron-injecting layer was formed by using comparative compound (1) instead of compound (1). The results are shown in Table 1.

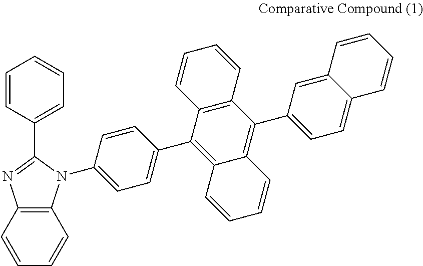 [SMILES: c1ccc(-c2nc3ccccc3n2-c2ccc(-c3c4ccccc4c(-c4ccc5ccccc5c4)c4ccccc34)cc2)cc1]

### Comparative Example 2

An organic EL device was fabricated and evaluated in the same manner as in Example 1, except that, in Example 1, the electron-injecting layer was formed by using comparative compound (2) instead of compound (1). The results are shown in Table 1.

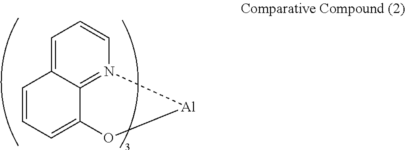

TABLE 1

| | Hole-blocking | Electron-injecting | Voltage | |
|---|---|---|---|---|
| | layer | layer | (V) | Life (h) |
| Example 1 | (H1) | Compound (1) | 5.0 | 7,300 |
| Example 2 | (HBL1) | Compound (1) | 4.8 | 7,000 |
| Example 3 | Compound (1) | Compound (1) | 4.6 | 7,000 |
| Comp. Ex. 1 | (H1) | Comp. Compound | 5.2 | 6,500 |
| | | (1) | | |
| Comp. Ex. 2 | (H1) | Comp. Compoud | 7.4 | 7,000 |
| | | (2) | | |

From the results of Examples 1 to 3, when the compound of the invention was used in the electron-injecting layer or the hole-blocking layer/electron-injecting layer, devices that could be driven at a lower voltage while keeping the life equivalent to those of Comparative Examples were obtained. In particular, when the compound of the invention was used in the hole-blocking layer/electron-injecting layer, an effect of lowering the driving voltage was significantly exhibited.

### Example 4

An organic EL device was fabricated and evaluated in the same manner as in Example 1, except that, in Example 1, the phosphorescent emitting layer was formed by using the following compound (H2) instead of compound (H1). The results are shown in Table 2.

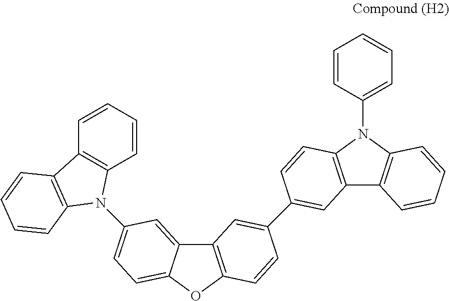 [SMILES: c1ccc(-n2c3ccccc3c3cc(-c4ccc5oc6ccc(-n7c8ccccc8c8ccccc87)cc6c5c4)ccc32)cc1]

### Comparative Example 3

An organic EL device was fabricated and evaluated in the same manner as in Example 4, except that, in Example 4, the electron-injecting layer was formed by using comparative compound (1) instead of compound (1). The results are shown in Table 2.

TABLE 2

| | Hole-blocking | Electron-injecting | | |
|---|---|---|---|---|
| | layer | layer | Voltage (V) | Life (h) |
| Example 4 | (H1) | Compound (1) | 4.6 | 4,300 |
| Comp. | (H1) | Comp. Compound | 5.1 | 4,300 |
| Ex. 3 | | (1) | | |

From the results of Example 4, it can be understood that when the compound of the invention is used in the electron-injecting layer, a device that can be driven at a lower voltage while keeping the life equivalent to that of Comparative Example 3 can be obtained.

### Example 5

An organic EL device was fabricated and evaluated in the same manner as in Example 1, except that, in Example 1, the electron-injecting layer was formed by depositing compound (1) and lithium (Li) at such a film thickness ratio that the amount of Li became 4 mass %. The results are shown in Table 3.

### Example 6

An organic EL device was fabricated and evaluated in the same manner as in Example 2, except that, in Example 2 the electron-injecting layer was formed by depositing compound (1) and lithium (Li) at such a film thickness ratio that the amount of Li became 4 mass %. The results are shown in Table 3.

TABLE 3

| | Hole-blocking | Electron-injecting | | |
|---|---|---|---|---|
| | layer | layer | Voltage (V) | Life (h) |
| Example 1 | (H1) | Compound (1) | 5.0 | 7,300 |
| Example 2 | (HBL1) | Compound (1) | 4.8 | 7,000 |
| Example 5 | (H1) | Compound (1) + Li | 4.1 | 7,500 |
| Example 6 | (HBL1) | Compound (1) + Li | 3.9 | 7,200 |

From Table 3, it can be understood that, as compared with an organic EL device in which Li is not doped, an organic EL device using compound (1) and Li (electron-donating dopant) as the electron-injecting layer can be driven at a further lower voltage while keeping the equivalent life.

### Example 7

An organic EL device was fabricated and evaluated in the same manner as in Example 1, except that, in Example 1, the phosphorescent emitting layer was formed by using the following compound (H3) instead of compound (H1). The results are shown in Table 4.

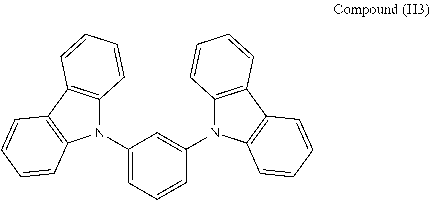 [SMILES: c1cc(-n2c3ccccc3c3ccccc32)cc(-n2c3ccccc3c3ccccc32)c1]

### Comparative Example 4

An organic EL device was fabricated and evaluated in the same manner as in Example 7, except that, in Example 7, the electron-injecting layer was formed by using comparative compound (1) instead of compound (1). The results are shown in Table 4.

TABLE 4

| | Hole-blocking | Electron-injecting | Voltage | |
|---|---|---|---|---|
| | layer | layer | (V) | Life (h) |
| Example 7 | (H1) | Compound (1) | 5.6 V | 600 |
| Comp. | (H1) | Comp. | 6.3 V | 600 |
| Ex. 4 | | Compound (1) | | |

From the results of Example 7, it can be understood that, when the compound of the invention is used in the electron-injecting layer, a device that can be driven at a lower voltage while keeping the life equivalent to that of Comparative Example 4 can be obtained.

### Example 8

An organic EL device was fabricated and evaluated in the same manner as in Example 1, except that, in Example 1, the phosphorescent emitting layer was formed by using the following compound (H4) instead of compound (H1). The results are shown in Table 5.

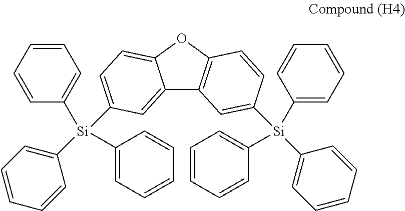 [SMILES: c1ccc([Si](c2ccccc2)(c2ccccc2)c2ccc3oc4ccc([Si](c5ccccc5)(c5ccccc5)c5ccccc5)cc4c3c2)cc1]

### Comparative Example 5

An organic EL device was fabricated and evaluated in the same manner as in Example 8, except that, in Example 8, the electron-injecting layer was formed by using comparative compound (1) instead of compound (1). The results are shown in Table 5.

TABLE 5

| | Hole-blocking | Electron-injecting | Voltage | |
|---|---|---|---|---|
| | layer | layer | (V) | Life (h) |
| Example 8 | (H1) | Compound (1) | 5.3 V | 100 |
| Comp. | (H1) | Comp. | 6.0 V | 100 |
| Ex. 5 | | Compound (1) | | |

From the results of Example 8, it can be understood that, when the compound of the invention is used in the electron-injecting layer, a device that can be driven at a lower voltage while keeping the life equivalent to that of Comparative Example 5 can be obtained.

Further, from the results of Examples 1, 4, 7 and 8, it can be understood that, when the compound of the invention is used in the electron-injecting layer, the organic EL devices of Examples 1 and 4 in which the compound having a carbazole ring and a dibenzofuran ring is used as the host of the emitting layer have a further prolonged life as compared with the devices of Examples 7 and 8.

### Synthesis Example 2

### (1) Synthesis of Compound (140))

### (1) Synthesis of Compound (140-a)

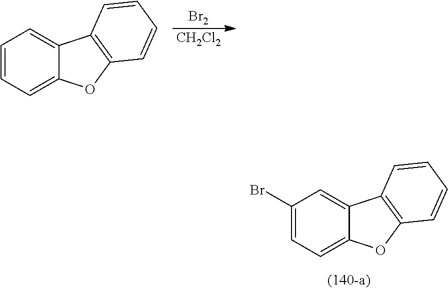

In a three-neck flask, 269.1 g (1600 mmol) of dibenzofuran and 1280 mL of dichloromethane were put, and the reactor was cooled to 0° C. in a nitrogen atmosphere. 100 mL of a dichloromethane solution of 204.6 g of bromine was added dropwise to the reactor over a period of 40 minutes, followed by stirring at room temperature for 12 hours. After completion of the reaction, the reactor was cooled to 0° C., and 500 mL of water was added. Further, 100 mL of a 20% aqueous NaHSO₄ solution was added. The sample solution was transferred to a separating funnel, and extracted several times with dichloromethane. The thus extracted sample was washed with 300 mL of a 1N aqueous sodium hydroxide solution, dried with anhydrous magnesium sulfate, filtrated and concentrated. The resultant was washed by dispersing in hexane, thereby to obtain white solids.

The yield amount was 136 g. The yield was 55%.

### (2) Synthesis of Compound (140-b)

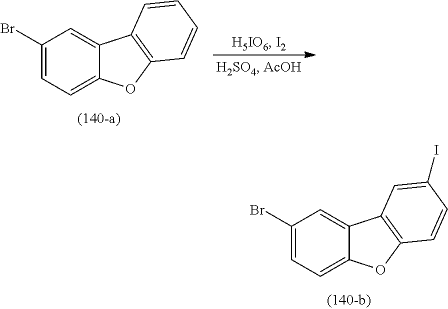 [SMILES: Brc1ccc2oc3ccccc3c2c1 ; Brc1ccc2oc3ccc(I)cc3c2c1]

In a three-neck flask, 10.0 g (40.4 mmol) of compound (140-a), 1.96 g (8.60 mmol) of orthoperiodical acid, 4.08 g (16.1 mmol) of iodine, 8 mL of dilute sulfuric acid and 40 mL of acetic acid were put, followed by stirring at 70° C. for 3 hours. After cooling the rector to room temperature, the reaction liquid was added to ice water, and precipitated solids were removed by filtration. The thus obtained solids were washed with methanol, whereby white solids were obtained.

The yield amount was 6.78 g. The yield was 45%.

### (3) Synthesis of Compound (140-c)

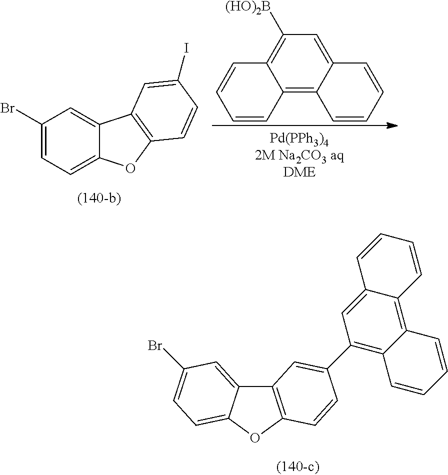

In a three-neck flask, 5.00 g (13.4 mmol) of compound (140-c), 2.48 g (11.2 mmol) of phenanthreneboronic acid, 18 mL of an aqueous 2M sodium carbonate solution, 35 mL of 1,2-dimethoxyethane, and 0.774 g (0.670 mmol) of Pd(PPh₃)₄ were put. The resultant was refluxed in a nitrogen atmosphere for 12 hours.

After completion of the reaction, 50 mL of water was added to the sample solution. The sample solution was transferred to a separating funnel, and extracted several times with dichloromethane. The thus extracted sample was dried with anhydrous magnesium sulfate, filtrated and concentrated. The resultant was purified by suspending and washing in methanol and hexane, thereby to obtain white solids.

The yield amount was 1.94 g. The yield was 41%.

### (5) Synthesis of Compound (140-d)

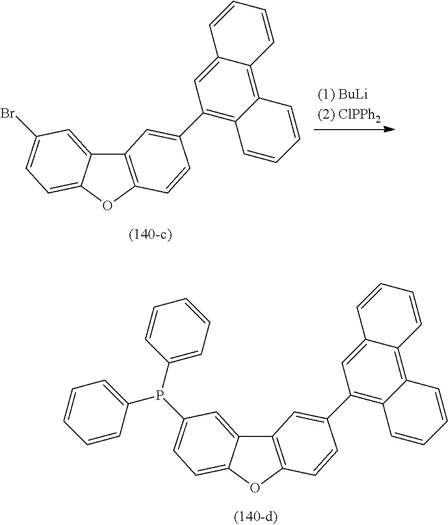 [SMILES: Brc1ccc2oc3ccc(-c4cc5ccccc5c5ccccc45)cc3c2c1 ; c1ccc(P(c2ccccc2)c2ccc3oc4ccc(-c5cc6ccccc6c6ccccc56)cc4c3c2)cc1]

In a three-neck flask, 1.50 g (2.84 mmol) of compound (140-c) and 10 mL of dehydrated tetrahydrofuran were put. The reactor was cooled to −70° C. in a nitrogen atmosphere. To the reactor, 1.9 mL (2.98 mmol) of a 1.57M n-butyllithium hexane solution was added dropwise, followed by stirring at −70° C. for one hour. To this, 0.783 mL (4.26 mmol) of chlorodiphenylphosphine was added, and stirred at room temperature for 8 hours.

After completion of the reaction, 50 mL of water was added. The resulting solution was transferred to a separating funnel, and extracted several times with dichloromethane. The thus obtained organic layer was dried with anhydrous magnesium sulfate, filtrated and concentrated. The resultant was purified by silica gel chromatography (hexane: dichloromethane=3:1), whereby white solids were obtained.

The yield amount was 1.28 g. The yield was 85%.

### (6) Synthesis of Compound (140)

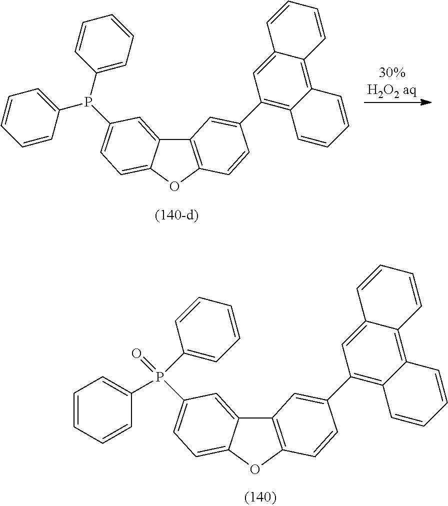 [SMILES: c1ccc(P(c2ccccc2)c2ccc3oc4ccc(-c5cc6ccccc6c6ccccc56)cc4c3c2)cc1 ; O=P(c1ccccc1)(c1ccccc1)c1ccc2oc3ccc(-c4cc5ccccc5c5ccccc45)cc3c2c1]

In a three-neck flask, 1.25 g (2.36 mmol) of compound (140-d) and 24 mL of dichloromethane were put. The reactor was cooled to 0° C. in a nitrogen atmosphere. 5 ml of a 30% aqueous solution of hydrogen peroxide was added, and the mixture was stirred at room temperature for 6 hours.

After completion of the reaction, 50 mL of water was added. The resulting solution was transferred to a separating funnel, and extracted several times with dichloromethane. The thus obtained organic layer was dried with anhydrous magnesium sulfate, filtrated and concentrated. The resultant was purified by silica gel chromatography (dichloromethane:ethyl acetate=2:1), whereby white solids were obtained.

The yield amount was 1.16 g. The yield was 90%.

The resulting white solids were analyzed by Field Desorption Mass Spectrometry (hereinafter referred to as FD-MS). As a result, they were confirmed to be the compound (140).

The results of FD-MS are shown below.

(m/z [M]⁺ calcd for C₃₈H₂₅O₂P 544; observed [M]⁺544)

The results of ¹H-NMR are also shown below.

For the measurement of ¹H-NMR, JNM-AL400 manufactured by JEOL Ltd. was used. Each sample for measurement was prepared by dissolving about 0.5 mg of the each compound in about 0.5 ml of dichloromethane, and the measurement was conducted for the sample.

¹H-NMR (CDCl₃) δ 8.80 (d, J=6.3 Hz, 1H), 8.74 (d, J=6.3 Hz, 1H), 8.33 (d, J=8.4 Hz, 1H), 8.06 (s, 1H), 7.90 (d, J=6.3 Hz, 1H), 7.87 (d, J=6.3 Hz, 1H), 7.85-7.60 (m, 11H), 7.59-7.42 (m, 8H)

### Synthesis Example 3

### Synthesis of Compound (141))

### (1) Synthesis of Compound (141-a)

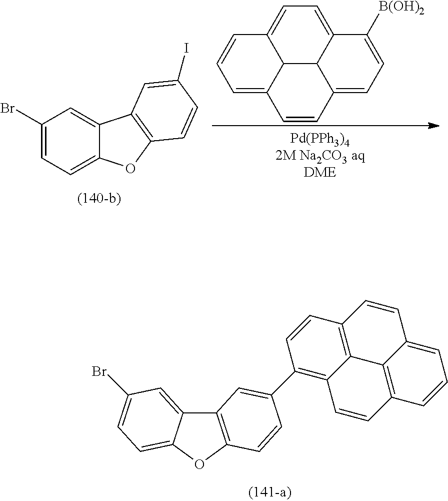

In a three-neck flask, 8.50 g (22.9 mmol) of compound (140-b), 4.68 g (19.0 mmol) of pyreneboronic acid, 30 mL of an aqueous 2M sodium carbonate solution, 60 mL of 1,2-dimethoxyethane and 1.32 g (1.15 mmol) of Pd(PPh₃)₄ were put. The resultant was refluxed in a nitrogen atmosphere for 12 hours.

After completion of the reaction, 100 mL of water was added to the sample solution. The sample solution was transferred to a separating funnel, and extracted several times with dichloromethane. This was dried with anhydrous magnesium sulfate, filtrated and concentrated. The resultant was purified by suspending and washing in methanol and hexanol, whereby white solids were obtained.

The yield amount was 2.00 g. The yield was 23%.

### (2) Synthesis of Compound (141-b)

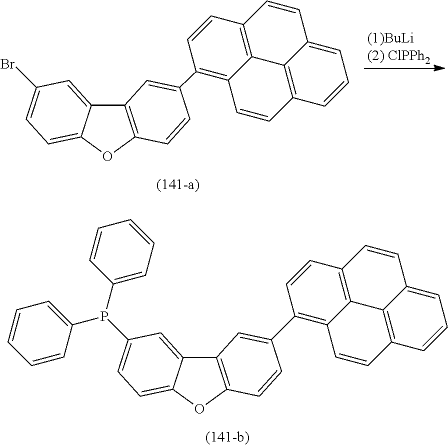 [SMILES: Brc1ccc2oc3ccc(-c4ccc5ccc6cccc7ccc4c5c67)cc3c2c1 ; c1ccc(P(c2ccccc2)c2ccc3oc4ccc(-c5ccc6ccc7cccc8ccc5c6c78)cc4c3c2)cc1]

In a three-neck flask, 2.00 g (4.47 mmol) of compound (141-a) and 12 mL of dehydrated tetrahydrofuran were put. The reactor was cooled to −70° C. in a nitrogen atmosphere. To the reactor, 2.67 mL (4.25 mmol) of a 1.59M n-butyllithium hexane solution was added dropwise, followed by stirring at −70° C. for one hour. To this, 1.64 mL (8.94 mmol) of chlorodiphenylphosphine was further added, and stirred at room temperature for 8 hours.

After completion of the reaction, 50 mL of water was added. The resulting solution was transferred to a separating funnel, and extracted several times with dichloromethane. The thus obtained organic layer was dried with anhydrous magnesium sulfate, filtrated and concentrated. The resultant was purified by silica gel chromatography (hexane: dichloromethane=3:1), whereby white solids were obtained.

The yield amount was 1.53 g. The yield was 65%.

### (3) Synthesis of Compound (141)

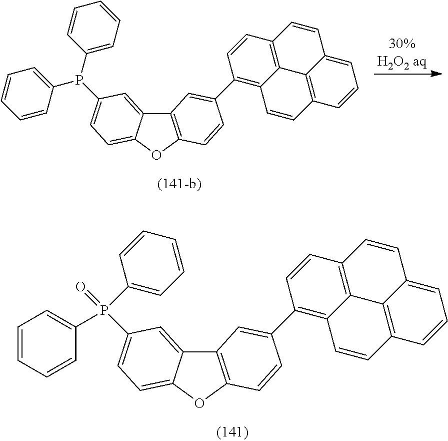 [SMILES: c1ccc(P(c2ccccc2)c2ccc3oc4ccc(-c5ccc6ccc7cccc8ccc5c6c78)cc4c3c2)cc1 ; O=P(c1ccccc1)(c1ccccc1)c1ccc2oc3ccc(-c4ccc5ccc6cccc7ccc4c5c67)cc3c2c1]

In a three-neck flask, 1.50 g (2.71 mmol) of compound (141-b) and 30 mL of dichloromethane were put. The reactor was cooled to 0° C. in a nitrogen atmosphere. To the reactor, 7 ml of an aqueous 30% hydrogen peroxide solution was added, and the mixture was stirred at room temperature for 6 hours.

After completion of the reaction, 50 mL of water was added. The resulting solution was transferred to a separating funnel, and extracted several times with dichloromethane. The thus obtained organic layer was dried with anhydrous magnesium sulfate, filtrated and concentrated. The resultant was purified by silica gel chromatography (dichloromethane:ethyl acetate=2:1), whereby white solids were obtained.

The yield amount was 1.16 g. The yield was 75%.

The resulting white solids were analyzed by FD-MS. As a result, they were confirmed to be the compound (141). The results of FD-MS are shown below.

(m/z [M]⁺ calcd for C₄₀H₂₅O₂P 568; observed [M]⁺568)

The results of ¹H-NMR are also shown below.

¹H-NMR (CDCl₃) δ 8.38 (d, J=9.6 Hz, 1H), 8.28-8.10 (m, 7H), 8.05-8.00 (m, 3H), 7.82-7.68 (m, 8H), 7.58-7.52 (m, 2H), 7.52-7.43 (m, 4H)

### Synthesis Example 4

### Synthesis of Compound (149))

### (1) Synthesis of Compound (149-b)

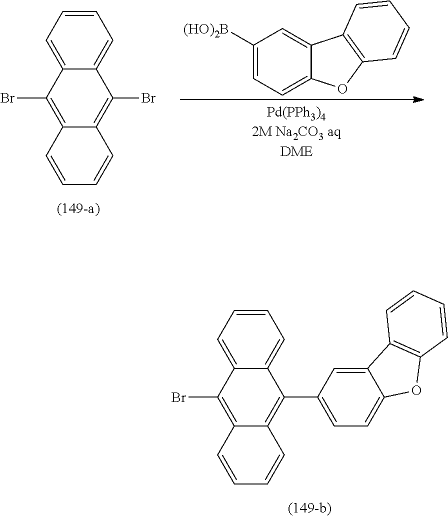 [SMILES: Brc1c2ccccc2c(Br)c2ccccc12 ; OB(O)c1ccc2oc3ccccc3c2c1 ; Brc1c2ccccc2c(-c2ccc3oc4ccccc4c3c2)c2ccccc12]

In a three-neck flask, 4.00 g (12.0 mmol) of 9,10-dibromoanthracene, 3.05 g (14.4 mmol) of dibenzofuran boronic acid, 20 mL of a 2M aqueous sodium carbonate solution, 40 mL of 1,2-dimethoxyethane and 0.693 g (0.600 mmol) of Pd(PPh₃)₄ were put. The mixture was refluxed in a nitrogen atmosphere for 12 hours.

After completion of the reaction, 50 mL of water was added to the sample solution. The sample solution was transferred to a separating funnel, and extracted several times with dichloromethane. This was dried with anhydrous magnesium sulfate, filtrated and concentrated. The resultant was purified by dispersing and washing in methanol and hexane, whereby white solids were obtained.

The yield amount was 3.01 g. The yield was 59%.

### (2) Synthesis of Compound (149-c)

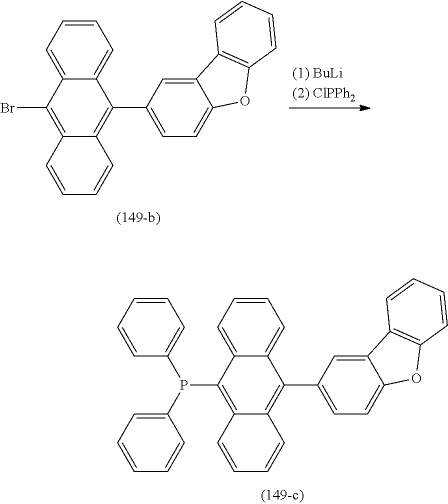 [SMILES: Brc1c2ccccc2c(-c2ccc3oc4ccccc4c3c2)c2ccccc12 ; c1ccc(P(c2ccccc2)c2c3ccccc3c(-c3ccc4oc5ccccc5c4c3)c3ccccc23)cc1]

In a three-neck flask, 3.00 g (7.11 mmol) of compound (149-b) and 20 mL of dehydrated tetrahydrofuran were put. The reactor was cooled to −70° C. in a nitrogen atmosphere. To the reactor, 4.7 mL (7.46 mmol) of a 1.58M n-butyllithium hexane solution was added dropwise, followed by stirring at −70° C. for one hour. Further, 1.96 mL (10.7 mmol) of chlorodiphenylphosphine was added thereto, and stirred at room temperature for 8 hours.

After completion of the reaction, 50 mL of water was added. The mixture was transferred to a separating funnel, and extracted several times with dichloromethane. The thus obtained organic layer was dried with anhydrous magnesium sulfate, filtrated and concentrated. The resultant was purified by silica gel chromatography (hexane: dichloromethane=3:1), whereby white solids were obtained.

The yield amount was 2.22 g. The yield was 59%.

### (3) Synthesis of Compound (149)

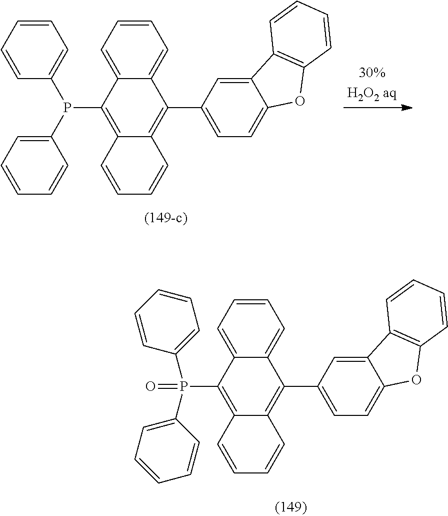 [SMILES: c1ccc(P(c2ccccc2)c2c3ccccc3c(-c3ccc4oc5ccccc5c4c3)c3ccccc23)cc1 ; O=P(c1ccccc1)(c1ccccc1)c1c2ccccc2c(-c2ccc3oc4ccccc4c3c2)c2ccccc12]

In a three-neck flask, 2.00 g (3.79 mmol) of compound (149-c) and 40 mL of dichloromethane were put. The reactor was cooled to 0° C. in a nitrogen atmosphere. To the reactor, 8 ml of an aqueous 30% hydrogen peroxide solution was added, followed by stirring at room temperature for 6 hours.

After completion of the reaction, 50 mL of water was added. The mixture was transferred to a separating funnel, and extracted several times with dichloromethane. The thus obtained organic layer was dried with anhydrous magnesium sulfate, filtrated and concentrated. The resultant was purified by silica gel chromatography (dichloromethane:ethyl acetate=2:1), whereby white solids were obtained.

The yield amount was 1.73 g. The yield was 84%.

The resulting white solids were analyzed by FD-MS. As a result, they were confirmed to be compound (141). The results of FD-MS are shown below.

(m/z [M]⁺ calcd for C₃₈H₂₅O₂P 544; observed [M]⁺ 544)

The results of ¹H-NMR are also shown below.

¹H-NMR (CDCl₃) δ 8.68 (d, J=5.7 Hz, 2H), 8.03 (s, 1H), 7.94 (d, J=6.0 Hz, 1H), 7.84-7.75 (m, 6H), 7.74-7.65 (m, 3H), 7.60-7.35 (m, 10H), 7.30-720 (m, 2H)

### Synthesis Example 5

### Synthesis of Compound (165))

### (1) Synthesis of Compound (165-a)

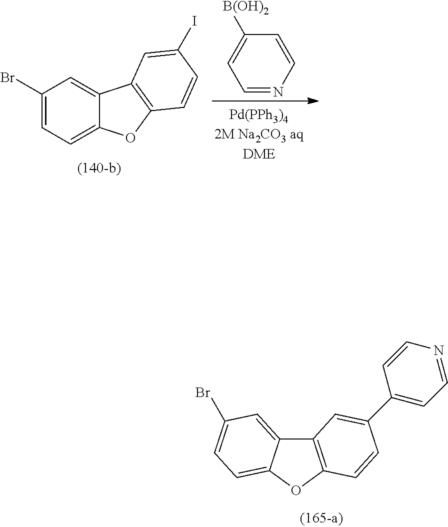

In a three-neck flask, 7.46 g (20.0 mmol) of compound (140-b), 2.46 g (20.0 mmol) of 4-pyridinylboronic acid, 50 mL of an aqueous 2M sodium carbonate solution, 140 mL of 1,2-dimethoxyethane and 1.16 g (1.00 mmol) of Pd(PPh₃)₄ were put, and refluxed for 12 hours in a nitrogen atmosphere.

After completion of the reaction, 50 ml of water was added to the sample solution. The resulting solution was transferred to a separating funnel, and extracted several times with dichloromethane. The extracted sample solution was dried with anhydrous magnesium sulfate, filtrated and concentrated. The resultant was purified by dispersing and washing in methanol, thereby to obtain pale yellow solids.

The yield amount was 4.62 g, and the yield was 71%.

### (2) Synthesis of Compound (165)

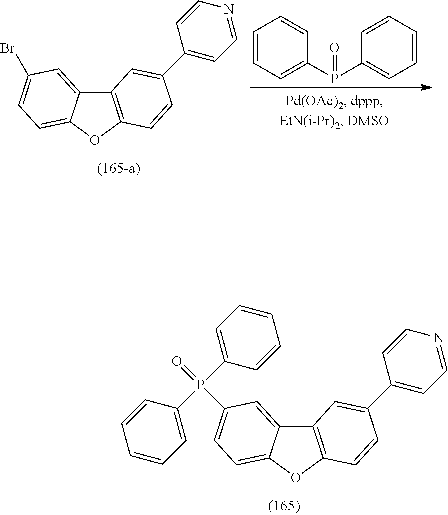

In a three-neck flask, 4.08 g (12.6 mmol) of compound (165-a), 5.10 g (25.2 mmol) of diphenylphosphine oxide, 0.141 g (0.630 mmol) of palladium acetate, 0.390 g (0.945 mmol) of 1,3-bis(diphenylphosphino)propene, 150 mL of dimethylsulfoxide and 10.7 mL (63.0 mmol) of N,N-diisopropylethylamine were put, followed by stirring at 100° C. for 13 hours in a nitrogen atmosphere.

After completion of the reaction, 50 ml of water was added. The resulting mixture was transferred to a separating funnel, and extracted several times with dichloromethane. The organic layer obtained was dried with anhydrous magnesium sulfate, filtrated and concentrated. The resultant was purified by silica gel chromatography (ethyl acetate: methanol=6:1), thereby to obtain white solids.

The yield amount was 4.09 g, and the yield was 73%.

The white solids obtained were analyzed by FD-MS. As a result, it was confirmed to be compound (165). The results of FD-MS are shown below.

(m/z [M]⁺ calcd for C₂₉H₂₀NO₂P 445; observed [M]⁺ 445)

The results of ¹H-NMR are also shown below.

¹H-NMR (CDCl₃) δ 8.69 (dd, J=0.9, 5.7 Hz, 2H), 8.46 (dd, J=0.9, 8.7 Hz, 1H), 8.18 (d, J=1.5 Hz, 1H), 7.84-7.65 (m, 8H), 7.65-7.45 (m, 8H)

### Synthesis Example 6

### Synthesis of Compound (170))

### (1) Synthesis of Compound (170-a)

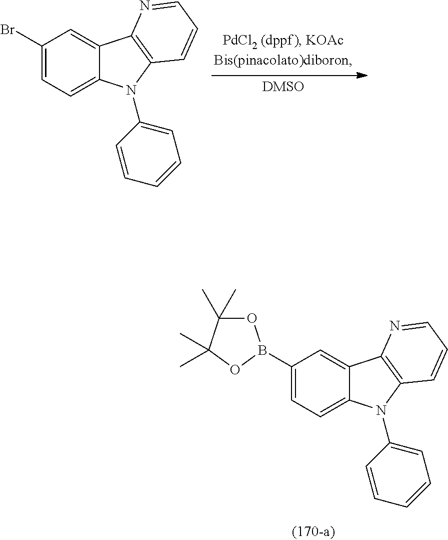 [SMILES: Brc1ccc2c(c1)c1ncccc1n2-c1ccccc1 ; CC1(C)OB(c2ccc3c(c2)c2ncccc2n3-c2ccccc2)OC1(C)C]

In a three-neck flask, 6.46 g (20.0 mmol) of Br compound, 7.62 g (30.0 mmol) of bis(pinacolato)diboron, 0.817 g (1.00 mmol) of [1,1′-bis(diphenylphosphino)ferrocene]palladium dichloride dichloromethane adduct compound, 6.10 g (62.2 mmol) of potassium acetate and 120 mL of dimethyl sulfoxide were put, followed by stirring at 80° C. for 11 hours in a nitrogen atmosphere.

After completion of the reaction, a solid matter was removed, and the resulting solution was concentrated. The concentrated solution was purified by silica gel chromatography (dichloromethane: ethyl acetate=2:1) to obtain white solids.

The yield amount was 5.28 g, and the yield was 71%.

### (2) Synthesis of Compound (170-b)

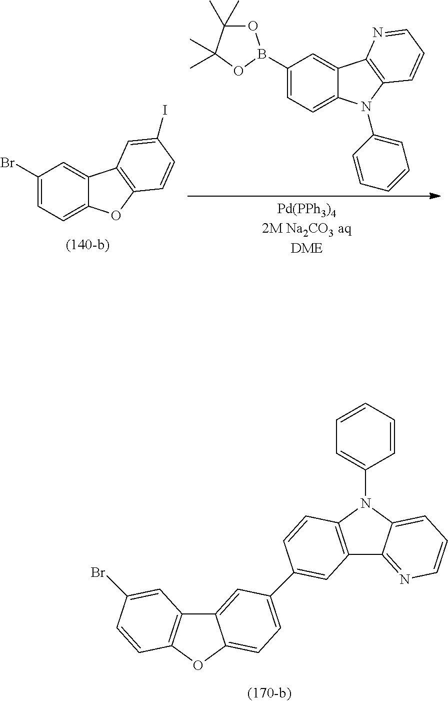 [SMILES: Brc1ccc2oc3ccc(I)cc3c2c1 ; CC1(C)OB(c2ccc3c(c2)c2ncccc2n3-c2ccccc2)OC1(C)C ; Brc1ccc2oc3ccc(-c4ccc5c(c4)c4ncccc4n5-c4ccccc4)cc3c2c1]

In a three-neck flask, 5.30 g (14.2 mmol) of compound (140-b), 5.28 g (14.2 mmol) of compound (170-a), 35 mL of a 2M sodium carbonate aqueous solution, 140 mL of 1,2-dimethoxyethane and 0.820 g (0.710 mmol) of Pd(PPh₃)₄ were put, and the resulting mixture was refluxed for 9 hours in a nitrogen atmosphere.

After completion of the reaction, 50 ml of water was added to the sample solution and the solid matter was separated by filtration. The separated solid matter was purified by dispersing and washing in methanol and hexane, thereby to obtain pale yellow solids.

The yield amount was 6.02 g, and the yield was 87%.

### (3) Synthesis of Compound (170)

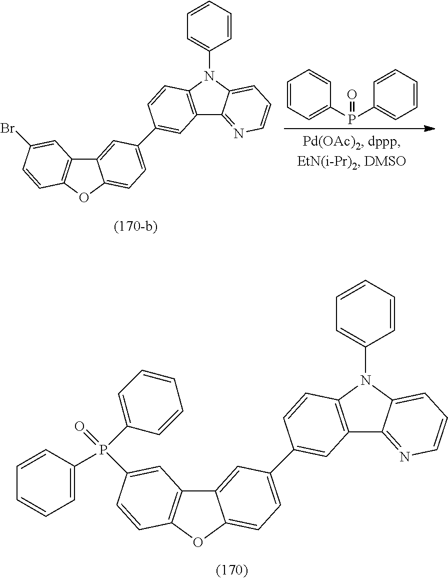

In a three-neck flask, 5.65 g (11.5 mmol) of compound (170-b), 4.65 g (23.0 mmol) of diphenylphosphine oxide, 0.129 g (0.575 mmol) of palladium acetate, 0.356 g (0.863 mmol) of 1,3-bis(diphenylphosphino)propane, 140 mL of dimethylsulfoxide and 9.78 mL (57.5 mmol) of N,N-diisopropylethylamine were put, followed by stirring at 100° C. for 12 hours in a nitrogen atmosphere.

After completion of the reaction, 50 ml of water was added. The resulting mixture was transferred to a separating funnel, and extracted several times with dichloromethane. The organic layer obtained was dried with anhydrous magnesium sulfate, filtrated and concentrated. The resultant was purified by silica gel chromatography (ethyl acetate: methanol=6:1), thereby to obtain white solids.

The yield amount was 5.48 g, and the yield was 78%.

The white solids obtained were analyzed by FD-MS. As a result, it was confirmed to be compound (170). The results of FD-MS are shown below.

(m/z [M]⁺ calcd for C₄₁H₂₇N₂₂O₂P 610; observed [M]⁺ 610)

The results of ¹H-NMR are also shown below.

¹H-NMR (CDCl₃) δ 8.71 (d, J=1.5 Hz, 1H), 8.64 (d, J=3.0 Hz, 1H), 8.32 (d, J=8.7 Hz, 1H), 8.24 (d, J=1.5 Hz, 1H), 7.90-7.48 (m, 22H), 7.36 (dd, J=3.0, 6.3 Hz, 1H)

### Synthesis Example 7

### Synthesis of Compound (173))

### (1) Synthesis of Compound (173-a)

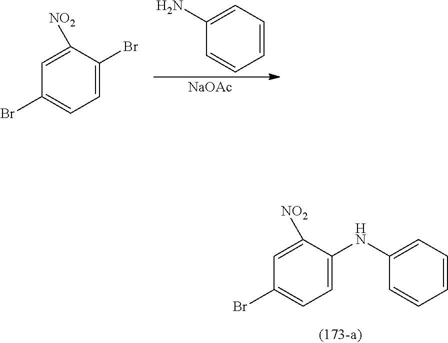 [SMILES: O=[N+]([O-])c1cc(Br)ccc1Br ; Nc1ccccc1 ; O=[N+]([O-])c1cc(Br)ccc1Nc1ccccc1 ; "NaOAc"]

In a three-neck flask, 25.2 g (89.7 mmol) of 1,4-dibromo-2-nitrobenzene and 22.09 g (269 mmol) of sodium acetate were put. 17.3 mL (177 mmol) of aniline was added dropwise thereto in a nitrogen atmosphere, followed by stirring at 16° C. for 7 hours.

After completion of the reaction, 50 mL of water was added. The resulting mixture was transferred to a separating funnel, and extracted several times with ethyl acetate. The organic layer obtained was dried with anhydrous magnesium sulfate, filtrated and concentrated. The resultant was purified by silica gel chromatography (hexane:dichloromethane=50:1) to obtain orange solids.

The yield amount was 17.1 g, and the yield was 65%.

### (2) Synthesis of Compound (173-b)

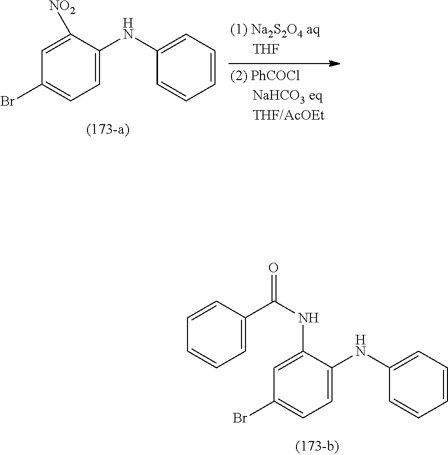 [SMILES: O=[N+]([O-])c1cc(Br)ccc1Nc1ccccc1 ; O=C(Nc1cc(Br)ccc1Nc1ccccc1)c1ccccc1]

In a three-neck flask, 16.4 g (56.3 mmol) of compound (173-a) and 120 mL of tetrahydrofuran were put. Under a stream of nitrogen, 200 mL of a 1.4M sodium dithionite solution was added, followed by stirring at room temperature for 5 hours. To the resulting mixture, 800 mL of ethyl acetate, 80 mL of a 1.4M sodium bicarbonate aqueous solution and 7.85 mL (67.6 mmol) of benzoyl chloride dissolved in 25 mL of ethyl acetate were added, followed by stirring under a stream of nitrogen at room temperature for 10 hours.

After completion of the reaction, the resultant was transferred to a separating funnel and extracted several times with ethyl acetate. The organic layer obtained was washed with a 10% potassium carbonate aqueous solution and saturate saline, dried with anhydrous magnesium sulfate, filtrated and concentrated to obtain pale yellow solids.

The yield amount was 20.6 g, and the yield was 99%.

### (3) Synthesis of Compound (173-c)

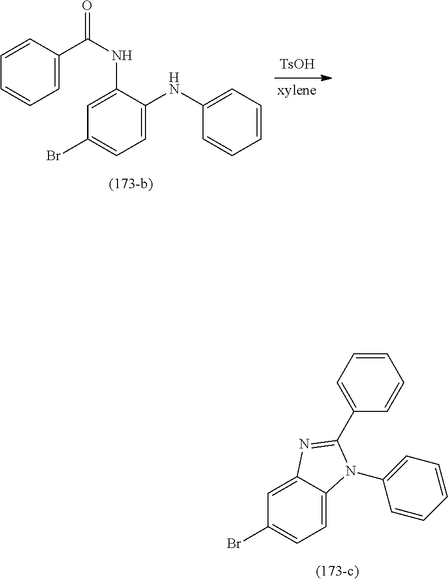 [SMILES: O=C(Nc1cc(Br)ccc1Nc1ccccc1)c1ccccc1 ; "TsOH" ; Brc1ccc2c(c1)nc(-c1ccccc1)n2-c1ccccc1]

In a three-neck flask, 20.6 g (56.1 mmol) of compound (173-b), 5.34 g (28.1 mmol) of para toluene sulfonic acid monohydrate and 220 mL of xylene were put, and subjected to azeotropic dehydration under reflux while heating for 4 hours under a nitrogen stream.

After completion of the reaction, a 10% potassium carbonate aqueous solution was added. The resulting solid matter was separated by filtration and washed with water to obtain white solids.

The yield amount was 12.8 g, and the yield was 66%.

### (4) Synthesis of Compound (173-d)

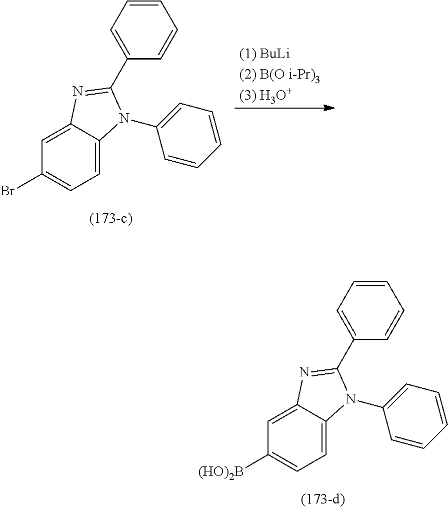 [SMILES: Brc1ccc2c(c1)nc(-c1ccccc1)n2-c1ccccc1 ; OB(O)c1ccc2c(c1)nc(-c1ccccc1)n2-c1ccccc1]

In a three-neck flask, 5.94 g (17.0 mmol) of compound (173-c) and 100 mL of dehydrated tetrahydrofuran were put. In a nitrogen atmosphere, the reactor was cooled to −70° C. To the reactor, 13.4 mL (22.1 mmol) of a 1.65M n-butyllithium hexane solution was added dropwise, followed by stirring at −70° C. for one hour. In addition, 6.67 mL (28.9 mmol) of tri isopropyl borate was added thereto, followed by stirring at room temperature for 6 hours. After completion of the reaction, 50 mL of a 1N HCl aqueous solution was added, and stirred for 30 minutes. Then, the sample solution was transferred to a separating funnel, and extracted several times with dichloromethane. The organic layer obtained was dried with anhydrous magnesium sulfate, filtrated and concentrated. The resultant was purified by silica gel chromatography (toluene: methanol=6:1) to obtain white solids.

The yield amount was 2.73 g, and the yield was 51%.

### (5) Synthesis of Compound (173-e)

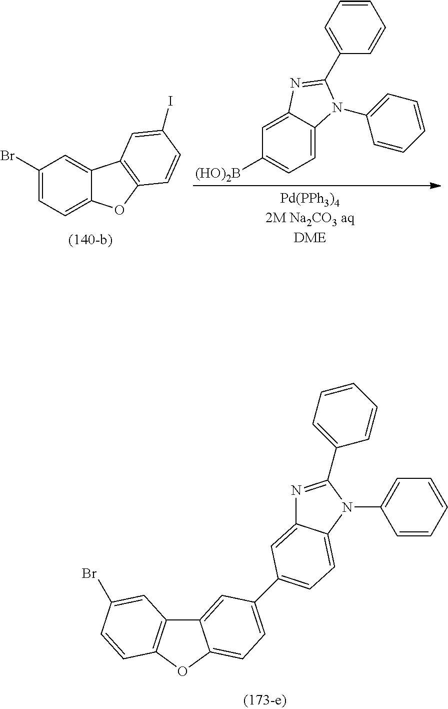 [SMILES: Brc1ccc2oc3ccc(I)cc3c2c1 ; OB(O)c1ccc2c(c1)nc(-c1ccccc1)n2-c1ccccc1 ; Brc1ccc2oc3ccc(-c4ccc5c(c4)nc(-c4ccccc4)n5-c4ccccc4)cc3c2c1]

In a three-neck flask, 2.87 g (7.70 mmol) of compound (6-b), 2.42 g (7.70 mmol) of compound (173-d), 19 mL of a 2M sodium carbonate aqueous solution, 100 mL of 1,2-dimethoxyethane and 0.445 (0.385 mmol) of Pd(PPh₃)₄ were put, and refluxed for 10 hours in a nitrogen atmosphere.

After completion of the reaction, 50 mL of water was added to the sample solution, and the solid matter was separated by filtration. The separated solid matter was purified by suspending and washing in methanol and hexane to obtain white solids.

The yield amount was 3.06 g, and the yield was 77%.

### (3) Synthesis of Compound (173)

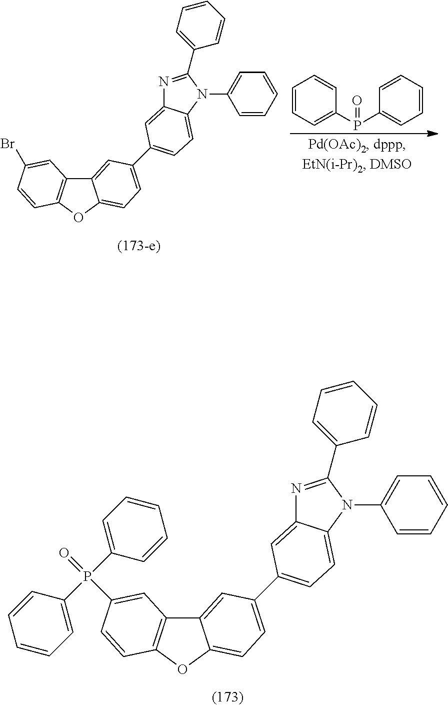

In a three-neck flask, 2.88 g (5.59 mmol) of compound (173-e), 2.26 g (11.2 mmol) of diphenylphosphine oxide, 0.0628 g (0.280 mmol) of palladium acetate, 0.173 g (0.419 mmol) of 1,3-bis(diphenylphosphino)propane, 70 mL of dimethylsulfoxide and 4.75 mL (28.0 mmol) of N,N-diisopropylethylamine were put, followed by stirring at 100° C. for 14 hours in a nitrogen atmosphere.

After completion of the reaction, 50 ml of water was added. The resulting mixture was transferred to a separating funnel, and extracted several times with dichloromethane. The organic layer obtained was dried with anhydrous magnesium sulfate, filtrated and concentrated. The resultant was purified by silica gel chromatography (toluene: methanol=6:1), thereby to obtain pale yellow solids.

The yield amount was 3.20 g, and the yield was 90%.

The pale yellow solids obtained were analyzed by FD-MS. As a result, it was confirmed to be compound (173). The results of FD-MS are shown below.

(m/z [M]⁺ calcd for C₄₃H₂₉N₂O₂P 636; observed [M]⁺ 636)

The results of ¹H-NMR are also shown below.

¹H-NMR (CDCl₃) δ 8.40 (d, J=7.8 Hz, 1H), 8.16 (d, J=1.5 Hz, 1H), 8.12 (d, J=1.5 Hz, 1H), 7.84-7.45 (m, 20H), 7.40-7.30 (m, 6H)

### Synthesis Example 8

### Synthesis of Compound (147)

### (1) Synthesis of Compound (147-a)

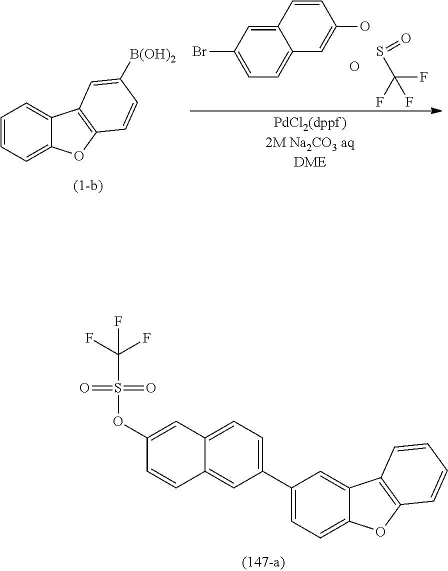

In a three-neck flask, 2.84 g (13.4 mmol) of compound (1-b), 4.76 g (13.4 mmol) of 6-bromo-2-naphtyl trifluoromethanesulfonate, 35 mL of a 2M sodium carbonate aqueous solution, 100 mL of 1,2-dimethoxyethane and 0.328 g (0.402 mmol) of [1,1′-bis(diphenylphosphino)ferrocene]palladium dichloride dichloromethane adduct were put. The mixture was refluxed for 8 hours in a nitrogen atmosphere.

After completion of the reaction, 50 mL of water was added to the sample solution. The resulting mixture was transferred to a separating funnel and extracted several times with dichloromethane. The extracted sample solution was dried with anhydrous magnesium sulfate, filtrated and concentrated. The resultant was purified by silica gel chromatography (hexane: dichloromethane=2:1) to obtain white solids.

The yield amount was 5.15 g, and the yield was 87%.

### (2) Synthesis of Compound (147)

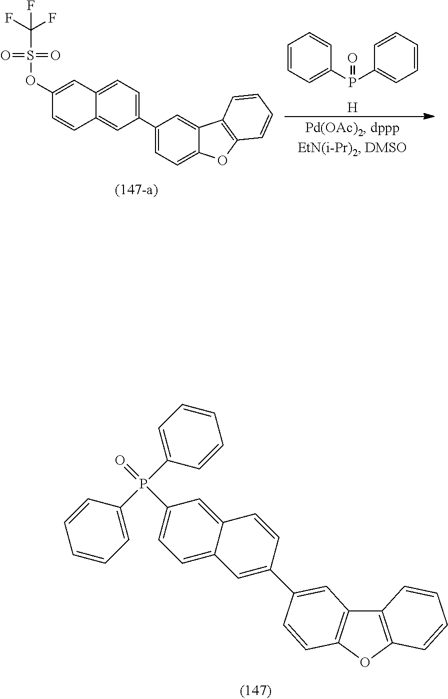

In a three-neck flask, 5.17 g (11.7 mmol) of compound (147-a), 4.73 g (23.4 mmol) of diphenylphosphine oxide, 0.131 g (0.585 mmol) of palladium acetate, 0.362 g (0.878 mmol) of 1,3-bis(diphenylphosphino)propane, 140 mL of dimethylsulfoxide and 9.95 mL (58.5 mmol) of N,N-diisopropylethylamine were put, followed by stirring at 100° C. for 12 hours in a nitrogen atmosphere. After completion of the reaction, 50 ml of water was added. The resulting mixture was transferred to a separating funnel, and extracted several times with dichloromethane. The organic layer obtained was dried with anhydrous magnesium sulfate, filtrated and concentrated. The resultant was purified by silica gel chromatography (toluene:ethyl acetate=1:1) to obtain white solids.

The yield amount was 4.10 g, and the yield was 71%.

The white solids obtained were analyzed by FD-MS. As a result, it was confirmed to be compound (147). The results of FD-MS are shown below.

(m/z [M]⁺ calcd for C₃₄H₂₃O₂P 494; observed [M]⁺494)

The results of ¹H-NMR are also shown below.

¹H-NMR (CDCl₃) δ 8.33 (d, J=10.2 Hz, 1H), 8.28 (d, J=1.5 Hz, 1H), 8.15 (d, J=1.5 Hz, 1H), 8.05-7.96 (m, 3H), 7.91 (d, J=6.6 Hz, 1H), 7.85-7.65 (m, 7H), 7.65-7.55 (m, 4H), 7.55-7.48 (m, 4H), 7.39 (t, J=5.4 Hz, 1H)

A part of the compounds synthesized as above, and exemplified compounds prepared in the same manner as in Synthesis Examples were evaluated for the hole mobility and the electron mobility by impedance spectrometry. For reference, the following referential compound disclosed in CHEMISTRY-AN ASIAN JOURNAL 2011, 6(11), 2895 was evaluated for the hole mobility and the electron mobility. The results are shown in Table 6.

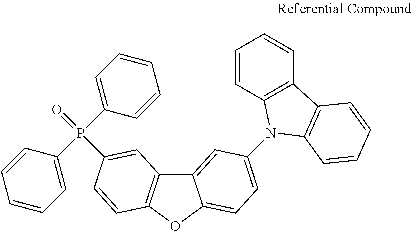 [SMILES: O=P(c1ccccc1)(c1ccccc1)c1ccc2oc3ccc(-n4c5ccccc5c5ccccc54)cc3c2c1]

### [Measurement of Mobility by Impedance Spectrometry]

A very small alternating voltage of 100 mV or less was applied to each of devices for measuring the hole mobility and for measuring the electron mobility which had been produced in the following method while applying a bias DC voltage. The alternating current value (absolute value and phase) flowing at this time was measured. This measurement was conducted with varying the frequency of the alternating voltage to calculate complex impedance (Z) from the current value and voltage value. The frequency dependence of the imaginary part (ImM) of the modulus M=iωZ (i: imaginary unit, ω: angular frequency) was determined. The inverse of the frequency ω at the maximal ImM was defined as a response time of a carrier conducting in an organic thin film. Then, the carrier mobility was calculated based on the following formula.

Carrier mobility=(thickness of organic thin film)²/(response time·applied voltage)

### (1) Preparation of Device for Measuring Hole Mobility

A glass substrate with a film thickness of 130 nm having ITO electrode lines (manufactured by Geomatec, Co., Ltd.) was subjected to ultrasonic cleaning in isopropyl alcohol for 5 minutes and UV ozone cleaning for 30 minutes. The cleaned glass substrate having ITO electrode lines was mounted on a substrate holder in a vacuum deposition apparatus. On the surface where the ITO electrode lines had been formed, initially, compound (HT1) was deposited by resistant heating to form a 10 nm-thick film so as to cover the ITO electrode lines. Next, the compound to be measured was deposited by resistant heating to form a 100 nm-thick film thereon. The film forming rate was 1 Å/s. Finally, metal aluminum was deposited at a film forming rate of 8.0 Å/s to form a metal electrode having a film thickness of 80 nm, whereby a device for measuring hole mobility was obtained.

### (2) Preparation of Device for Measuring Electron Mobility

A glass substrate was subjected to ultrasonic cleaning in isopropyl alcohol for 5 minutes and then UV ozone cleaning for 30 minutes. The cleaned glass substrate was mounted on a substrate holder in a vacuum deposition apparatus. Initially, metal aluminum was deposited at a film forming rate of 8.0 Å/s to form a metal anode having a film thickness of 80 nm. Subsequently, the compound to be measured was deposited to form a 100 nm-thick film, compound (H6) was deposited to form a 5 nm-thick film, and compound (ET1) was deposited to form a 5 nm-thick film in sequence. The film forming rate was 1 Å/s. LiF with a film thickness of 1.0 nm was deposited thereon at a film forming rate of 0.1 Å/s. Finally, metal aluminum was deposited at a film forming rate of 8.0 Å/s on the LiF film to form a metal cathode having a film thickness of 80 nm, whereby a device for measuring electron mobility was obtained.

TABLE 6

| | Hole mobility | Electron mobility |
|---|---|---|
| | [cm²/Vs] | [cm²/Vs] |
| Referential | 1.4 × 10⁻¹¹ | 7.8 × 10⁻⁸ |
| Compound | | |
| Compound | 5.7 × 10⁻¹⁰ | 3.8 × 10⁻⁷ |
| (1) | | |
| Compound (20) | 7.7 × 10⁻¹² | 4.1 × 10⁻⁷ |
| Compound (141) | 3.9 × 10⁻⁹ | 4.2 × 10⁻⁹ |
| Compound (165) | 1.2 × 10⁻¹¹ | 2.1 × 10⁻⁸ |
| Compound (87) | 5.2 × 10⁻⁹ | 5.4 × 10⁻⁸ |
| Compound (170) | 3.4 × 10⁻¹⁰ | 1.6 × 10⁻⁷ |
| Compound (173) | 3.3 × 10⁻⁸ | 4.9 × 10⁻⁸ |

Table 6 shows that the referential compound has a very high electron mobility compared to its hole mobility. Therefore, it is not a bipolar compound, but an electron-transporting compound.

On the other hand, although the compound of the invention has phosphine oxide and dibenzofuran with various substituents introduced into the terminal site, the level of the electron mobility is higher than that of the hole mobility. That is, it is found that the combined unit of phosphine oxide and dibenzofuran predominantly controls the carrier property of the compound, and hence each compound exhibits the electron-transporting property superior to the hole-transporting property. Since the compounds of the invention in which a fused heteroaromatic ring such as dibenzofuran, azadibenzofuran or azacarbazole is induced to the terminal site exhibit high electron mobility, the fused heteroaromatic ring is suitable for being at the terminal site.

### Example 9

### Preparation of Organic EL Device

A glass substrate with a film thickness of 130 nm having ITO electrode lines (manufactured by Geomatec, Co., Ltd.) was subjected to ultrasonic cleaning in isopropyl alcohol for 5 minutes and UV ozone cleaning for 30 minutes.

The cleaned glass substrate having ITO electrode lines was mounted on a substrate holder in a vacuum deposition apparatus. On the surface where the ITO electrode lines had been formed, initially, compound (HT1) was deposited by resistant heating to form a 20 nm-thick film so as to cover the ITO electrode lines. Subsequently, the compound (HT1) was deposited by resistant heating to form a 60 nm-thick film thereon. The film forming rate was 1 Å/s. These thin films function as a hole-injecting layer and a hole-transporting layer, respectively.

Next, on the hole-injecting/transporting layer, compound (H1) and compound (BD1) were simultaneously deposited by resistant heating to form a thin film with a thickness 50 nm. At this time, the compound (BD1) was deposited such that the mass of the compound (BD1) became 20% relative to the total mass of the compound (H1) and the compound (BD1). The deposition rates were 1.2 Å/s and 0.3 Å/s, respectively. This thin film functions as a phosphorescent emitting layer.

On the phosphorescent emitting layer, compound (H1) was deposited by resistant heating to form a 20 nm-thick thin film. The deposition rate was 1.0 Å/s. This thin film functions as a blocking layer and an electron-injecting layer.

Subsequently, on the blocking layer, compound (140) was deposited by resistant heating to form a 10 nm-thick thin film. The deposition rate was 1 Å/s. This film functions as an electron-injecting layer.

On the electron-injecting layer, LiF was deposited at a deposition rate of 0.1 Å/s to form a 1.0 nm-thick thin film.

Finally, on the LiF film, metal aluminum was deposited at a deposition rate of 8.0 Å/s to form an 80 nm-thick metal cathode, whereby an organic EL device was obtained.

For the organic EL device obtained, the half life was evaluated according to the following method. The result is shown in Table 7.

A continuous current test (DC) was conducted at an initial luminance of 1000 cd/m². The time that elapsed until the initial luminance reduced by half was measured.

### Examples 10 to 17 and Comparative Examples 6 to 7

Organic EL devices were produced and evaluated in the same manner as in Example 1, except that the blocking layer and the electron-injecting layer were formed by using compounds shown in Table 1 instead of compound (H1) and compound (140), respectively. The results are shown in Table 7.

The compounds used in Examples 9 to 17 and Comparative Examples 6 to 7 are shown below.

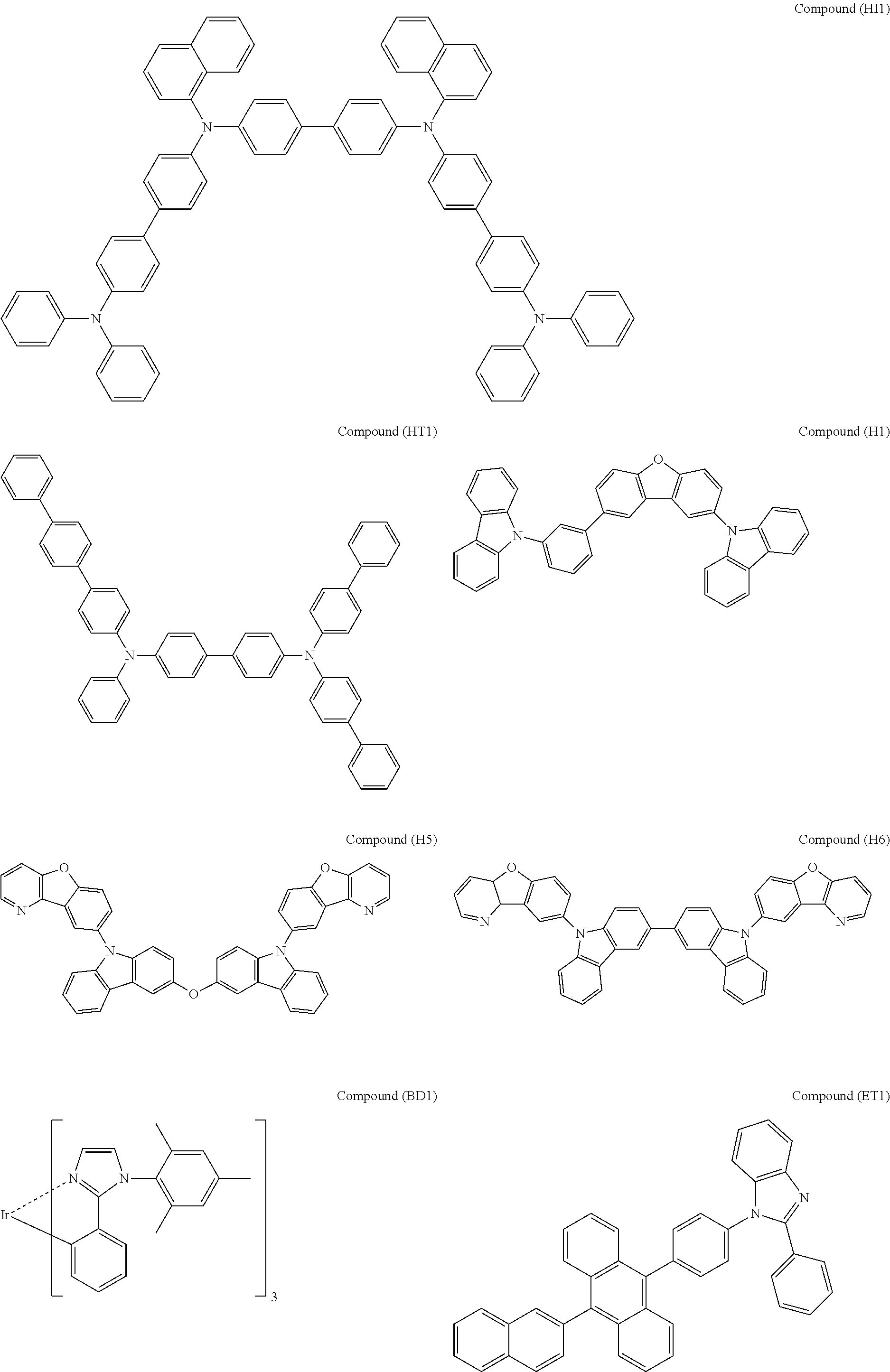

TABLE 7

| | | Electron-injecting | Half life |
|---|---|---|---|
| | Blocking layer | layer | [h] |
| Example 9 | Compound (H1) | Compound (140) | 8,400 |
| Example 10 | Compound (H5) | Compound (140) | 9,600 |
| Example 11 | Compound (H1) | Compound (165) | 9,200 |
| Example 12 | Compound (H5) | Compound (165) | 10,400 |
| Example 13 | Compound (165) | Compound (165) | 8,300 |
| Example 14 | Compound (H1) | Compound (147) | 9,000 |
| Example 15 | Compound (H5) | Compound (147) | 10,000 |
| Example 16 | Compound (H1) | Compound (170) | 9,300 |
| Example 17 | Compound (H5) | Compound (170) | 7,600 |
| Comp. Ex. 6 | Compound (H1) | Compound (ET1) | 7,000 |
| Comp. Ex. 7 | Compound (H5) | Compound (ET1) | 5,400 |

From the results in Table 7, it is found that use of the compound of the invention in the blocking layer and/or the electron-injecting layer allows the resulting device to have a prolonged life compared to the devices obtained in Comparative Examples 6 and 7.

### INDUSTRIAL APPLICABILITY

The compound of the invention can be used as a material for an organic EL device.

The organic EL device of the invention can be utilized for a planar emitting body such as a flat panel display of a wall-hanging television, a copier, a printer, a back light of a liquid crystal display, or a light source in instruments or the like, a sign board, a signal light or the like.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in this specification and the Japanese application specification claiming priority under the Paris Convention are incorporated herein by reference in its entirety.

1. A compound represented by the following formula (1-1): 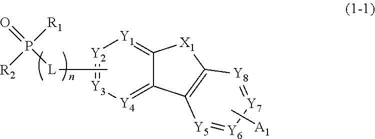
wherein in the formula (1-1),
X₁ is O or S;
Y₁ to Y₄ are independently C(Rₐ), N, or a carbon atom that is bonded to L or P;
Y₅ to Y₈ are independently C(Rₐ), N, or a carbon atom that is bonded to A₁;
L is O, S, a substituted or unsubstituted arylene group including 6 to 30 ring carbon atoms, or a substituted or unsubstituted heteroarylene group including 5 to 30 ring atoms;
n is an integer of 0 to 3, and when n is 2 or more, plural Ls may be the same or different from each other;
R₁ and R₂ are independently a substituted or unsubstituted aryl group including 6 to 30 ring carbon atoms, or a substituted or unsubstituted heteroaryl group including 5 to 30 ring atoms;
Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;
when two or more Rₐs are present in the formula (1-1), plural Rₐs may be the same or different from each other;
A₁ is a hydrogen atom, a substituted or unsubstituted aryl group including 6 to 30 ring carbon atoms, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl group, a substituted or unsubstituted azacarbazolyl group, a substituted or unsubstituted benzimidazolyl group, or a substituent represented by the following formula (2); and
provided that when A₁ is a hydrogen atom, n is an integer of 1 to 3: 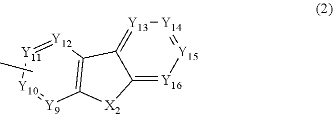
wherein in the formula (2),
X₂ is O or S;
Y₉ to Y₁₂ are independently C(Rₐ), N, or a carbon atom that is bonded to any of Y₅ to Y₈;
Y₁₃ to Y₁₆ are independently C(Rₐ), or N; and
Rₐ is the same as in the formula (1-1).

2. The compound according to claim 1, wherein the substituted or unsubstituted aryl group including 6 to 30 ring carbon atoms for A₁ is a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.

3. The compound according to claim 1, wherein the group represented by the formula (2) is a group represented by the following formula (2-1): 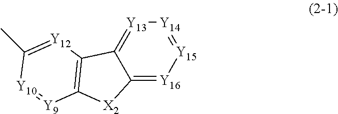
wherein in the formula (2-1),
X₂, Y₉, Y₁₀, Y₁₂ and Y₁₃ to Y₁₆ are the same as those in the formula (2).

4. The compound according to claim 1, wherein L is an arylene group or a heteroarylene group represented by any of the following formulas (4) to (8): 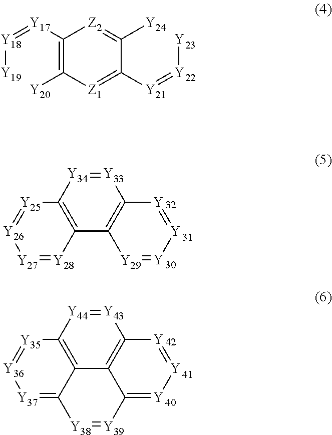 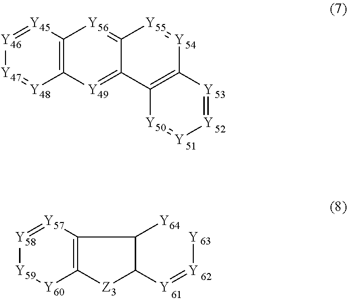
wherein in the formulas (4) to (8), Y₁₇ to Y₆₄, Z₁ and Z₂ are independently C(Rₐ), N or a carbon atom that is bonded to P, another L or any of Y₁ to Y₄;
in the formula (8), Z₃ is C(Rₐ)₂, N(Rₐ) or a nitrogen atom that is bonded to P, another L or any of Y₁ to Y₄; and
Rₐ is the same as in the formula (1-1).

5. A material for an organic electroluminescence device comprising the compound according to claim 1.

6. An electron-transporting material for an organic electroluminescence device represented by the following formula (1-2): 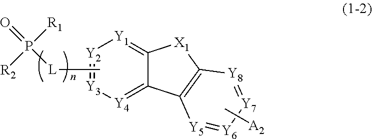
wherein in the formula (1-2),
X₁ is O or S;
Y₁ to Y₄ are independently C(Rₐ), N, or a carbon atom that is bonded to L or P;
Y₅ to Y₈ are independently C(Rₐ), N, or a carbon atom that is bonded to A₂;
L is O, S, a substituted or unsubstituted arylene group including 6 to 30 ring carbon atoms, or a substituted or unsubstituted heteroarylene group including 5 to 30 ring atoms;
n is an integer of 0 to 3, and when n is 2 or more, plural Ls may be the same or different from each other;
R₁ and R₂ are independently a substituted or unsubstituted aryl group including 6 to 30 ring carbon atoms, or a substituted or unsubstituted heteroaryl group including 5 to 30 ring atoms;
Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;
when two or more Rₐs are present in the formula (1-2), plural Rₐs may be the same or different from each other, and
A₂ is a hydrogen atom, a substituted or unsubstituted aryl group including 6 to 30 ring carbon atoms, or a substituted or unsubstituted heteroaryl group including 5 to 30 ring atoms.

7. The electron-transporting material for an organic electroluminescence device according to claim 6, wherein the substituted or unsubstituted aryl group including 6 to 30 ring carbon atoms for A₂ is a group selected from a substituted or unsubstituted naphthyl group, a substituted or unsubstituted anthryl group, a substituted or unsubstituted pyrenyl group, a substituted or unsubstituted phenanthryl group and a substituted or unsubstituted triphenylenyl group.

8. The electron-transporting material for an organic electroluminescence device according to claim 6, wherein the substituted or unsubstituted heteroaryl group including 5 to 30 ring atoms for A₂ is a group represented by the following formula (2): 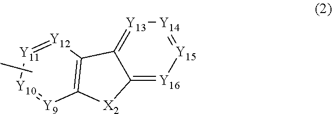
wherein in the formula (2),
X₂ is O or S;
Y₉ to Y₁₂ are independently C(Rₐ), N, or a carbon atom that is bonded to any of Y₅ to Y₈;
Y₁₃ to Y₁₆ are independently C(Rₐ), or N; and
Rₐ is the same as in the formula (1-2).

9. The electron-transporting material for an organic electroluminescence device according to claim 8, wherein the group represented by the formula (2) is a group represented by the following formula (2-1): 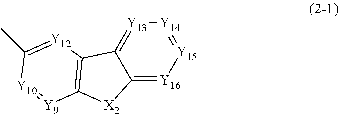
wherein in the formula (2-1),
X₂, Y₉, Y₁₀, Y₁₂ and Y₁₃ to Y₁₆ are the same as those in the formula (2).

10. The electron-transporting material for an organic electroluminescence device according to claim 6, wherein the substituted or unsubstituted heteroaryl group including 5 to 30 ring atoms for A₂ is a substituted or unsubstituted nitrogen-containing heteroaryl group including 5 to 30 ring atoms.

11. The electron-transporting material for an organic electroluminescence device according to claim 10, wherein the substituted or unsubstituted nitrogen-containing heteroaryl group including 5 to 30 ring atoms for A₂ is a substituted or unsubstituted pyridinyl group, a substituted or unsubstituted pyrimidinyl group, a substituted or unsubstituted triazinyl group, a substituted or unsubstituted imidazolyl group, a substituted or unsubstituted carbazolyl group, a substituted or unsubstituted phenanthrolinyl group, a substituted or unsubstituted carbazolyl group, or a substituted or unsubstituted azacarbazolyl group.

12. The electron-transporting material for an organic electroluminescence device according to claim 6, wherein L is an arylene group or a heteroarylene group represented by any of the following formulas (4) to (8): 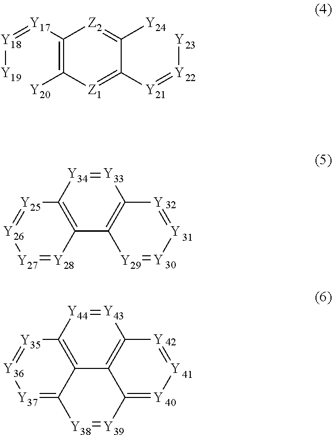 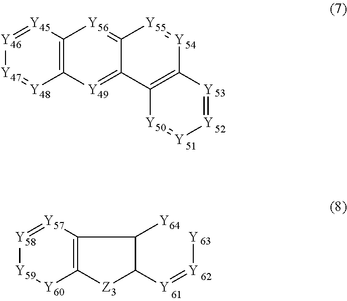
wherein in the formulas (4) to (8), Y₁₇ to Y₆₄, Z₁ and Z₂ are independently C(Rₐ), N, or a carbon atom that is bonded to P, another L or any of Y₁ to Y₄;
in the formula (8), Z₃ is C(Rₐ)₂, N(Rₐ), or a nitrogen atom that is bonded to P, other Ls or any of Y₁ to Y₄; and
Rₐ is the same as in the formula (1-2).

13. A hole-blocking material for an organic electroluminescence device represented by the following formula (1-3): 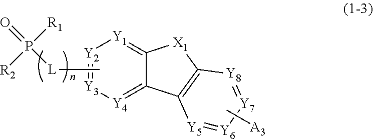
wherein in the formula (1-3),
X₁ is O or S;
Y₁ to Y₄ are independently C(Rₐ), N, or a carbon atom that is bonded to L or P;
Y₅ to Y₈ are independently C(Rₐ), N, or a carbon atom that is bonded to A₃;
L is O, S, a substituted or unsubstituted arylene group including 6 to 30 ring carbon atoms, or a substituted or unsubstituted heteroarylene group including 5 to 30 ring atoms;
n is an integer of 0 to 3, and when n is 2 or more, plural Ls may be the same or different from each other;
R₁ and R₂ are independently a substituted or unsubstituted aryl group including 6 to 30 ring carbon atoms, or a substituted or unsubstituted heteroaryl group including 5 to 30 ring atoms;
Rₐ is independently a hydrogen atom, a substituted or unsubstituted aryl group including 6 to 30 ring carbon atoms, a substituted or unsubstituted heteroaryl group including 5 to 30 ring atoms, a substituted or unsubstituted alkyl group including 1 to 30 carbon atoms, a substituted or unsubstituted fluoroalkyl group including 1 to 30 carbon atoms, a substituted or unsubstituted cycloalkyl group including 3 to 30 ring carbon atoms, a substituted or unsubstituted aralkyl group including 7 to 30 carbon atoms, a cyano group, a nitro group, or a carboxy group;
when two or more Rₐs are present in the formula (1-3), plural Rₐs may be the same or different from each other,
A₃ is a hydrogen atom, a substituted or unsubstituted phenyl group, a substituted or unsubstituted meta-biphenylyl group, a substituted or unsubstituted meta-terphenyl group, a substituted or unsubstituted pyridinyl group, a substituted or unsubstituted pyrimidinyl group, a substituted or unsubstituted triazinyl group, a substituted or unsubstituted imidazolyl group, a substituted or unsubstituted phenanthrolinyl group, a substituted or unsubstituted azacarbazolyl group, a substituted or unsubstituted benzimidazolyl group, or a substituent represented by the following formula (2); and
provided that when A₃ is a hydrogen atom, n is an integer of 1 to 3, 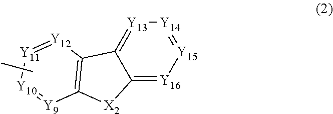
wherein in the formula (2),
X₂ is O or S;
Y₉ to Y₁₂ are independently C(Rₐ), N, or a carbon atom that is bonded to any of Y₅ to Y₈;
Y₁₃ to Y₁₆ are independently C(Rₐ), or N; and
Rₐ is the same as in the formula (1-3).

14. The hole-blocking material for an organic electroluminescence device according to claim 13, wherein the group represented by the formula (2) is a group represented by the following formula (2-1): 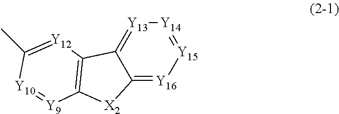
wherein in the formula (2-1),
X₂, Y₉, Y₁₀, Y₁₂ and Y₁₃ to Y₁₆ are the same as those in the formula (2).

15. The hole-blocking material for an organic electroluminescence device according to claim 13, wherein L is an arylene group or a heteroarylene group represented by any of the following formulas (4) to (8): 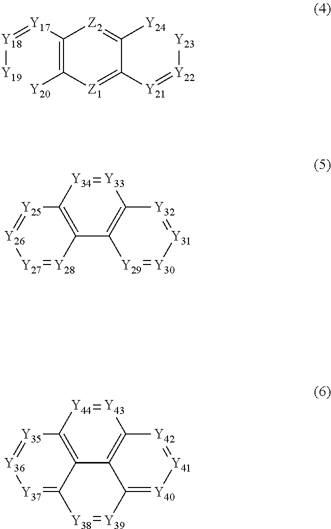 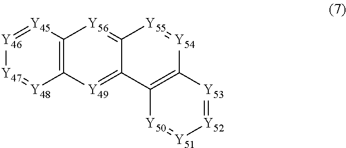 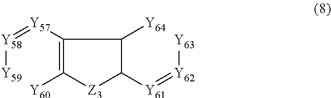
wherein in the formulas (4) to (8), Y₁₇ to Y₆₄, Z₁ and Z₂ are independently C(Rₐ), N or a carbon atom that is bonded to P, another L or any of Y₁ to Y₄;
in the formula (8), Z₃ is C(Rₐ)₂, N(Rₐ) or a nitrogen atom that is bonded to P, other Ls or any of Y₁ to Y₄; and
Rₐ is the same as in the formula (1-3).

16. An organic electroluminescence device comprising one or more organic thin film layers including an emitting layer between an anode and a cathode, wherein at least one layer of the organic thin film layers comprises the material for an organic electroluminescence device according to claim 5.

17. The organic electroluminescence device according to claim 16, wherein the emitting layer comprises the material for an organic electroluminescence device.

18. An organic electroluminescence device comprising one or more organic thin film layers including an emitting layer between an anode and a cathode, and comprising an electron-transporting region between the cathode and the emitting layer, wherein the electron-transporting region comprises the electron-transporting material for an organic electroluminescence device according to claim 6.

19. An organic electroluminescence device comprising one or more organic thin film layers including an emitting layer between an anode and a cathode, and comprising an hole-blocking layer between the cathode and the emitting layer, wherein the hole-barrier layer comprises the hole-barrier material for an organic electroluminescence device according to claim 13.

20. The organic electroluminescence device according to claim 19, further comprising an electron-transporting region between the cathode and the emitting layer.

21. The organic electroluminescence device according to claim 18, wherein the electron-transporting region comprises an electron-donating dopant.

22. The organic electroluminescence device according to claim 16, wherein the emitting layer comprises a phosphorescent material, the phosphorescent material being an ortho-metalated complex of a metal atom selected from iridium (Ir), osmium (Os) and platinum (Pt).

23. The organic electroluminescence device according to claim 22, wherein the phosphorescent material is represented by the following formula (I): 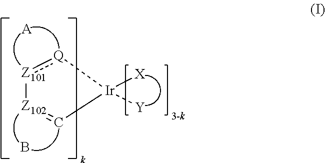
wherein in the formula, Z₁₀₁ and Z₁₀₂ are independently a carbon atom or a nitrogen atom;
A is a group of atoms that forms a five-membered hetero ring or a six-membered hetero ring together with Z₁₀₁ and a nitrogen atom;
B is a group of atoms that forms a five-membered ring or a six-membered ring together with Z₁₀₂ and a carbon atom;
Q is a carbon atom, a nitrogen atom, or a boron atom;
X—Y is a monoanionic bidentate ligand; and
k is an integer of 1 to 3.

24. The organic electroluminescence device according to claim 16, wherein the emitting layer comprises a compound comprising a carbazole ring and a dibenzofuran ring.
